(19) United States
(12) Patent Application Publication
(10) Pub. No.: US 2025/0133824 A1
(43) Pub. Date: Apr. 24, 2025

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Tatsuya ONUKI, Atsugi, Kanagawa (JP); Kiyoshi KATO, Atsugi, Kanagawa (JP); Hitoshi KUNITAKE, Machida, Tokyo (JP); Ryota HODO, Atsugi, Kanagawa (JP); Shunpei YAMAZAKI, Setagaya, Tokyo (JP)

(21) Appl. No.: 18/834,712

(22) PCT Filed: Jan. 27, 2023
(86) PCT No.: PCT/IB2023/050702

§ 371 Date: Jul. 31, 2024

(30) Foreign Application Priority Data
Feb. 10, 2022 (JP) 2022-019564

(51) Int. Cl. H10D 86/40; H10D 30/67; H10D 64/68

(52) U.S. Cl. CPC H10D 86/423; H10D 30/6756; H10D 64/691

(57) ABSTRACT

A semiconductor device that can be miniaturized or highly integrated is provided. First to second transistors share a first metal oxide over a first insulator and a first conductor over the first metal oxide; the first transistor includes a second conductor and a second insulator which are over the first metal oxide and a third conductor over the second insulator; the second transistor includes a fourth conductor and a third insulator which are over the first metal oxide and a fifth conductor over the third insulator; a side surface of the first insulator includes a portion in contact with the fourth conductor; an end portion of the fourth conductor includes a portion positioned outward from an end portion of the first insulator; the second insulator is positioned between the first conductor and the second conductor; the metal oxide and the third conductor overlap with each other with the second insulator therebetween; the third insulator is positioned between the first conductor and the fourth conductor; and the metal oxide and the fifth conductor overlap with each other with the third insulator therebetween.

### TECHNICAL FIELD

One embodiment of the present invention relates to a semiconductor device, a memory device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method for manufacturing any of them.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, semiconductor devices such as an LSI (Large Scale Integration), a CPU (Central Processing Unit), a GPU (Graphic Processing Unit), and a memory (memory device) have been developed. These semiconductor devices have been used in various electronic devices such as computers and portable information terminals. In addition, memories employing various memory systems for intended uses such as temporary storage at the time of executing arithmetic processing and long-term storage of data have been developed. Examples of memories employing typical memory systems include a DRAM (Dynamic Random Access Memory), an SRAM (Static Random Access Memory), and a flash memory.

With the increase in the amount of data dealt with, semiconductor devices having a larger storage capacity have been required. Patent Document 1 and Non-Patent Document 1 disclose a memory cell in which stacked transistors are formed.

### REFERENCES

### Patent Documents

[Patent Document 1] PCT International Publication No. 2021/053473

### Non-Patent Document

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be miniaturized or highly integrated. An object of one embodiment of the present invention is to provide a semiconductor device with high operating speed. An object of one embodiment of the present invention is to provide a semiconductor device having favorable electrical characteristics. An object of one embodiment of the present invention is to provide a semiconductor device in which variation in electrical characteristics of transistors is small. An object of one embodiment of the present invention is to provide a highly reliable semiconductor device. An object of one embodiment of the present invention is to provide a semiconductor device with a high on-state current. An object of one embodiment of the present invention is to provide a semiconductor device with low power consumption. An object of one embodiment of the present invention is to provide a novel semiconductor device.

An object of one embodiment of the present invention is to provide a memory device having large storage capacity. An object of one embodiment of the present invention is to provide a memory device occupying a small area. An object of one embodiment of the present invention is to provide a highly reliable memory device. An object of one embodiment of the present invention is to provide a memory device with low power consumption. An object of one embodiment of the present invention is to provide a novel memory device.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a semiconductor device including a first transistor, a second transistor, and a first insulator over an insulating surface. The first transistor and the second transistor share a first metal oxide over the first insulator and a first conductor over the first metal oxide. The first transistor includes a second conductor and a second insulator, the second conductor and the second insulator being over the first metal oxide, and a third conductor over the second insulator. The second transistor includes a fourth conductor and a third insulator, the fourth conductor and the third insulator being over the first metal oxide, and a fifth conductor over the third insulator. A side surface of the first insulator includes a portion in contact with the fourth conductor. An end portion of the fourth conductor includes a portion positioned outward from an end portion of the first insulator. The second insulator is positioned between the first conductor and the second conductor. The metal oxide and the third conductor overlap with each other with the second insulator therebetween. The third insulator is positioned between the first conductor and the fourth conductor. The metal oxide and the fifth conductor overlap with each other with the third insulator therebetween.

One embodiment of the present invention is a semiconductor device including a first transistor, a second transistor, a third transistor, a first insulator, a second insulator, a third insulator, and a capacitor. The first transistor and the second transistor share a first metal oxide over the first insulator and a first conductor over the first metal oxide. The first transistor includes a second conductor and a fourth insulator, the second conductor and the fourth insulator being over the first metal oxide, and a third conductor over the fourth insulator. The second transistor includes a fourth conductor and a fifth insulator, the fourth conductor and the fifth insulator being over the first metal oxide, and a fifth conductor over the fifth insulator. The third transistor includes a second metal oxide, a sixth conductor, a seventh conductor, and a sixth insulator, the sixth conductor, the seventh conductor, and the sixth insulator being over the second metal oxide, and an eighth conductor over the sixth insulator. The capacitor includes a ninth conductor, a seventh insulator over the ninth conductor, and a tenth conductor over the seventh insulator. A side surface of the first insulator includes a portion in contact with the fourth conductor. An end portion of the fourth conductor includes a portion positioned outward from an end portion of the first insulator. The second insulator is positioned over the first transistor and over the second transistor. The second conductor and the sixth conductor are electrically connected to each other through an opening provided in the second insulator. The third insulator is positioned over the third transistor. A portion where the ninth conductor, the seventh insulator, and the tenth conductor overlap with one another is positioned over the third insulator. The sixth conductor and the ninth conductor are electrically connected to each other through an opening provided in the third insulator.

The end portion of the fourth conductor preferably includes a portion positioned outward from an end portion of the second insulator.

The end portion of the second insulator preferably includes a portion positioned outward from the end portion of the first insulator.

An end portion of the seventh conductor preferably includes a portion positioned outward from the end portion of the second insulator.

An end portion of the third insulator preferably includes a portion positioned outward from the end portion of the first insulator.

The semiconductor devices described above each preferably include an eleventh conductor which includes a portion in contact with part of the top surface of the fourth conductor, a portion in contact with part of a side surface of the fourth conductor, a portion in contact with part of the top surface of the seventh conductor, and a portion in contact with part of a side surface of the seventh conductor. The eleventh conductor preferably includes a portion in contact with part of the bottom surface of the fourth conductor and a portion in contact with part of the bottom surface of the seventh conductor.

The seventh insulator preferably contains one or both of zirconium oxide and aluminum oxide.

### Effect of the Invention

According to one embodiment of the present invention, a semiconductor device that can be miniaturized or highly integrated can be provided. According to one embodiment of the present invention, a semiconductor device with high operating speed can be provided. According to one embodiment of the present invention, a semiconductor device having favorable electrical characteristics can be provided. According to one embodiment of the present invention, a semiconductor device in which variation in electrical characteristics of transistors is small can be provided. According to one embodiment of the present invention, a highly reliable semiconductor device can be provided. According to one embodiment of the present invention, a semiconductor device with a high on-state current can be provided. According to one embodiment of the present invention, a semiconductor device with low power consumption can be provided. According to one embodiment of the present invention, a novel semiconductor device can be provided.

According to one embodiment of the present invention, a memory device having large storage capacity can be provided. According to one embodiment of the present invention, a memory device occupying a small area can be provided. According to one embodiment of the present invention, a highly reliable memory device can be provided. According to one embodiment of the present invention, a memory device with lower power consumption can be provided. According to one embodiment of the present invention, a novel memory device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

line

FIG. 1 is a cross-sectional view illustrating an example of a semiconductor device.

FIG. 2 is a cross-sectional view illustrating an example of a semiconductor device.

FIG. 3 is a cross-sectional view illustrating an example of a semiconductor device.

FIG. 4 is a cross-sectional view illustrating an example of a semiconductor device.

FIG. 5 is a cross-sectional view illustrating an example of a semiconductor device.

FIG. 6 is a cross-sectional view illustrating an example of a semiconductor device.

FIG. 7 is a cross-sectional view illustrating an example of a semiconductor device.

FIG. 8 is a cross-sectional view illustrating an example of a semiconductor device.

FIG. 9 is a cross-sectional view illustrating an example of a semiconductor device.

FIG. 10 is a cross-sectional view illustrating an example of a semiconductor device.

FIG. 11 is a cross-sectional view illustrating an example of a semiconductor device.

FIG. 12A and FIG. 12B are top views illustrating examples of a semiconductor device.

FIG. 13A to FIG. 13D are cross-sectional views illustrating an example of a method for manufacturing a semiconductor device.

FIG. 14A to FIG. 14C are cross-sectional views illustrating an example of a method for manufacturing a semiconductor device.

FIG. 15A and FIG. 15B are cross-sectional views illustrating an example of a method for manufacturing a semiconductor device.

FIG. 16A and FIG. 16B are cross-sectional views illustrating an example of a method for manufacturing a semiconductor device.

FIG. 17A and FIG. 17B are cross-sectional views illustrating an example of a method for manufacturing a semiconductor device.

FIG. 18A and FIG. 18B are cross-sectional views illustrating an example of a method for manufacturing a semiconductor device.

FIG. 19A and FIG. 19B are diagrams illustrating an example of a memory device.

FIG. 20A and FIG. 20B are circuit diagrams each illustrating an example of a memory layer.

FIG. 21 is a timing chart showing an operation example of a memory cell.

FIG. 22A and FIG. 22B are circuit diagrams each illustrating an operation example of a memory cell.

FIG. 23A and FIG. 23B are circuit diagrams each illustrating an operation example of a memory cell.

FIG. 24 is a circuit diagram illustrating a structure example of a semiconductor device.

FIG. 25A and FIG. 25B are diagrams illustrating an example of a semiconductor device.

FIG. 26A and FIG. 26B are diagrams illustrating examples of electronic components.

FIG. 27A to FIG. 27J are diagrams illustrating examples of electronic devices.

FIG. 28A to FIG. 28E are diagrams illustrating examples of electronic devices.

FIG. 29A to FIG. 29C are diagrams illustrating examples of electronic devices.

FIG. 30 is a diagram illustrating an example of a device for space.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and description thereof is not repeated. The same hatching pattern is applied to portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or claims in some cases.

Note that the term “film” and the term “layer” can be interchanged with each other depending on the case or circumstances. For example, the term “conductive layer” can be replaced with the term “conductive film”. As another example, the term “insulating film” can be replaced with the term “insulating layer”.

### Embodiment 1

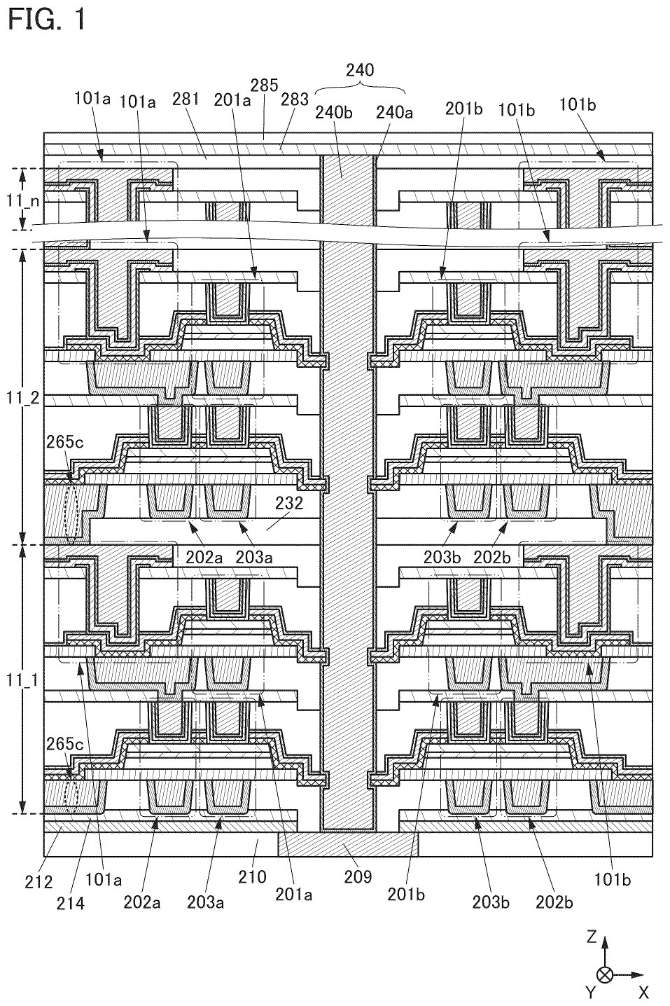

In this embodiment, a semiconductor device of one embodiment of the present invention will be described with reference to FIG. 1 to FIG. 18.

The semiconductor device of one embodiment of the present invention includes a first transistor, a second transistor, and a first insulator over an insulating surface. The first transistor and the second transistor share a first metal oxide over the first insulator and a first conductor over the first metal oxide. The first transistor includes a second conductor and a second insulator which are over the first metal oxide and a third conductor over the second insulator. The second transistor includes a fourth conductor and a third insulator which are over the first metal oxide and a fifth conductor over the third insulator. The side surface of the first insulator includes a portion in contact with the fourth conductor. An end portion of the fourth conductor includes a portion positioned outward from an end portion of the first insulator. The second insulator is positioned between the first conductor and the second conductor. A metal oxide and the third conductor overlap with each other with the second insulator therebetween. The third insulator is positioned between the first conductor and the fourth conductor. The metal oxide and the fifth conductor overlap with each other with the third insulator therebetween.

The metal oxide functions as a channel formation region of the first transistor and also functions as a channel formation region of the second transistor. The first conductor functions as a source or a drain of the first transistor and also functions as a source or a drain of the second transistor.

When the first transistor and the second transistor are adjacent to each other and share the metal oxide and the first conductor, two transistors can be formed in an area smaller than that for two transistors (e.g., the area of 1.5 transistors). Accordingly, the transistors can be arranged at high density, so that high integration of the semiconductor device can be achieved. For example, the semiconductor device can be used for high integration of a memory device such as a variety of memories.

The semiconductor device of one embodiment of the present invention includes a transistor containing a metal oxide in a channel formation region (such a transistor is also referred to as an OS transistor). Since the OS transistor has a low off-state current, a memory device that uses the OS transistor can retain stored data for a long time. In other words, such a memory device does not require refresh operation or has extremely low frequency of the refresh operation, which leads to a sufficient reduction in power consumption of the memory device. An OS transistor has high frequency characteristics and thus can perform reading and writing of a memory device at high speed.

The semiconductor device of one embodiment of the present invention includes a first transistor, a second transistor, a third transistor, a first insulator, a second insulator, a third insulator, and a capacitor. The first transistor and the second transistor share a first metal oxide over the first insulator and a first conductor over the first metal oxide. The first transistor includes a second conductor and a fourth insulator, the second conductor and the fourth insulator being over the first metal oxide, and a third conductor over the fourth insulator, The second transistor includes a fourth conductor and a fifth insulator, the fourth conductor and the fifth insulator being over the first metal oxide, and a fifth conductor over the fifth insulator. The third transistor includes a second metal oxide and a sixth conductor, a seventh conductor, and a sixth insulator, the sixth conductor, the seventh conductor, and the sixth insulator being over the second metal oxide, and an eighth conductor over the sixth insulator, The capacitor includes a ninth conductor, a seventh insulator over the ninth conductor, and a tenth conductor over the seventh insulator. The side surface of the first insulator includes a portion in contact with the fourth conductor. An end portion of the fourth conductor includes a portion positioned outward from an end portion of the first insulator. The second insulator is positioned over the first transistor and over the second transistor. The second conductor and the sixth conductor are electrically connected to each other through an opening provided in the second insulator. The third insulator is positioned over the third transistor. A portion where the ninth conductor, the seventh insulator, and the tenth conductor overlap with one another is positioned over the third insulator. The sixth conductor and the ninth conductor are electrically connected to each other through an opening provided in the third insulator.

Examples of the opening include a groove and a slit. A region where an opening is formed is referred to as an opening portion in some cases.

In the drawings used in embodiments, a sidewall of an insulator in an opening portion in the insulator is illustrated as being substantially perpendicular to a substrate surface or a formation surface, but the sidewall may have a tapered shape.

Note that in this specification and the like, a tapered shape refers to a shape such that at least part of the side surface of a component is inclined with respect to the substrate surface or the surface where the component is formed. For example, a tapered shape preferably includes a region where the angle formed by the inclined side surface and the substrate surface or the surface where a component is formed (hereinafter, such an angle is also referred to as a taper angle in some cases) is less than 90°. Note that the side surface of the component and the substrate surface are not necessarily completely flat and may be substantially flat with a slight curvature or substantially flat with slight unevenness.

The semiconductor device of one embodiment of the present invention is not limited to a structure where all the transistors included in one circuit are formed on the same plane, and two-unit structure where some transistors are provided over the other transistors can be employed. Accordingly, the transistors can be arranged at high density, so that high integration of the semiconductor device can be achieved. For example, the semiconductor device can be used for high integration of a memory device such as a variety of memories.

In a memory device to which one embodiment of the present invention is applied, a structure can be employed in which part of the top surface and part of the side surface of the fourth conductor are directly in contact with a write and read bit line. Similarly, in the semiconductor device of one embodiment of the present invention, a structure can be employed in which part of the top surface and part of the side surface of the ninth conductor are directly in contact with a write and read bit line. With such a structure, a separate electrode for connection does not need to be provided between a write and read bit line and the fourth conductor or the ninth conductor, so that the integration degree of the memory cells can be increased.

### Cross-Sectional Structure Example 1 of Semiconductor Device

Cross-sectional structure examples of the semiconductor device of one embodiment of the present invention will be described with reference to FIG. 1 to FIG. 8.

Note that in FIG. 1 to FIG. 8, the X direction is parallel to the channel length direction of transistors in the drawings, the Y direction is perpendicular to the X direction, and the Z direction is perpendicular to the X direction and the Y direction.

The semiconductor device illustrated in FIG. 1 includes an insulator 210, a conductor 209 embedded in the insulator 210, an insulator 212 over the insulator 210, an insulator 214 over the insulator 212, n layers 11 (n is an integer greater than or equal to 1) (a first layer 11_1 to an n-th layer 11_n) over the insulator 214, a conductor 240 (a conductor 240a and a conductor 240b) which is provided to extended in the Z direction so as to penetrate the n layers 11 and is electrically connected to the conductor 209, an insulator 281 over the n-th layer 11_n, an insulator 283 over the insulator 281 and the conductor 240, and an insulator 285 over the insulator 283. Note that components of the semiconductor device of this embodiment may each have either a single-layer structure or a stacked-layer structure.

The conductor 209 functions as part of a circuit element such as a switch, a transistor, a capacitor, an inductor, a resistor, or a diode, a wiring, an electrode, or a terminal.

Among the n layers 11, FIG. 1 illustrates the first layer 11_1 that is a lowermost layer, a second layer 11_2 over the first layer 11_1, and the n-th layer 11_n that is an uppermost layer.

The semiconductor device of this embodiment can be used as a memory cell (or a memory cell array) of the memory device. Each layer of the n layers 11 corresponds to a memory layer 60 in a memory device that will be described in Embodiment 2. A memory cell array including a plurality of memory cells is provided in each layer of the n layers 11. The conductor 209 is electrically connected to a driver circuit for driving the memory cells provided below the conductor 209. Increasing the number of stacked memory layers 60 (increasing the value of n) can increase the storage capacity of the memory device without increasing the area occupied by the memory cells. Thus, the area occupied per bit is reduced, so that a memory device with a large storage capacity can be obtained with a small size.

Since the n layers 11 have similar structures, the first layer 11_1 is mainly described as an example in this embodiment.

The first layer 11_1 includes transistors 201a, 201b, 202a, 202b, 203a, and 203b and capacitors 101a and 101b.

In the first layer 11_1, a structure on the right side and that on the left side are symmetrical with the conductor 240 as a boundary. That is, in FIG. 1, the transistor 201a and the transistor 201b are symmetrical, the transistor 202a and the transistor 202b are symmetrical, the transistor 203a and the transistor 203b are symmetrical, and the capacitor 101a and the capacitor 101b are symmetrical. In this embodiment, the structure on the left side (the transistors 201a, 202a, and 203a and the capacitor 101a) in the first layer 11_1 is mainly described as an example.

The transistor 202a and the transistor 203a are provided over the insulator 214 and share some layers. A gate of the transistor 202a and a source or a drain of the transistor 201a are electrically connected to each other through a conductor provided over the transistor 202a. One electrode (a lower electrode) of the capacitor 101a is physically and electrically connected to the source or the drain of the transistor 201a. The other electrode (an upper electrode) of the capacitor 101a included in the first layer 11_1 is electrically connected to a source or a drain of the transistor 202a included in the second layer 11_2.

In this manner, it can be said that the first layer 11_1 has a structure in which two layers provided with transistors are stacked. Specifically, the first layer 11_1 includes the transistors 202a and 203a in the first stage (a lower stage) and the transistor 201a and the capacitor 101a in the second stage (an upper stage). Stacking two layers provided with transistors can increase the degree of integration.

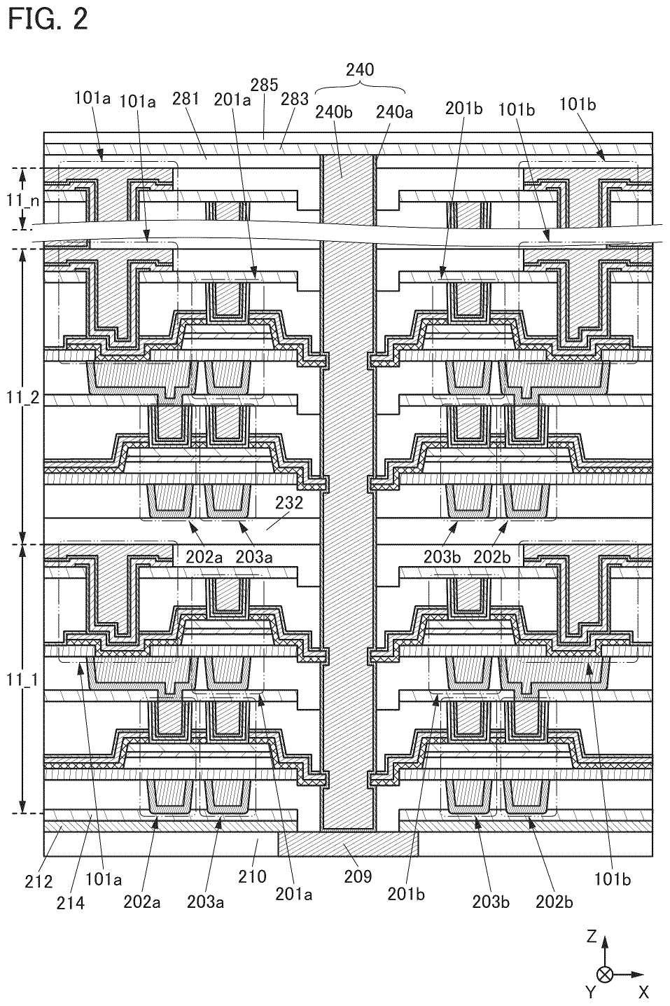

A semiconductor device illustrated in FIG. 2 is a variation example of the semiconductor device illustrated in FIG. 1. Although FIG. 1 illustrates an example in which the source or the drain of the transistor 202a and a conductor 265c are electrically connected to each other, a structure in which the conductor 265c is not provided as illustrated in FIG. 2 may be employed. In that case, the source or the drain of the transistor 202a is preferably provided to be led in the Y direction, in which case a desired potential (e.g., a ground potential) can be easily supplied.

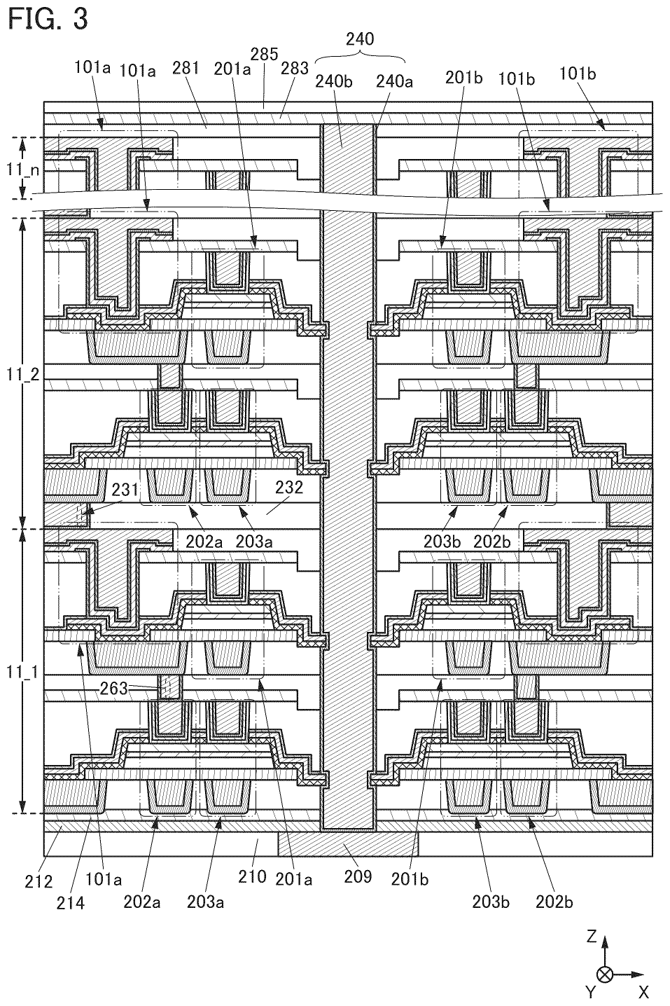

A semiconductor device illustrated in FIG. 3 is a variation example of the semiconductor device illustrated in FIG. 1. Specifically, in FIG. 3, a conductor 263 functioning as a contact plug for electrically connecting the gate of the transistor 202a and the source or the drain of the transistor 201a is used. In FIG. 3, a conductor 231 functioning as a contact plug for electrically connecting the other electrode (the upper electrode) of the capacitor 101a included in the first layer 11_1 and the source or the drain of the transistor 202a included in the second layer 11_2 is used. The conductor 231 is embedded inside an opening provided in an insulator 232 positioned over the capacitor 101a. In this manner, there is no particular limitation on the method for electrically connecting two conductors positioned above and below, and a variety of structures can be employed.

FIG. 3 illustrates an example in which the insulator 212 and the insulator 214 are in contact with the conductor 240.

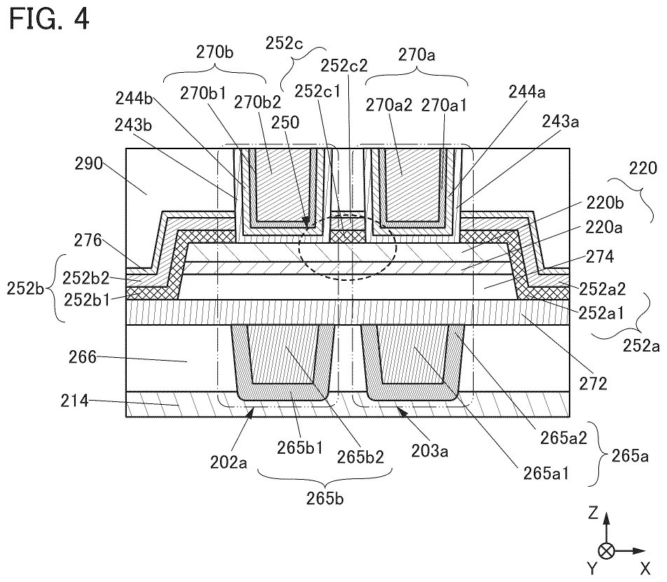

Next, the transistor 202a and the transistor 203a will be described in detail with reference to FIG. 4.

The transistor 202a includes a conductor 265b (a conductor 265b1 and a conductor 265b2) provided over the insulator 214, an insulator 272 over the conductor 265b, an insulator 274 over the insulator 272, an oxide 220 (an oxide 220a and an oxide 220b) over the insulator 274, a conductor 252b (a conductor 252b1 and a conductor 252b2) covering part of the side surface of the insulator 274 and part of the top surface and part of the side surface of the oxide 220, a conductor 252c (a conductor 252c1 and a conductor 252c2) over the oxide 220, an insulator 243b over the oxide 220, an insulator 244b over the insulator 243b, and a conductor 270b (a conductor 270b1 and a conductor 270b2) over the insulator 244b.

The transistor 203a includes a conductor 265a (a conductor 265a1 and a conductor 265a2) provided over the insulator 214, the insulator 272 over the conductor 265a, the insulator 274 over the insulator 272, the oxide 220 over the insulator 274, a conductor 252a (a conductor 252a1 and a conductor 252a2) covering part of the side surface of the insulator 274 and part of the top surface and part of the side surface of the oxide 220, the conductor 252c over the oxide 220, an insulator 243a over the oxide 220, an insulator 244a over the insulator 243a, and a conductor 270a (a conductor 270a1 and a conductor 270a2) over the insulator 244a.

The conductors 265a and 265b are each embedded inside an opening provided in an insulator 266. An insulator 276 is provided over the conductors 252a, 252b, and 252c, and an insulator 290 is provided over the insulator 276. The insulators 243a, 243b, 244a, and 244b and the conductors 270a and 270b are embedded inside openings provided in the insulator 290 and the insulator 276.

The oxide 220 includes a region functioning as a channel formation region of the transistor 202a and a region functioning as a channel formation region of the transistor 203a.

The conductor 252a includes a region that functions as one of a source electrode and a drain electrode of the transistor 203a. The conductor 252b includes a region that functions as one of a source electrode and a drain electrode of the transistor 202a. The conductor 252c includes a region that functions as the other of the source electrode and the drain electrode of the transistor 202a and a region that functions as the other of the source electrode and the drain electrode of the transistor 203a. It can be said that the conductor 252c functions as both the other of the source electrode and the drain electrode of the transistor 202a and the other of the source electrode and the drain electrode of the transistor 203a.

The conductor 270a includes a region that functions as a first gate electrode of the transistor 203a. The insulators 243a and 244a each include a region that functions as a first gate insulator of the transistor 203a.

The conductor 270b includes a region that functions as a first gate electrode of the transistor 202a. The insulators 243b and 244b each include a region that functions as a first gate insulator of the transistor 202a.

The conductor 265a includes a region that functions as a second gate electrode of the transistor 203a. The conductor 265b includes a region that functions as a second gate electrode of the transistor 202a. The insulators 272 and 274 each include a region that functions as a second gate insulator of the transistor 202a and a region that functions as a second gate insulator of the transistor 203a.

The transistor 202a and the transistor 203a are adjacent to each other and share the oxide 220 and the conductor 252c. Thus, two transistors (the transistor 202a and the transistor 203a) can be formed in an area smaller than that for two transistors (e.g., the area of 1.5 transistors). Accordingly, the transistors can be arranged at high density, so that high integration of the semiconductor device can be achieved.

As indicated by a region 250 in FIG. 4, the conductor 252c is provided in a region between the conductor 270a and the conductor 270b. Thus, an n-type region (a low-resistance region) can be formed in a region of the oxide 220 (particularly the oxide 220b) that overlaps with the conductor 252c. Furthermore, current can flow between the transistor 202a and the transistor 203a through the conductor 252c. Thus, as compared with a structure where two transistors using silicon in their semiconductor layers where channels are formed (also referred to as Si transistors) are connected in series, the resistance components between the transistor 202a and the transistor 203a can be significantly reduced.

Note that the structures of the transistor 202a and the transistor 203a are similar to that of the transistor 201a except that they share the oxide 220 and the conductor 252c. A material and a manufacturing method that can be used for the transistor 202a and the transistor 203a are also similar to those for the transistor 201a. Thus, a material and a manufacturing method of a transistor included in the semiconductor device of this embodiment are collectively described in the description of the transistor 201a described later.

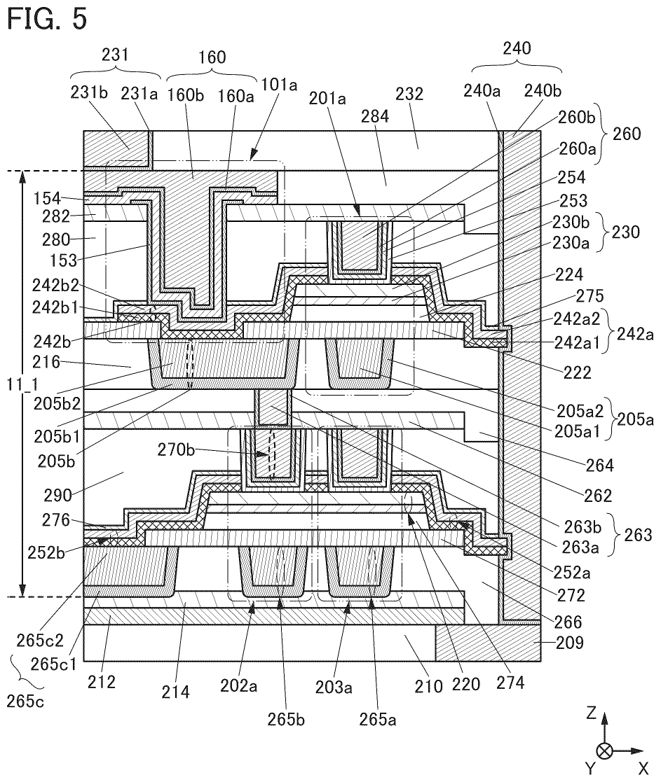

FIG. 5 illustrates an enlarged view of the left half of the structure of the first layer 11_1 in FIG. 3 (the conductor 240 and the structure on the left side of the conductor 240).

As illustrated in FIG. 5, the transistor 202a and the transistor 203a are provided over the insulator 214. The conductor 252b included in the transistor 202a is electrically connected to the conductor 265c (a conductor 265c1 and a conductor 265c2).

An insulator 262 is provided over the insulator 290, the transistor 202a, and the transistor 203a, and an insulator 264 is provided over the insulator 262. The conductor 263 (a conductor 263a and a conductor 263b) is provided inside an opening provided in the insulator 262 and the insulator 264. Furthermore, the transistor 201a and the capacitor 101a are provided over the insulator 264.

The transistor 201a includes a conductor 205a (a conductor 205a1 and a conductor 205a2) provided over the insulator 264, an insulator 222 over the conductor 205a, an insulator 224 over the insulator 222, an oxide 230 (an oxide 230a and an oxide 230b) over the insulator 224, a conductor 242a (a conductor 242a1 and a conductor 242a2) and a conductor 242b (a conductor 242b1 and a conductor 242b2) each covering part of the side surface of the insulator 224 and part of the top surface and part of the side surface of the oxide 230, an insulator 253 over the oxide 230, an insulator 254 over the insulator 253, and a conductor 260 (a conductor 260a and a conductor 260b) over the insulator 254.

The conductor 205a and a conductor 205b are embedded inside openings provided in an insulator 216. An insulator 275 is provided over the conductors 242a and 242b, and an insulator 280 is provided over the insulator 275. The insulators 253 and 254 and the conductor 260 are embedded inside an opening provided in the insulator 280 and the insulator 275. An insulator 282 is provided over the insulator 280 and the conductor 260.

The oxide 230 includes a region functioning as a channel formation region of the transistor 201a.

The conductor 242a includes a region that functions as one of a source electrode and a drain electrode of the transistor 201a. The conductor 242b includes a region that functions as the other of the source electrode and the drain electrode of the transistor 201a.

The conductor 260 includes a region that functions as a first gate electrode of the transistor 201a. The insulators 253 and 254 each include a region that functions as a first gate insulator of the transistor 201a.

The conductor 205a includes a region that functions as a second gate electrode of the transistor 201a. The insulators 222 and 224 each include a region that functions as a second gate insulator of the transistor 201a.

The conductor 242b included in the transistor 201a is electrically connected to the conductor 270b included in the transistor 202a. Specifically, the conductor 242b is electrically connected to the conductor 270b through the conductor 205b (a conductor 205b1 and a conductor 205b2) and the conductor 263.

The capacitor 101a includes a conductor 153 over the conductor 242b, an insulator 154 over the conductor 153, and a conductor 160 (a conductor 160a and a conductor 160b) over the insulator 154.

At least part of the conductor 153, part of the insulator 154, and part of the conductor 160 are provided in an opening provided inside the insulator 275, the insulator 280, and the insulator 282. End portions of the conductor 153, the insulator 154, and the conductor 160 are positioned over the insulator 282. The insulator 154 is provided to cover the end portion of the conductor 153. This enables the conductor 153 and the conductor 160 to be electrically insulated from each other. The deeper the opening provided in the insulator 275, the insulator 280, and the insulator 282 (that is, the larger the thickness of one or more of the insulators 275, 280, and 282), the more the capacitance of the capacitor 101a can be increased. Increasing the capacitance per unit area of the capacitor 101a can promote miniaturization or higher integration of the semiconductor device.

The conductor 231 (a conductor 231a and a conductor 231b) is provided over the conductor 160, whereby the conductor 160 and the source or the drain of the transistor 202a in the upper stage can be electrically connected to each other. Note that as illustrated in FIG. 1, the conductor 160 and the source or the drain of the transistor 202a in the upper stage can be electrically connected to each other not through the conductor 231.

The conductor 153 includes a region that functions as the one electrode (the lower electrode) of the capacitor 101a. The insulator 154 includes a region that functions as a dielectric of the capacitor 101a. The conductor 160 includes a region that functions as the other electrode (the upper electrode) of the capacitor 101a. The capacitor 101a forms an MIM (Metal-Insulator-Metal) capacitor.

The conductor 242a including a region that functions as the one of the source electrode and the drain electrode of the transistor 201a extends beyond the oxide 230 that functions as a semiconductor layer. Thus, the conductor 242a also functions as a wiring. In FIG. 5, for example, part of the top surface, part of the side surface, and part of the bottom surface of the conductor 242a are electrically connected to the conductor 240 extending in the Z direction.

Similarly, the conductor 252a including a region that functions as the one of the source electrode and the drain electrode of the transistor 203a extends beyond the oxide 220 functioning as a semiconductor layer. Thus, the conductor 252a also functions as a wiring. In FIG. 5, for example, part of the top surface, part of the side surface, and part of the bottom surface of the conductor 252a are electrically connected to the conductor 240 extending in the Z direction.

When the conductor 240 is directly in contact with both at least one of the top surface, the side surface, and the bottom surface of the conductor 242a and at least one of the top surface, the side surface, and the bottom surface of the conductor 252a, a separate electrode for connection does not need to be provided, and thus the area occupied by the memory cell arrays can be reduced. In addition, the integration degree of the memory cells can be improved and the storage capacity thereof can be increased. Note that the conductor 240 is preferably in contact with two or more of the top surface, the side surface, and the bottom surface of the conductor 242a. Similarly, the conductor 240 is preferably in contact with two or more of the top surface, the side surface, and the bottom surface of the conductor 252a. When the conductor 240 is in contact with a plurality of surfaces of the conductor 242a or the conductor 252a, the contact resistance between the conductor 240) and the conductor 242a or the conductor 252a can be reduced.

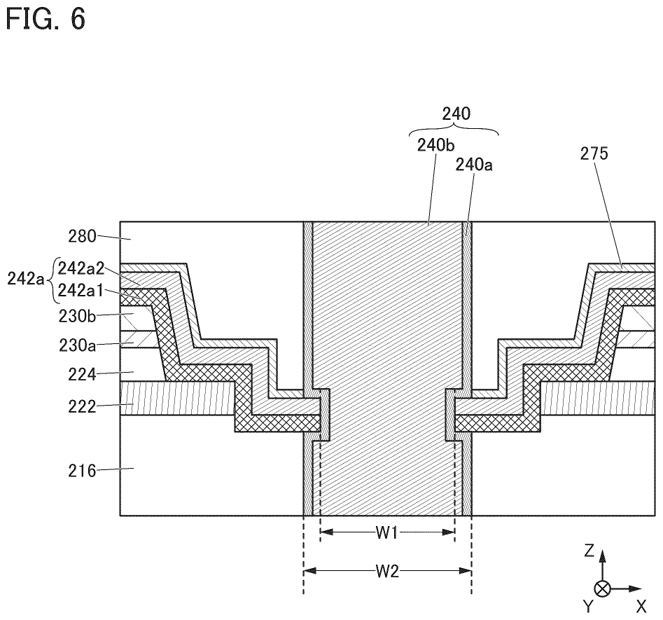

FIG. 6 illustrates an enlarged view of a region where the conductor 240 and the conductor 242a are in contact with each other and its vicinity. As illustrated in FIG. 6, the conductor 240) includes a region having a width W1 and a region having a width W2. The width W1 corresponds to the distance between the conductor 242a included in the transistor 201a and the conductor 242a included in the transistor 201b. The width W2 corresponds to, for example, the distance between an interface between the insulator 280 and the conductor 240a on the transistor 201a side and an interface between the insulator 280) and the conductor 240a on the transistor 201b side.

As illustrated in FIG. 6, the width W2 is preferably larger than the width W1. In this structure, the conductor 240 is in contact with at least part of the top surface and part of the side surface of the conductor 242a. Thus, the area of the region where the conductor 240) and the conductor 242a are in contact with each other can be increased. Note that in this specification and the like, a contact between the conductor 240) and the conductor 242a is sometimes referred to as a top-side contact. As illustrated in FIG. 6, the conductor 240 may be in contact with part of the bottom surface of the conductor 242a. With such a structure, the area of the region where the conductor 240) and the conductor 242a are in contact with each other can be further increased.

Note that the contents described with reference to FIG. 6 can be similar to those of a region where the conductor 240 and the conductor 252a are in contact with each other and its vicinity.

In FIG. 5, an end portion of the insulator 262 is positioned inward from end portions of the insulators 266, 290, 264, 216, 280, 284, and 232. Similarly, an end portion of the insulator 282 is positioned inward from the end portions of the insulators 266, 290, 264, 216, 280, 284, and 232. As described above, in a cross-sectional view, the end portion of the insulator 262 and the end portion of the insulator 282 can each be positioned inward from one or more of the end portions of the insulators 266, 290, 264, 216, 280, 284, and 232.

The insulators 266, 290, 264, 216, 280, 284, and 232 function as interlayer films. For example, the insulators 266, 290, 264, 216, 280, 284, and 232 each preferably contain one or both of silicon oxide and silicon oxynitride.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

Meanwhile, the insulator 262 and the insulator 282 each preferably function as a barrier insulator of the transistor. For example, each of the insulator 262 and the insulator 282 preferably contains one or both of aluminum oxide and hafnium oxide.

Note that in this specification and the like, a barrier insulator refers to an insulator having a barrier property. A barrier property in this specification and the like means a function of inhibiting diffusion of a targeted substance (also referred to as having low permeability). Alternatively, a barrier property in this specification and the like means a function of capturing and fixing (also referred to as gettering) a targeted substance.

Here, aluminum oxide and hafnium oxide are sometimes more difficult to etch than silicon oxide or silicon oxynitride. Aluminum oxide and hafnium oxide are each a hard-to-etch material.

In the manufacturing process of the semiconductor device in this embodiment, an opening portion needs to be provided in a stacked-layer structure of insulators before the conductor 240 is provided. At this time, it is sometimes difficult to process the insulator 262 and the insulator 282 with the same etching gas as the insulators 266, 290, 264, 216, 280, and 284. Thus, in the method for manufacturing the semiconductor device of one embodiment of the present invention, as the formation step of the insulator 262 and the formation step of the insulator 282, the processing step is performed subsequent to the deposition step, and then, the formation step of a next layer (e.g., the deposition step) is performed. Then, in the processing step of the stacked-layer structure of the insulators immediately before the conductor 240 is provided, an opening is provided in an insulator formed using a material that can be easily etched, such as the insulators 266, 290, 264, 216, 280, and 284, as compared with the insulator 262 and the insulator 282. As described above, when the insulator formed using a hard-to-etch material is opened in advance and the other insulators are collectively opened before the conductor 240 is provided, the margin of the process can be increased. In addition, the yield in formation of the openings can be increased, and the productivity of the semiconductor device can be improved.

In FIG. 5 and the like, a depressed portion is provided in each of a region of the insulator 280 that does not overlap with the insulator 282 and a region of the insulator 290 that does not overlap with the insulator 262. Depending on the etching condition of the insulator 282 or the insulator 262, part of the insulator 280 or part of the insulator 290 is removed at the time of processing the insulator 282 or the insulator 262, so that a depressed portion is formed in some cases. Note that each of the insulator 280 and the insulator 290 does not necessarily have a depressed portion.

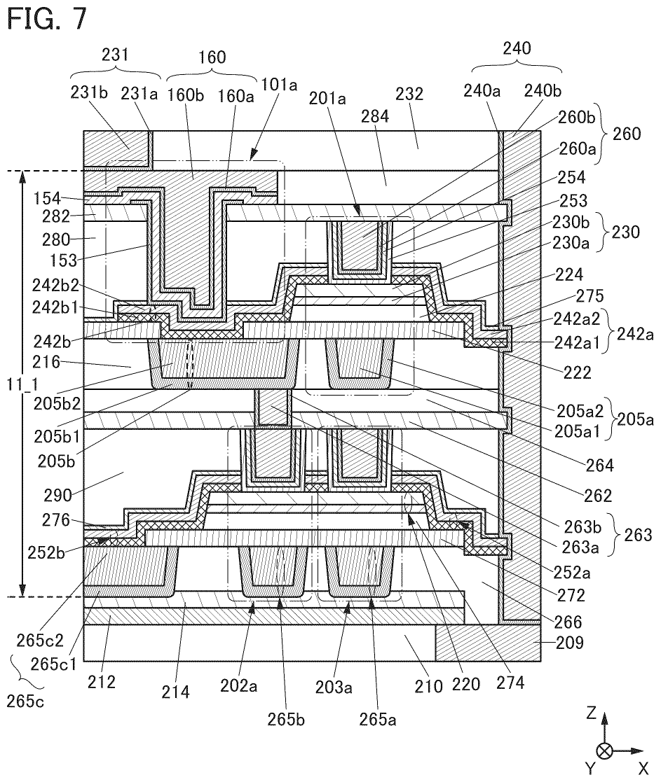

Note that in FIG. 7, the end portion of the insulator 262 is positioned outward from the end portions of the insulators 266, 290, 264, 216, 280, 284, and 232. Similarly, the end portion of the insulator 282 is positioned outward from the end portions of the insulators 266, 290, 264, 216, 280, 284, and 232. As described above, the end portion of the insulator 262 and the end portion of the insulator 282 can each be positioned outward from one or more of the end portions of the insulators 266, 290, 264, 216, 280, 284, and 232.

Here, as illustrated in FIG. 1 and the like, in the case where an opening portion for providing the conductor 240 is provided in a stacked-layer structure of insulators after n layers of memory cells are stacked, the width of the opening portion (also referred to as an opening diameter, which corresponds to the length of the X-axis direction in FIG. 1 and the like) is sometimes difficult to keep constant because the opening portion needs to be formed deeply. For example, the width of the upper side (an n-th layer side) of the opening portion is likely to be wide, and the width of the lower side (a first layer side) of the opening portion is likely to be narrowed. Here, when each of the end portion of the insulator 262 and the end portion of the insulator 282 is provided so as to protrude into the opening portion, the opening portion can be inhibited from being etched excessively in some cases. Thus, a variation in the opening diameter can be suppressed. Furthermore, a sufficient width can be ensured even in the bottom portion of the opening portion while the width of the upper portion of the opening portion is not excessively widened.

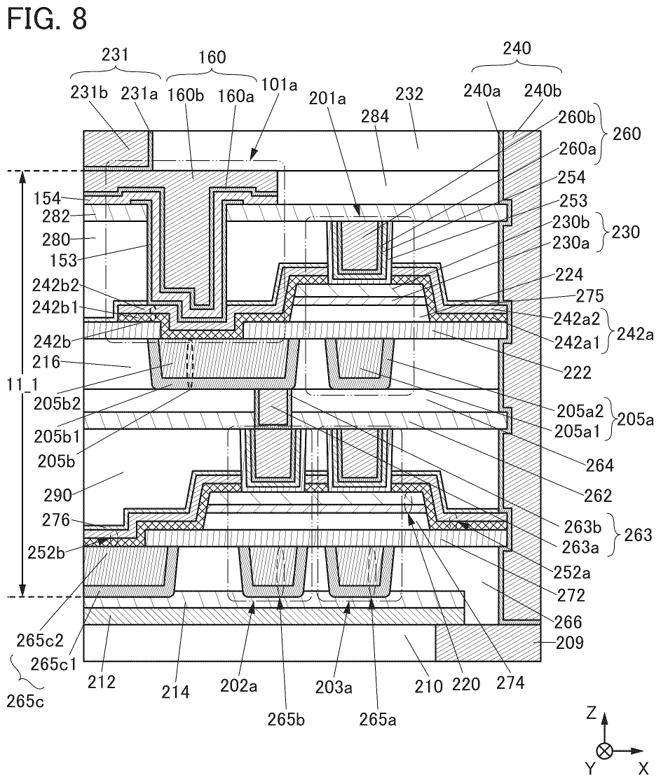

Note that FIG. 7 and FIG. 8 each illustrate an example in which the end portion of the insulator 262 and the end portion of the insulator 282 are aligned or substantially aligned with an end portion of the conductor 242a and an end portion of the conductor 252a. FIG. 8 illustrates an example in which an end portion of the insulator 272 and an end portion of the insulator 222 are substantially aligned with the end portion of the conductor 242a and the end portion of the conductor 252a. The semiconductor device of one embodiment of the present invention is not limited to these structures. For example, the end portions of the insulators 272, 222, 262, and 282 may be positioned outward or inward from one or both of the end portion of the conductor 242a and the end portion of the conductor 252a.

In the case where end portions are aligned or substantially aligned with each other and the case where top surface shapes are the same or substantially the same in a cross-sectional view, it can be said that outlines of stacked layers at least partly overlap with each other in a top view. In such a case, the case of processing an upper layer and a lower layer with the use of the same mask pattern or mask patterns that are partly the same is included, for example. However, in some cases, the outlines do not completely overlap with each other and part of the upper layer is positioned inward from the lower layer or part of the upper layer is positioned outward from the lower layer; such a case is also represented by the expression “end portions are substantially aligned with each other” or “top surface shapes are substantially the same”.

Note that in FIG. 5, the end portion of the insulator 222 and the end portion of the insulator 272 are positioned inward from the end portions of the insulators 266, 290, 264, 216, 280, 284, and 232. The structures of the insulator 222 and the insulator 272 are not limited thereto. For example, in FIG. 8, the end portion of the insulator 222 and the end portion of the insulator 272 are each positioned outward from the end portions of the insulators 266, 290, 264, 216, 280, 284, and 232.

As illustrated in FIG. 5, in the case where the end portion of the insulator 272 is positioned inward from the end portion of the conductor 252a, the conductor 240 can be in contact with the top surface, the side surface, and the bottom surface of the conductor 252a, so that the contact resistance between the conductor 240 and the conductor 252a can be reduced. Similarly, in the case where the end portion of the insulator 222 is positioned inward from the end portion of the conductor 242a, the conductor 240 can be in contact with the top surface, the side surface, and the bottom surface of the conductor 242a, so that contact resistance between the conductor 240 and the conductor 242a can be reduced.

In FIG. 5 and the like, a depressed portion is provided in a region of the insulator 216 that does not overlap with the insulator 222 and a region of the insulator 266 that does not overlap with the insulator 272. Depending on the etching condition of the insulator 222 or the insulator 272, part of the insulator 216 or part of the insulator 266 is removed at the time of processing the insulator 222 or the insulator 272, so that a depressed portion is formed in some cases. Note that each of the insulator 216 and the insulator 266 does not necessarily have a depressed portion.

As illustrated in FIG. 8, in the case where the end portion of the insulator 272 is substantially aligned with the end portion of the conductor 252a or is positioned outward from the end portion of the conductor 252a, the insulator 266 can have a structure where no depressed portion is included in a completed semiconductor device. Similarly, in the case where the end portion of the insulator 222 is substantially aligned with the end portion of the conductor 242a or is positioned outward from the end portion of the conductor 242a, the insulator 216 can have a structure where no depressed portion is included in a completed semiconductor device. In the depressed portion provided in the insulator, a variation in shape is likely to occur in some cases. Thus, the variation in shape of the semiconductor device can be reduced when the depressed portion is not left in each of the insulator 266 and the insulator 216.

Although the structure in which the insulator 282 is opened in advance is described above as an example, a method for achieving the structures illustrated in FIG. 5, FIG. 7, and FIG. 8 is not limited thereto. For example, in the case where the etching rate of the insulator 282 is different from that of the insulator 280, even when the insulators are opened at the same time, the end portion of the insulator 282 and the end portion of the insulator 280 are not aligned with each other in a cross-sectional view in some cases. For example, when the insulator 282 and the insulator 280 are opened at the same time, the insulator 280 and the insulator 282 each having a shape illustrated in FIG. 7 can be formed in some cases. The semiconductor device manufactured by such a method is also included in one embodiment of the present invention.

Other materials that can be used for the insulators 262, 282, 266, 290, 264, 216, 280, and 284 will be described later.

Next, transistors included in the semiconductor device of this embodiment will be described in detail.

Note that although the components of the transistor 201a are mainly described as an example below, the same can also be applied to the components of the transistors 202a and 203a. That is, for example, the description on the conductor 205, the insulator 222, the insulator 224, the oxide 230, the conductor 242, the insulator 253, the insulator 254, and the conductor 260 can also be applied to the conductor 265, the insulator 272, the insulator 274, the oxide 220, the conductor 252, the insulator 243, the insulator 244, and the conductor 270.

The oxide 230 preferably includes the oxide 230a over the insulator 224 and the oxide 230b over the oxide 230a. Including the oxide 230a under the oxide 230b makes it possible to inhibit diffusion of impurities into the oxide 230b from components formed below the oxide 230a.

Although an example in which the oxide 230 has a two-layer structure of the oxide 230a and the oxide 230b is described in this embodiment, one embodiment of the present invention is not limited thereto. For example, the oxide 230 may have a single-layer structure of the oxide 230b or a stacked-layer structure of three or more layers.

In the oxide 230b, a channel formation region and a source region and a drain region provided to sandwich the channel formation region therebetween, which are in the transistor 201a, are provided. At least part of the channel formation region overlaps with the conductor 260. One of a source region and a drain region overlaps with the conductor 242a, and the other overlaps with the conductor 242b.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of impurities such as hydrogen, nitrogen, or a metal element, and thus are low-resistance regions with a high carrier concentration. In other words, the source region and the drain region are n-type regions (low resistance regions) having higher carrier concentrations than the channel formation region.

Note that the carrier concentration in the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. Note that the lower limit of the carrier concentration of the channel formation region is not particularly limited and can be, for example, 1×10⁻⁹ cm⁻³.

In order to reduce the carrier concentration in the oxide 230b, the impurity concentration in the oxide 230b is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration (or a metal oxide) may be referred to as a highly purified intrinsic or substantially highly purified intrinsic oxide semiconductor (or a metal oxide).

Thus, a reduction in the impurity concentration in the oxide 230b is effective in achieving stable electrical characteristics of the transistor 201a. Furthermore, in order to reduce the impurity concentration in the oxide 230b, the impurity concentration in an adjacent film is also preferably reduced. Examples of impurities include hydrogen, nitrogen, an alkali metal, an alkaline earth metal, iron, nickel, and silicon. Note that an impurity in the oxide 230b refers to, for example, an element other than the main components of the oxide 230b. For example, an element with a concentration lower than 0.1 atomic % can be regarded as an impurity.

Note that the channel formation region, the source region, and the drain region may be formed not only in the oxide 230b but also in the oxide 230a.

In the oxide 230, the boundaries between the regions are difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (such a metal oxide is hereinafter also referred to as an oxide semiconductor) is preferably used for the oxide 230 (the oxide 230a and the oxide 230b).

The metal oxide functioning as a semiconductor preferably has a band gap of 2 eV or higher, further preferably 2.5 eV or higher. With the use of a metal oxide having a wide bandgap, the off-state current of the transistor can be reduced.

As the oxide 230, a metal oxide such as indium oxide, gallium oxide, or zinc oxide is preferably used, for example. Alternatively, as the oxide 230, a metal oxide containing two or three selected from indium, an element M, and zinc is preferably used, for example. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin. Note that a metal oxide containing indium, the element M, and zinc is referred to as In-M-Zn oxide in some cases.

The oxide 230 preferably has a stacked-layer structure of a plurality of oxide layers with different chemical compositions. For example, the atomic ratio of the element M to a metal element that is a main component in the metal oxide used as the oxide 230a is preferably greater than the atomic ratio of the element M to a metal element that is a main component in the metal oxide used as the oxide 230b. Moreover, the atomic ratio of the element M to In in the metal oxide used as the oxide 230a is preferably greater than the atomic ratio of the element M to In in the metal oxide used as the oxide 230b. With this structure, impurities and oxygen can be inhibited from diffusing into the oxide 230b from the components formed below the oxide 230a.

Furthermore, the atomic ratio of In to the element M in the metal oxide used as the oxide 230b is preferably greater than the atomic ratio of In to the element M in the metal oxide used as the oxide 230a. With this structure, the transistor 201a can have a high on-state current and high frequency characteristics.

When the oxide 230a and the oxide 230b contain a common element as the main component besides oxygen, the density of defect states at an interface between the oxide 230a and the oxide 230b can be made low. Thus, the influence of interface scattering on carrier conduction is small, and the transistor 201a can have a high on-state current and excellent frequency characteristics.

Specifically, as the oxide 230a, a metal oxide with a composition of In:M:Zn=1:3:4 [atomic ratio] or in the neighborhood thereof, or a composition of In:M:Zn=1:1:0.5 [atomic ratio] or in the neighborhood thereof can be used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of +30% of an intended atomic ratio. Gallium is preferably used as the element M. In the case where a single layer of the oxide 230b is provided as the oxide 230, a metal oxide that can be used as the oxide 230a may be used as the oxide 230b.

When the metal oxide is deposited by a sputtering method, the above atomic ratio is not limited to the atomic ratio of the deposited metal oxide and may be the atomic ratio of a sputtering target used for depositing the metal oxide.

The oxide 230b preferably has crystallinity. It is particularly preferable to use a CAAC-OS (c-axis aligned crystalline oxide semiconductor) as the oxide 230b.

The CAAC-OS is a metal oxide having a dense structure with high crystallinity and a small amount of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide 230b, oxygen extraction from the oxide 230b by the source electrode or the drain electrode can be inhibited. This can reduce oxygen extraction from the oxide 230b even when heat treatment is performed; thus, the transistor 201a is stable with respect to high temperatures in a manufacturing process (what is called thermal budget).

If impurities and oxygen vacancies exist in a region of an oxide semiconductor where a channel is formed, a transistor using the oxide semiconductor may have variable electrical characteristics and poor reliability. In some cases, hydrogen in the vicinity of an oxygen vacancy forms a defect that is the oxygen vacancy into which hydrogen enters (hereinafter sometimes referred to as V_{O}H), which generates an electron serving as a carrier. Therefore, when the region of the oxide semiconductor where a channel is formed includes oxygen vacancies, the transistor tends to have normally-on characteristics (even when no voltage is applied to the gate electrode, the channel exists and current flows through the transistor). Thus, impurities, oxygen vacancies, and V_{O}H are preferably reduced as much as possible in the region of the oxide semiconductor where a channel is formed. In other words, it is preferable that the region of the oxide semiconductor where a channel is formed have a reduced carrier concentration and be of an i-type (intrinsic) or substantially i-type.

As a countermeasure to the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor 201a. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Thus, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and V_{O}H in the channel formation region of the oxide semiconductor are preferably reduced. Supply of an excess amount of oxygen to the source region and the drain region and excessive reduction in the amount of V_{O}H in the source region and the drain region are preferably inhibited. A reduction in the conductivity of the conductor 260, the conductor 242a, the conductor 242b, and the like is preferably inhibited. For example, oxidation of the conductor 260, the conductor 242a, the conductor 242b, and the like is preferably inhibited. Note that hydrogen in an oxide semiconductor can form V_{O}H; thus, the hydrogen concentration needs to be reduced in order to reduce the amount of V_{O}H.

The semiconductor device of this embodiment has a structure in which the hydrogen concentration in the channel formation region is reduced, oxidation of the conductor 242a, the conductor 242b, and the conductor 260 is inhibited, and the hydrogen concentration in the source region and drain region is inhibited from being reduced.

The insulator 253 in contact with the channel formation region of the oxide 230b preferably has a function of capturing and fixing hydrogen. Thus, the hydrogen concentration in the channel formation region of the oxide 230b can be reduced. Accordingly, V_{O}H in the channel formation region can be reduced, so that the channel formation region can be an i-type or substantially i-type region.

Examples of an insulator having a function of capturing and fixing hydrogen include a metal oxide having an amorphous structure. For the insulator 253, for example, a metal oxide, such as magnesium oxide or an oxide containing one or both of aluminum and hafnium, is preferably used. In such a metal oxide having an amorphous structure, an oxygen atom has a dangling bond and sometimes has a property of capturing or fixing hydrogen with the dangling bond. That is, the metal oxide having an amorphous structure is regarded as having high capability of capturing or fixing hydrogen.

A high dielectric constant (high-k) material is preferably used for the insulator 253. An example of the high-k material is an oxide containing one or both of aluminum and hafnium. With the use of a high-k material for the insulator 253, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 253, an oxide containing one or both of aluminum and hafnium is preferably used, an oxide containing one or both of aluminum and hafnium and having an amorphous structure is further preferably used, and hafnium oxide having an amorphous structure is still further preferably used. In this embodiment, hafnium oxide is used for the insulator 253. In this case, the insulator 253 is an insulator that contains at least oxygen and hafnium. The hafnium oxide has an amorphous structure. In this case, the insulator 253 has an amorphous structure.

Besides, as the insulator 253, an insulator having a thermally stable structure such as silicon oxide or silicon oxynitride may be used. For example, for the insulator 253, a stacked-layer structure including aluminum oxide and silicon oxide or silicon oxynitride over the aluminum oxide may be employed. Alternatively, for the insulator 253, a stacked-layer structure including aluminum oxide, silicon oxide or silicon oxynitride over the aluminum oxide, and hafnium oxide over the silicon oxide or the silicon oxynitride may be employed, for example.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 253, the insulator 254, and the insulator 275, for example.

Examples of a barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 253, the insulator 254, and the insulator 275 preferably has a single-layer structure or a stacked-layer structure of the barrier insulator against oxygen.

The insulator 253 preferably has a barrier property against oxygen. The insulator 253 is preferably less permeable to oxygen than at least the insulator 280 is. The insulator 253 includes a region in contact with the side surface of the conductor 242a and the side surface of the conductor 242b. When the insulator 253 has a barrier property against oxygen, oxidation of the side surfaces of the conductor 242a and the conductor 242b and formation of oxide films on the side surfaces can be inhibited. Accordingly, a decrease in the on-state current or field-effect mobility of the transistor 201a can be inhibited.

The insulator 253 is provided in contact with the top surface and the side surface of the oxide 230b, the side surface of the oxide 230a, the side surface of the insulator 224, and the top surface of the insulator 222. When the insulator 253 has a barrier property against oxygen, release of oxygen from the channel formation region of the oxide 230b caused by heat treatment or the like can be inhibited. This can reduce formation of oxygen vacancies in the oxide 230a and the oxide 230b.

Even when an excess amount of oxygen is contained in the insulator 280, oxygen can be inhibited from being excessively supplied to the oxide 230a and the oxide 230b. Thus, it is possible to inhibit excessive oxidation of the source region and the drain region and a decrease in the on-state current or field-effect mobility of the transistor 201a.

An oxide containing one or both of aluminum and hafnium has a barrier property against oxygen and thus can be suitably used for the insulator 253.

The insulator 254 preferably has a barrier property against oxygen. The insulator 254 is provided between the conductor 260 and the channel formation region of the oxide 230 and between the insulator 280 and the conductor 260. Such a structure can inhibit oxygen contained in the channel formation region of the oxide 230 from diffusing into the conductor 260 and formation of oxygen vacancies in the channel formation region of the oxide 230. Oxygen contained in the oxide 230 and oxygen contained in the insulator 280 can be inhibited from diffusing into the conductor 260 and oxidizing the conductor 260. The insulator 254 is preferably less permeable to oxygen than at least the insulator 280 is. For example, silicon nitride is preferably used for the insulator 254. In this case, the insulator 254 is an insulator that contains at least nitrogen and silicon.

The insulator 254 preferably has a barrier property against hydrogen. This can prevent diffusion of impurities such as hydrogen contained in the conductor 260 into the oxide 230b.

The insulator 275 preferably has a barrier property against oxygen. The insulator 275 is provided between the insulator 280 and the conductor 242a and between the insulator 280 and the conductor 242b. The structure can inhibit diffusion of oxygen contained in the insulator 280 into the conductor 242a and the conductor 242b. Thus, the conductor 242a and the conductor 242b can be inhibited from being oxidized by oxygen contained in the insulator 280, so that an increase in resistivity and a reduction in on-state current can be inhibited. The insulator 275 is preferably less permeable to oxygen than at least the insulator 280 is. For example, silicon nitride is preferably used for the insulator 275. In this case, the insulator 275 is an insulator that contains at least nitrogen and silicon.

In order to prevent a reduction in hydrogen concentration in the source region and the drain region in the oxide 220, a barrier insulator against hydrogen is preferably provided in the vicinity of each of the source region and the drain region. In the semiconductor device described in this embodiment, the barrier insulator against hydrogen is, for example, the insulator 275.

Examples of the barrier insulator against hydrogen include an oxide such as aluminum oxide, hafnium oxide, or tantalum oxide and a nitride such as silicon nitride. For example, the insulator 275 preferably has a single-layer structure or a stacked-layer structure of the above barrier insulator against hydrogen.

The insulator 275 preferably has a barrier property against hydrogen. When the insulator 275 has a barrier property against hydrogen, capturing and fixing of hydrogen in the source region and the drain region by the insulator 253 can be inhibited. Thus, the source region and the drain region can be n-type regions.

With the above structure, the channel formation region can be an i-type or substantially i-type region, and the source region and the drain region can be n-type regions; therefore, a semiconductor device with favorable electrical characteristics can be provided. The semiconductor device with the above structure can have favorable electrical characteristics even when miniaturized or highly integrated. Miniaturization of the transistor 201a can improve the high frequency characteristics. Specifically, the cutoff frequency can be improved.

Each of the insulator 253 and the insulator 254 functions as part of a gate insulator. The insulator 253 and the insulator 254 are provided in the opening formed in the insulator 280 and the like, together with the conductor 260. Each of the thickness of the insulator 253 and the thickness of the insulator 254 is preferably small for miniaturization of the transistor 201a. The thickness of the insulator 253 is preferably greater than or equal to 0.1 nm and less than or equal to 5.0 nm, further preferably greater than or equal to 0.5 nm and less than or equal to 5.0 nm, still further preferably greater than or equal to 1.0 nm and less than 5.0 nm, yet still further preferably greater than or equal to 1.0 nm and less than or equal to 3.0 nm. The thickness of the insulator 254 is preferably greater than or equal to 0.1 nm and less than or equal to 5.0 nm, further preferably greater than or equal to 0.5 nm and less than or equal to 3.0 nm, still further preferably greater than or equal to 1.0 nm and less than or equal to 3.0 nm. Note that at least part of each of the insulator 253 and the insulator 254 includes a region having a thickness like the above-described thickness.

To form the insulator 253 having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables an atomic layer to be deposited one by one, has advantages such as deposition of an extremely thin film, deposition on a component with a high aspect ratio, deposition of a film with a small number of defects such as pinholes, deposition with excellent coverage, and low-temperature deposition. Therefore, the insulator 253 can be deposited on the side surface of the opening portion formed in the insulator 280 and the like and side end portions of the conductors 242a and 242b, with a small thickness like the above-described thickness and favorable coverage.

Note that some of precursors usable in an ALD method contain carbon or the like. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

For example, silicon nitride deposited by a PEALD method can be used for the insulator 254.

Note that when an insulator having a function of inhibiting the passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the semiconductor device.

In addition to the above structure, the semiconductor device of this embodiment preferably has a structure in which hydrogen is inhibited from entering the transistor 201a. For example, one or both of upper and lower insulators having a function of inhibiting diffusion of hydrogen is/are preferably provided to cover the transistor 201a. In the semiconductor device described in this embodiment, the insulator corresponds to, for example, the insulator 212.

As the insulator 212, an insulator having a function of inhibiting diffusion of hydrogen is preferably used. This can inhibit diffusion of hydrogen into the transistor 201a from below the insulator 212. The insulator 212 can be formed using an insulator that can be used as the insulator 275.

One or more of the insulator 212, the insulator 214, the insulator 262, the insulator 282, the insulator 283, the insulator 284, and the insulator 285 preferably function(s) as (a) barrier insulator(s) that inhibit(s) diffusion of impurities such as water and hydrogen from the substrate side or from above the transistor 201a into the transistor 201a. Thus, for one or more of the insulator 212, the insulator 214, the insulator 262, the insulator 282, the insulator 283, the insulator 284, and the insulator 285, it is preferable to contain an insulating material having a function of inhibiting diffusion of impurities such as hydrogen atoms, hydrogen molecules, water molecules, nitrogen atoms, nitrogen molecules, nitrogen oxide molecules (e.g., N₂O, NO, and NO₂), and copper atoms (an insulating material through which the impurities are less likely to pass). Alternatively, it is preferable to contain an insulating material having a function of inhibiting diffusion of oxygen (e.g., at least one of oxygen atoms, oxygen molecules, and the like) (an insulating material through which the oxygen is less likely to pass).

An insulator having a function of inhibiting diffusion of oxygen and impurities such as water and hydrogen is preferably used as the insulator 212, the insulator 214, the insulator 262, the insulator 282, the insulator 283, the insulator 284, and the insulator 285; for example, aluminum oxide, magnesium oxide, hafnium oxide, gallium oxide, indium gallium zinc oxide, silicon nitride, or silicon nitride oxide can be used. For example, silicon nitride, which has a higher hydrogen barrier property, is preferably used for the insulator 212. For example, aluminum oxide, magnesium oxide, or the like, which has a high capability of capturing or fixing hydrogen, is preferably used for each of the insulator 214, the insulator 262, the insulator 282, the insulator 283, the insulator 284, and the insulator 285. In this case, impurities such as water and hydrogen can be inhibited from diffusing to the transistor 201a side from the substrate side through the insulator 212 and the insulator 214. Impurities such as water and hydrogen can be inhibited from diffusing to the transistor 201a side from an interlayer insulating film and the like which are provided outside the insulator 284. Oxygen contained in the insulator 224 and the like can be inhibited from diffusing to the substrate side. Oxygen contained in the insulator 280 and the like can be inhibited from diffusing to above the transistor 201a through the insulator 282 and the like. In this manner, it is preferable that the transistor 201a be surrounded by upper and lower insulators having a function of inhibiting diffusion of oxygen and impurities such as water and hydrogen.

The conductor 205a is provided to overlap with the oxide 230 and the conductor 260. Here, the conductor 205a is preferably provided to be embedded in an opening portion formed in the insulator 216. Part of the conductor 205a is embedded in the insulator 214 in some cases.

The conductor 205a may have either a single-layer structure or a stacked-layer structure. In FIG. 5, the conductor 205a includes the conductor 205a1 and the conductor 205a2. The conductor 205a1 is provided to be in contact with the bottom surface and a sidewall of the opening portion. The conductor 205a2 is provided to be embedded in a depressed portion of the conductor 205a1. Here, the top surface of the conductor 205a2 is substantially level with the top surface of the conductor 205a1 and the top surface of the insulator 216.

Here, for the conductor 205a1, it is preferable to contain a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to contain a conductive material having a function of inhibiting diffusion of oxygen (e.g., at least one of an oxygen atom, an oxygen molecule, and the like).

When a conductive material having a function of inhibiting diffusion of hydrogen is used for the conductor 205a1, impurities such as hydrogen contained in the conductor 205a2 can be prevented from diffusing into the oxide 230 through the insulator 216, the insulator 224, and the like. When a conductive material having a function of inhibiting diffusion of oxygen is used for the conductor 205a1, the conductivity of the conductor 205a2 can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 205a1 can have a single-layer structure or a stacked-layer structure of the above conductive material. For example, the conductor 205a1 preferably contains titanium nitride.

Moreover, a conductive material containing tungsten, copper, or aluminum as its main component is preferably used for the conductor 205a2. For example, the conductor 205a2 preferably contains tungsten.

The conductor 205a can function as a second gate electrode. In that case, by changing a potential applied to the conductor 205a out of synchronization with and independently of a potential applied to the conductor 260, the threshold voltage (Vth) of the transistor 201a can be controlled. In particular, by applying a negative potential to the conductor 205a, Vth of the transistor 201a can be higher, and its off-state current can be reduced. Thus, a drain current at the time when a potential applied to the conductor 260 is 0 V can be lower in the case where a negative potential is applied to the conductor 205a than in the case where the negative potential is not applied to the conductor 205a.

The electric resistivity of the conductor 205a is designed in consideration of the potential applied to the conductor 205a, and the thickness of the conductor 205a is determined in accordance with the electric resistivity. The thickness of the insulator 216 is substantially equal to that of the conductor 205a. Here, the thicknesses of the conductor 205a and the insulator 216 are preferably as small as possible in the allowable range of the design of the conductor 205a. When the thickness of the insulator 216 is reduced, the absolute amount of impurity such as hydrogen contained in the insulator 216 can be reduced, inhibiting the diffusion of the impurity into the oxide 230.

The insulator 222 and the insulator 224 function as a gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

The insulator 222 preferably contains an insulator containing an oxide of one or both of aluminum and hafnium, which is an insulating material. As the insulator, aluminum oxide, hafnium oxide, an oxide containing aluminum and hafnium (hafnium aluminate), or the like is preferably used. Alternatively, an oxide containing hafnium and zirconium, e.g., a hafnium zirconium oxide, is preferably used. In the case where the insulator 222 is formed using such a material, the insulator 222 functions as a layer that inhibits release of oxygen from the oxide 230 to the substrate side and diffusion of impurities such as hydrogen from the periphery of the transistor 201a into the oxide 230. Thus, providing the insulator 222 can inhibit diffusion of impurities such as hydrogen into the transistor 201a and inhibit generation of oxygen vacancies in the oxide 230. Moreover, the conductor 205a can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of silicon oxide, silicon oxynitride, or silicon nitride over the insulators may be used for the insulator 222.

For example, a single-layer structure or a stacked-layer structure of an insulator(s) containing what is called a high-k material such as aluminum oxide, hafnium oxide, tantalum oxide, zirconium oxide, or hafnium zirconium oxide may be used for the insulator 222. As miniaturization and high integration of transistors progress, a problem such as leakage current may arise because of a thinner gate insulator. When a high-k material is used for the insulator functioning as a gate insulator, a gate potential at the time of the operation of the transistor can be reduced while the physical thickness is maintained. Furthermore, a substance with a high dielectric constant such as lead zirconate titanate (PZT), strontium titanate (SrTiO₃), or (Ba,Sr)TiO₃ (BST) can be used for the insulator 222 in some cases.

The insulator 224 in contact with the oxide 230 preferably contains, for example, silicon oxide or silicon oxynitride.

Note that the insulator 222 and the insulator 224 may each have a stacked-layer structure of two or more layers. In that case, without limitation to a stacked-layer structure formed of the same material, a stacked-layer structure formed of different materials may be employed.

A conductive material that is less likely to be oxidized or a conductive material having a function of inhibiting diffusion of oxygen is preferably used for each of the conductor 242a, the conductor 242b, and the conductor 260. Examples of the conductive material include a conductive material containing nitrogen and a conductive material containing oxygen. Thus, a decrease in conductivity of the conductor 242a, the conductor 242b, and the conductor 260 can be inhibited. In the case where a conductive material containing a metal and nitrogen is used for the conductor 242a, the conductor 242b, and the conductor 260, the conductor 242a, the conductor 242b, and the conductor 260 contain at least a metal and nitrogen.

The conductor 242a and the conductor 242b may each have a single-layer structure or a stacked-layer structure. The conductor 260 can have either a single-layer structure or a stacked-layer structure.

FIG. 5 illustrates the conductors 242a and 242b each having a two-layer structure. In this case, a conductive material that is less likely to be oxidized or a conductive material having a function of inhibiting diffusion of oxygen is preferably used for a layer in contact with the oxide 230b (the conductor 242a1 and the conductor 242b1). This can inhibit a reduction in the conductivity of the conductors 242a and 242b. For a layer (the conductor 242a1 and the conductor 242b1) in contact with the oxide 230b, a material that is likely to absorb (extract) hydrogen is preferably used, in which case the hydrogen concentration in the oxide 230 can be reduced.

The conductor 242a2 and the conductor 242b2 preferably have higher conductivity than the conductor 242a1 and the conductor 242b1. For example, the thicknesses of the conductor 242a2 and the conductor 242b2 are preferably larger than the thicknesses of the conductor 242a1 and the conductor 242b1.

For example, tantalum nitride or titanium nitride can be used for the conductor 242a1 and the conductor 242b1, and tungsten can be used for the conductor 242a2 and the conductor 242b2.

To inhibit a decrease in the conductivity of the conductors 242a and 242b, an oxide having crystallinity, such as CAAC-OS, is preferably used as the oxide 230b. Specifically, a metal oxide containing indium, zinc, and one or more selected from gallium, aluminum, and tin is preferably used. With the use of CAAS-OS, the conductor 242a or the conductor 242b can be inhibited from extracting oxygen from the oxide 230b. Furthermore, it is possible to inhibit a reduction in the conductivity of the conductor 242a and the conductor 242b.

For the conductors 242a and 242b, for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

Note that hydrogen contained in the oxide 230b or the like diffuses into the conductor 242a or the conductor 242b in some cases. In particular, when a nitride containing tantalum is used for the conductor 242a and the conductor 242b, hydrogen contained in the oxide 230b or the like is likely to diffuse into the conductor 242a or the conductor 242b, and the diffused hydrogen is bonded to nitrogen contained in the conductor 242a or the conductor 242b in some cases. That is, hydrogen contained in the oxide 230b or the like is absorbed by the conductor 242a or the conductor 242b in some cases.

The top surface of the conductor 260 is provided to be substantially level with the uppermost portion of the insulator 254, the uppermost portion of the insulator 253, and the top surface of the insulator 280.

The conductor 260 functions as the first gate electrode of the transistor 201a. The conductor 260 preferably includes the conductor 260a and the conductor 260b provided over the conductor 260a. For example, the conductor 260a is preferably provided to cover the bottom surface and the side surface of the conductor 260b.

FIG. 5 illustrates the conductor 260 having a two-layer structure. In this case, a conductive material that is less likely to be oxidized or a conductive material having a function of inhibiting diffusion of oxygen is preferably used for the conductor 260a.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen contained in the insulator 280 or the like. As the conductive material having a function of inhibiting diffusion of oxygen, for example, titanium, titanium nitride, tantalum, tantalum nitride, ruthenium, or ruthenium oxide is preferably used.

The conductor 260 is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 201a, the conductor 260 is formed in a self-aligned manner to fill the opening formed in the insulator 280 and the like. The formation of the conductor 260 in this manner allows the conductor 260 to be provided properly in a region between the conductor 242a and the conductor 242b without alignment.

The dielectric constant of each of the insulator 266, the insulator 290, the insulator 264, the insulator 216, the insulator 280, the insulator 284, the insulator 232, and the insulator 281 is preferably lower than that of the insulator 214. When a material with a low dielectric constant is used for an interlayer film, parasitic capacitance generated between wirings can be reduced.

For example, each of the insulator 266, the insulator 290, the insulator 264, the insulator 216, the insulator 280, the insulator 284, the insulator 232, and the insulator 281 preferably contains one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. In particular, materials such as silicon oxide, silicon oxynitride, and porous silicon oxide are preferably used, in which case a region containing oxygen released by heating can be easily formed.

The top surface of each of the insulator 266, the insulator 290, the insulator 264, the insulator 216, the insulator 280, the insulator 284, the insulator 232, and the insulator 281 may be planarized.

The concentration of impurities such as water and hydrogen in the insulator 280 is preferably reduced. For example, the insulator 280 preferably contains an oxide containing silicon such as silicon oxide or silicon oxynitride.

Note that a sidewall of the insulator 280 in an opening portion of the insulator 280 may be substantially perpendicular to the top surface of the insulator 222 or may have a tapered shape. The tapered shape of the sidewall can improve the coverage with the insulator 253 and the like provided in the opening portion formed in the insulator 280; as a result, the number of defects such as voids can be reduced.

Each of the conductor 153 and the conductor 160 included in the capacitor 101a can be formed with a variety of conductors that can be used for the conductor 205, the conductor 242, and the conductor 260. The conductor 153 and the conductor 160 are preferably deposited by a deposition method that has excellent coverage, such as an ALD method or a CVD method.

The top surface of the conductor 242b is in contact with the bottom surface of the conductor 153. When the same conductive material as the conductor 242b is used for the conductor 153, for example, the contact resistance between the conductor 153 and the conductor 242b can be reduced. Titanium nitride or tantalum nitride that are deposited by an ALD method can be used for the conductor 153, for example.

For example, titanium nitride deposited by an ALD method can be used for the conductor 160a, and tungsten deposited by a CVD method can be used for the conductor 160b. Note that in the case where the adhesion of tungsten to the insulator 154 is sufficiently high, a single-layer structure of tungsten deposited by a CVD method may be used for the conductor 160.

For the insulator 154 included in the capacitor 101a, a high dielectric constant (high-k) material (material with a high relative dielectric constant) is preferably used. Thus, the insulator 154 is preferably deposited by a deposition method that provides favorable coverage, such as an ALD method or a CVD method.

As an insulator of the high dielectric constant (high-k) material, an oxide, an oxynitride, a nitride oxide, or a nitride containing one or more kinds of metal elements selected from aluminum, hafnium, zirconium, gallium, and the like can be used, for example. The above-described oxide, oxynitride, nitride oxide, and nitride may contain silicon. Insulators each formed of any of the above-described materials can be stacked to be used.

As examples of the insulator of the high dielectric constant (high-k) material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, and an oxynitride containing hafnium and zirconium are given. With the use of such a high-k material, the insulator 154 can be made thick enough to inhibit leakage current and ensure sufficient capacitance of the capacitor 101a.

It is preferable to use stacked insulators formed of any of the above-described materials, and it is preferable to use a stacked-layer structure including a high dielectric constant (high-k) material and a material having higher dielectric strength than the high dielectric constant (high-k) material. As the insulator 154, an insulator in which zirconium oxide, aluminum oxide, and zirconium oxide are stacked in this order can be used, for example. For another example, an insulator in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The use of stacked insulators with relative high dielectric strength such as aluminum oxide can increase the dielectric strength and inhibit electrostatic breakdown of the capacitor 101a.

The conductor 240 is provided in contact with an inner wall of an opening portion in the insulator 212, the insulator 214, the insulator 266, the insulator 272, the insulator 290, the insulator 262, the insulator 264, the insulator 216, the insulator 275, the insulator 280, the insulator 282, the insulator 284, the insulator 232, and the insulator 281. The conductor 240 is in contact with the top surface and the side surface of the conductor 252a, the top surface and the side surface of the conductor 242a, and the top surface of the conductor 209.

The conductor 240 functions as a plug or a wiring for electrically connecting the transistors 201a and 203a to a circuit element such as a switch, a transistor, a capacitor, an inductor, a resistor, or a diode, a wiring, an electrode, or a terminal.

For example, in a memory device that will be described in Embodiment 2, the conductor 240 functions as a write and read bit line.

The conductor 240 preferably has a stacked-layer structure of the conductor 240a and the conductor 240b. For example, as illustrated in FIG. 5, the conductor 240 can have a structure in which the conductor 240a is provided in contact with the inner wall of the opening portion and the conductor 240b is provided inside the conductor 240a. That is, the conductor 240a is provided closer to the insulator 212, the insulator 214, the insulator 266, the insulator 272, the insulator 290, the insulator 262, the insulator 264, the insulator 216, the insulator 275, the insulator 280, the insulator 282, the insulator 284, the insulator 232, and the insulator 281 than the conductor 240b is. The conductor 240a is in contact with the top surface and the side surface of the conductor 252a, the top surface and the side surface of the conductor 242a, and the top surface of the conductor 209.

A conductive material having a function of inhibiting transmission of impurities such as water and hydrogen is preferably used for the conductor 240a. The conductor 240a can have a single-layer structure or a stacked-layer structure including one or more of tantalum, tantalum nitride, titanium, titanium nitride, ruthenium, and ruthenium oxide, for example. Thus, impurities such as water and hydrogen can be inhibited from entering the oxides 230 and 220 through the conductor 240.

The conductor 240 also functions as a wiring and thus is preferably formed using a conductor having high conductivity. For example, a conductive material containing tungsten, copper, or aluminum as its main component can be used for the conductor 240b.

For example, it is preferable to use titanium nitride for the conductor 240a and tungsten for the conductor 240b. In that case, the conductor 240a is a conductor that contains titanium and nitrogen, and the conductor 240b is a conductor that contains tungsten.

Note that the conductor 240 may have a single-layer structure or a stacked-layer structure of three or more layers. Although FIG. 1 and the like illustrate an example in which the top surface of the conductor 240 is level with the top surface of the insulator 281, the top surface of the conductor 240 may be higher than the top surface of the insulator 281.

### Cross-Sectional Structure Example 2 of Semiconductor Device

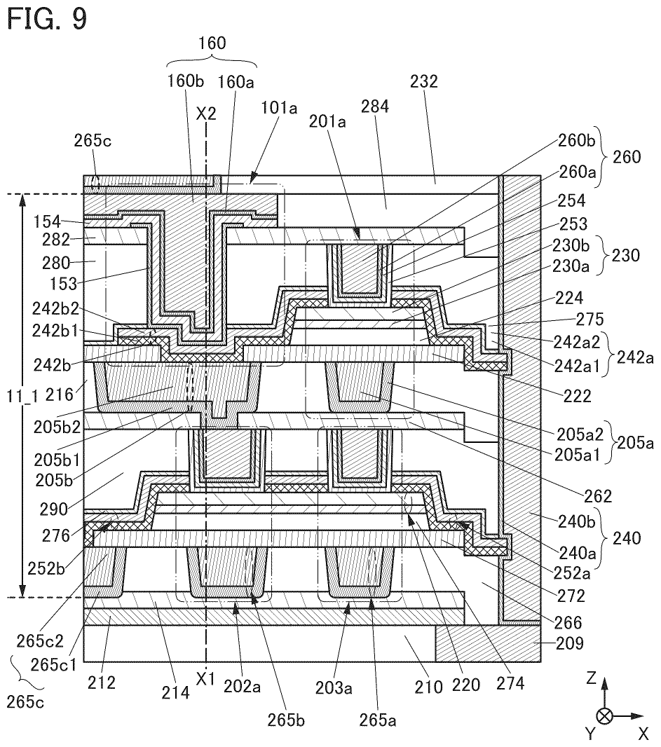

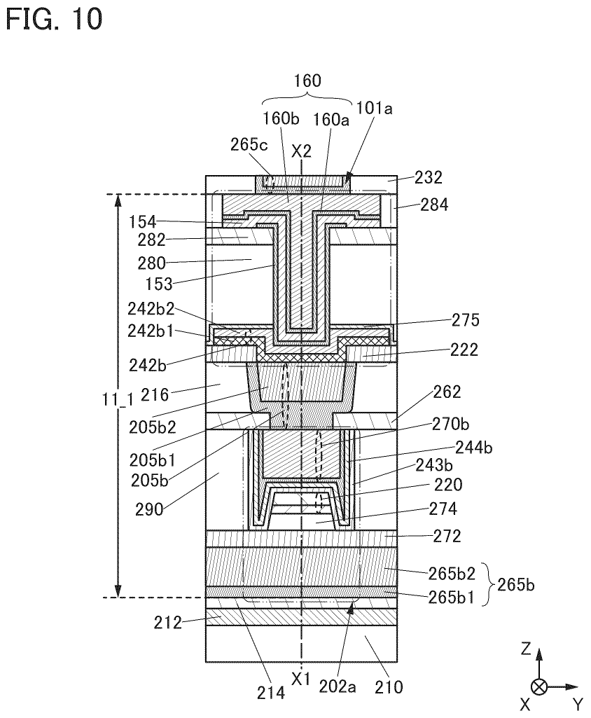

A cross-sectional structure example of the semiconductor device of one embodiment of the present invention will be described below with reference to FIG. 9 and FIG. 10.

In FIG. 9, the X direction is parallel to the channel length direction of transistors illustrated in the drawing, the Y direction is perpendicular to the X direction, and the Z direction is perpendicular to the X direction and the Y direction.

In FIG. 10, the Y direction is parallel to the channel width direction of a transistor in the drawing, the X direction is perpendicular to the Y direction, and the Z direction is perpendicular to the X direction and the Y direction.

FIG. 9 is a variation example of the semiconductor device illustrated in FIG. 5. Specifically, in FIG. 9, the channel length of the transistor 202a is longer than the channel length of the transistor 203a.

Although FIG. 5 and the like illustrate an example in which the channel length of the transistor 203a and the channel length of the transistor 202a are equal to each other, one embodiment of the present invention is not limited thereto. The channel length of the transistor 203a and the channel length of the transistor 202a can be determined independently.

As illustrated in FIG. 9, a portion where the transistor 202a and the capacitor 101a overlap with each other may be included. Specifically, a portion where a stacked-layer structure of the conductor 265b, the oxide 220, and the conductor 270b in the transistor 202a and a stacked-layer structure of the conductor 153, the insulator 154, and the conductor 160 in the capacitor 101a overlap with each other may be included.

FIG. 10 illustrates a cross-sectional view taken along the dashed-dotted line X1-X2 in the Y direction in FIG. 9. FIG. 10 can also be referred to as a cross-sectional view of the transistor 202a in the channel width direction. FIG. 9 can also be referred to as a cross-sectional view taken along the dashed-dotted line X1-X2 in the Y direction in FIG. 10.

In FIG. 10, the insulator 212 is provided over the insulator 210, the insulator 214 is provided over the insulator 212, and the conductor 265b is provided over the insulator 214. The insulator 272 is provided over the conductor 265b, the insulator 274 is provided over the insulator 272, and the oxide 220 is provided over the insulator 274. The side surface of the insulator 274 and the top surface and the side surface of the oxide 220 are covered with the insulator 243b, the insulator 244b, and the conductor 270b. The insulator 243b, the insulator 244b, and the conductor 270b are provided inside the opening of the insulator 290 provided over the insulator 272.

Here, it can be said that not only the top surface but also the side surface of the oxide 220 is surrounded by the conductor 270b including a region that functions as the first gate electrode.

In this specification and the like, a transistor structure in which a channel formation region is electrically surrounded by electric fields of at least the first gate electrode is referred to as a surrounded channel (S-channel) structure. The S-channel structure disclosed in this specification and the like has a structure that is different from a Fin-type structure and a planar structure. Meanwhile, the S-channel structure disclosed in this specification and the like can also be regarded as a kind of the Fin-type structure. In this specification and the like, the Fin-type structure refers to a structure where at least two surfaces (specifically, two surfaces, three surfaces, or four surfaces) of a channel are covered with a gate electrode. With the Fin-type structure and the S-channel structure, resistance to a short-channel effect can be enhanced; that is, a transistor in which a short-channel effect is less likely to occur can be provided.

When the transistor included in the semiconductor device of this embodiment has the above-described S-channel structure, the channel formation region can be electrically surrounded. Since the S-channel structure is a structure with the electrically surrounded channel formation region, the S-channel structure can be referred to as a structure substantially equivalent to a GAA (Gate All Around) structure or a LGAA (Lateral Gate All Around) structure. When the transistor has the S-channel structure, the GAA structure, or the LGAA structure, the channel formation region that is formed at the interface between the oxide and the gate insulator or in the vicinity of the interface can be formed in the entire bulk of the oxide. Accordingly, the density of current flowing in the transistor can be improved, which can be expected to improve the on-state current of the transistor or increase the field-effect mobility of the transistor.

Although FIG. 10 illustrates, as an example, a transistor with an S-channel structure as the transistor 202a, the semiconductor device of one embodiment of the present invention is not limited thereto. For example, a transistor structure that can be used in one embodiment of the present invention is one or more selected from a planar structure, a Fin-type structure, and a GAA structure.

Note that the cross-sectional shape of the oxide 220 is not limited to the structure illustrated in FIG. 10. For example, the oxide 220 may have a curved surface between the side surface and the top surface. Accordingly, coverage with a film formed over the oxide 220 can be improved.

In FIG. 10, the insulator 262 is provided over the insulator 272, and the insulator 216 is provided over the insulator 262. The conductor 205b is embedded in an opening provided in the insulator 262 and the insulator 216, and the conductor 205b and the conductor 270b are electrically connected to each other. The insulator 222 is provided over the insulator 216, the conductor 242b is provided over the insulator 222, the insulator 275 is provided over the conductor 242b, the insulator 280 is provided over the insulator 275, and the insulator 282 is provided over the insulator 280. The conductor 153 is provided over the insulator 282, the insulator 154 is provided over the conductor 153, and the conductor 160 is provided over the insulator 154. The conductor 205b and the conductor 242b are electrically connected to each other through an opening provided in the insulator 222. The conductor 242b and the conductor 153 are electrically connected to each other through the opening provided in the insulator 275, the insulator 280, and the insulator 282. The conductor 160 is electrically connected to the conductor 265c provided in the upper layer (the second layer 11_2 for the first layer 11_1).

### Cross-Sectional Structure Example 3 of Semiconductor Device

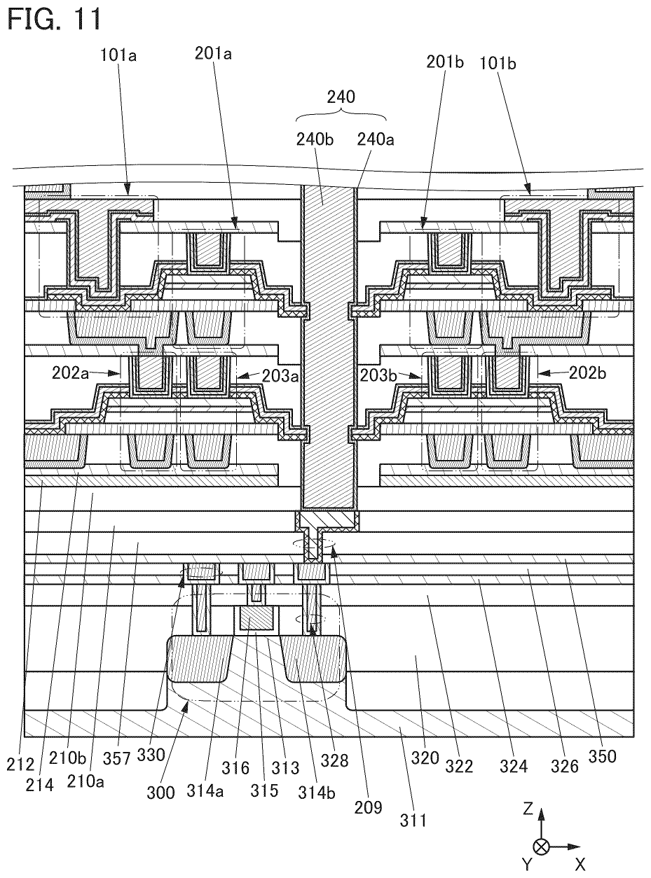

A cross-sectional structure example of the semiconductor device of one embodiment of the present invention will be described with reference to FIG. 11.

In the semiconductor device illustrated in FIG. 11, a layer including a transistor 300 and the like (corresponding to a driver circuit layer 50 that will be described in Embodiment 2) is provided below a stacked-layer structure similar to that illustrated in FIG. 1 (corresponding to the memory layer 60 that will be described in Embodiment 2). A structure above the insulator 212 in FIG. 11 is similar to that in FIG. 1 and thus is not described in detail.

FIG. 11 illustrates an example of the transistor 300 included in the driver circuit layer 50 that will be described in Embodiment 2. The transistor 300 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 300 may be a p-channel transistor or an n-channel transistor. As the substrate 311, a single crystal silicon substrate can be used, for example.

Here, in the transistor 300 illustrated in FIG. 11, the semiconductor region 313 (part of the substrate 311) in which the channel is formed has a protruding shape. The conductor 316 is provided to cover the side surfaces and the top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon on Insulator) substrate.

Note that the transistor 300 illustrated in FIG. 11 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, part of a conductor functions as a wiring in some cases and part of a conductor functions as a plug in other cases.

For example, an insulator 320, an insulator 322, an insulator 324, and an insulator 326 are sequentially stacked over the transistor 300 as interlayer films. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as interlayer films may also function as planarization films that cover uneven shapes therebelow. For example, the top surface of the insulator 322 may be planarized by planarization treatment using a chemical mechanical polishing (CMP) method or the like to have improved planarity.

A wiring layer may be provided over the insulator 326 and the conductor 330. For example, in FIG. 11, an insulator 350, an insulator 357, an insulator 210a, and an insulator 210b are stacked sequentially over the insulator 326 and the conductor 330. The conductor 209 is embedded in the insulator 350, the insulator 357, the insulator 210a, and the insulator 210b. The conductor 209 functions as a contact plug or a wiring.

For example, the conductor 240 and the transistor 300 are electrically connected to each other through the conductor 209, the conductor 330, the conductor 328, and the like.

### <Top-Surface Structure Example of Semiconductor Device>

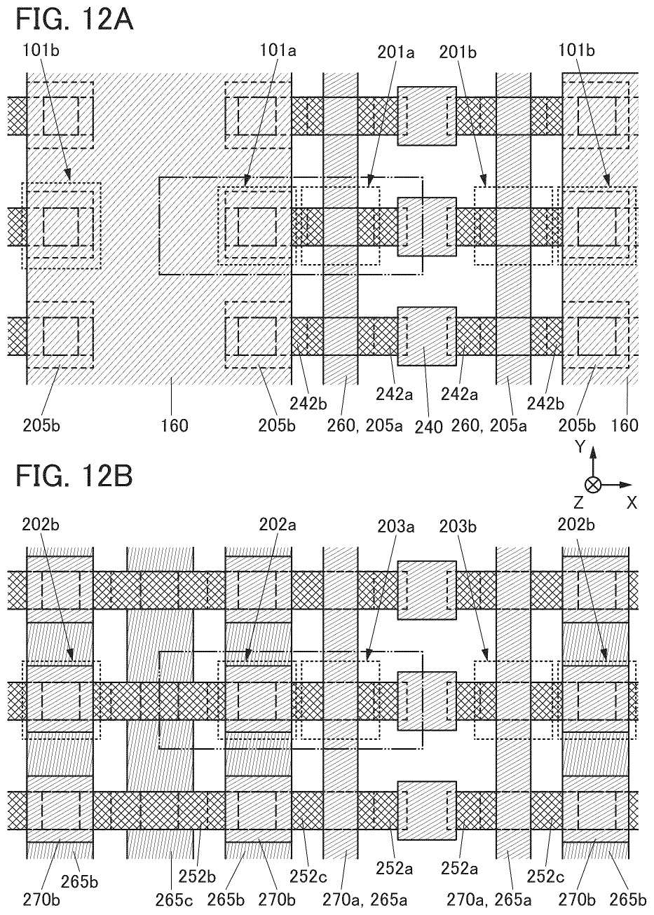

Top-surface structure examples of the semiconductor device of one embodiment of the present invention will be described with reference to FIG. 12A and FIG. 12B.

In FIG. 12A and FIG. 12B, the X direction is parallel to the channel length direction of transistors illustrated in the drawings, the Y direction is parallel to the channel width direction of the transistors in the drawings, and the Z direction is perpendicular to the X direction and the Y direction. Note that in FIG. 12A and FIG. 12B, some components such as an insulator are not illustrated for simplicity.

FIG. 12A is a layout of an upper stage of each layer such as the first layer 11_1 and the like and illustrates the transistors 201a and 201b, the capacitors 101a and 101b, and the like.

FIG. 12B is a layout of a lower stage of each layer such as the first layer 11_1 and the like and illustrates the transistors 202a, 202b, 203a, and 203b, and the like.

A variety of conductors illustrated in FIG. 12A and FIG. 12B are formed with a line-and-space pattern. In the case where the conductors are designed with a line/space=20 nm/20 nm, a margin of a portion where two patterns overlap with each other is 10 nm, and the conductor 240 is designed with 25 nm×25 nm by adding 5 nm of a margin with respect to the misalignment, the area of one cell (the area of a region surrounded by a dashed-double-dotted line in FIG. 12A and FIG. 12B) is 60 nm×162.5 nm=0.000975 μm² and the cell density is 103 cells/μm². For example, in the case where four layers of cells are stacked (the case of n=4 in FIG. 1), the cell density is 412 cells/μm².

In the case where a margin of a portion where two patterns overlap with each other is 5 nm and the conductor 252b is led in the Y direction to supply the potential (that is, a structure where the conductor 265c is not provided, see FIG. 2), the area of one cell is 50 nm×135 nm=0.00675 μm² and the cell density is 148 cells/μm². For example, in the case where four layers of cells are stacked, the cell density is 593 cells/μm².

Although the conductor 240 has a quadrangular shape in the top view of FIG. 12A and FIG. 12B, the shape is not limited thereto. For example, in the top view, the conductor 240 may have an almost circular shape such as a circular shape or an elliptical shape, a polygonal shape such as a quadrangular shape, or a polygonal shape such as a quadrangular shape with rounded corners.

### <Component Material for Semiconductor Device>

Component materials that can be used for the semiconductor device will be described below. Note that the layers included in the semiconductor device may have a single-layer structure or a stacked-layer structure.

### <<Substrate>>

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Furthermore, a semiconductor substrate having an insulator region in the semiconductor substrate described above, e.g., an SOI (Silicon On Insulator) substrate, can be given. Examples of the conductor substrate include a graphite substrate, a metal substrate, an alloy substrate, and a conductive resin substrate. Alternatively, examples of the substrate include a substrate including a metal nitride, a substrate including an oxide of a metal, a substrate in which an insulator substrate is provided with a conductor or a semiconductor, a substrate in which a semiconductor substrate is provided with a conductor or an insulator, and a substrate in which a conductor substrate is provided with a semiconductor or an insulator. Alternatively, these substrates provided with one or more kinds of elements may be used. Examples of the elements provided for the substrates include a capacitor, a resistor, a switching element, a light-emitting element, and a memory element.

### <<Insulator>>

Examples of an insulator include an oxide, a nitride, an oxynitride, a nitride oxide, a metal oxide, a metal oxynitride, and a metal nitride oxide, each of which has an insulating property.

As miniaturization and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. In contrast, when a material with a low relative dielectric constant is used for the insulator functioning as an interlayer film, the parasitic capacitance generated between wirings can be reduced. Thus, a material is preferably selected depending on the function of the insulator.

Examples of the insulator having a high relative dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low relative dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, one or more of boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be given.

The insulator functioning as the gate insulator is preferably an insulator including a region that contains oxygen to be released by heating. For example, when a structure is employed in which silicon oxide or silicon oxynitride including a region that contains oxygen to be released by heating is in contact with the oxide 220 or the oxide 230, oxygen vacancies included in the oxide 220 or the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the conductor, for example, tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel can be given. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high electrical conductivity, typified by polycrystalline silicon containing an impurity element such as phosphorus, or silicide such as nickel silicide may be used.

In the case where a stacked-layer structure of conductors is used, for example, a stacked-layer structure combining a material containing any of the above metal elements and a conductive material containing oxygen, a stacked-layer structure combining a material containing any of the above metal elements and a conductive material containing nitrogen, or a stacked-layer structure combining a material containing any of the above metal elements, a conductive material containing oxygen, and a conductive material containing nitrogen may be employed.

In the case where an oxide is used for the channel formation region of the transistor, the conductor functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>>

The oxides 220 and 230 are each preferably formed using a metal oxide functioning as a semiconductor (an oxide semiconductor). A metal oxide that can be used as each of the oxides 220 and 230 of one embodiment of the present invention is described below.

The metal oxide preferably contains at least indium or zinc. In particular, indium and zinc are preferably contained. In addition, aluminum, gallium, yttrium, tin, or the like is preferably contained. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is In-M-Zn oxide containing indium, the element M, and zinc is considered. Note that the element M is aluminum, gallium, yttrium, or tin. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

It is particularly preferable to use an oxide containing indium (In), gallium (Ga), and zinc (Zn) (also referred to as In—Ga—Zn oxide or IGZO) for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

Note that in this specification and the like, a metal oxide containing nitrogen is also collectively referred to as a metal oxide in some cases. A metal oxide containing nitrogen may be referred to as a metal oxynitride.

In—Ga—Zn oxide is described below as an example of the metal oxide.

Amorphous (including a completely amorphous structure), CAAC (c-axis-aligned crystalline), nc (nanocrystalline), CAC (cloud-aligned composite), single-crystal, and polycrystalline (poly crystal) structures can be given as examples of a crystal structure of an oxide semiconductor.

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. Moreover, the CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter less than 10 nm). In the case where the crystal region is formed of one fine crystal, the maximum diameter of the crystal region is less than 10 nm. In the case where the crystal region is formed of a large number of fine crystals, the maximum diameter of the crystal region may be approximately several tens of nanometers.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Thus, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

[a-Like OS]

The a-like OS is an oxide semiconductor having a structure between those of the nc-OS and the amorphous oxide semiconductor. The a-like OS contains a void or a low-density region. That is, the a-like OS has lower crystallinity than the nc-OS and the CAAC-OS. Moreover, the a-like OS has higher hydrogen concentration in the film than the nc-OS and the CAAC-OS.

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

In addition, in a material composition of a CAC-OS in In—Ga—Zn oxide that contains In, Ga, Zn, and O, there are regions containing In as a main component in part of the CAC-OS (the first regions) and regions containing Ga as a main component in another part of the CAC-OS (the second regions). These regions each form a mosaic pattern and are randomly present. Thus, it is suggested that the CAC-OS has a structure in which metal elements are unevenly distributed.

The CAC-OS can be formed by a sputtering method under a condition where a substrate is not heated, for example. In addition, in the case of forming the CAC-OS by a sputtering method, one or more selected from an inert gas (typically, argon), an oxygen gas, and a nitrogen gas can be used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

Here, the first region is a region having a higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region is a region having a higher insulating property than the first region. In other words, when the second regions are distributed in a metal oxide, leakage current can be inhibited.

Thus, in the case where a CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), a high field-effect mobility (μ), and an excellent switching operation can be achieved.

A transistor using the CAC-OS has high reliability. Thus, the CAC-OS is most suitable for a variety of semiconductor devices such as display devices.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <<Other Semiconductor Materials>>

A semiconductor material that has a band gap (a semiconductor material that is not a zero-gap semiconductor) may be used for the semiconductor layer of the transistor. For example, a single-element semiconductor such as silicon or a compound semiconductor such as gallium arsenide may be used.

For a semiconductor layer of a transistor, transition metal chalcogenide functioning as a semiconductor is preferably used, for example. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the above transition metal chalcogenide for the semiconductor layer of the transistor can provide a semiconductor device with a high on-state current.

### <Manufacturing Method Example of Semiconductor Device>

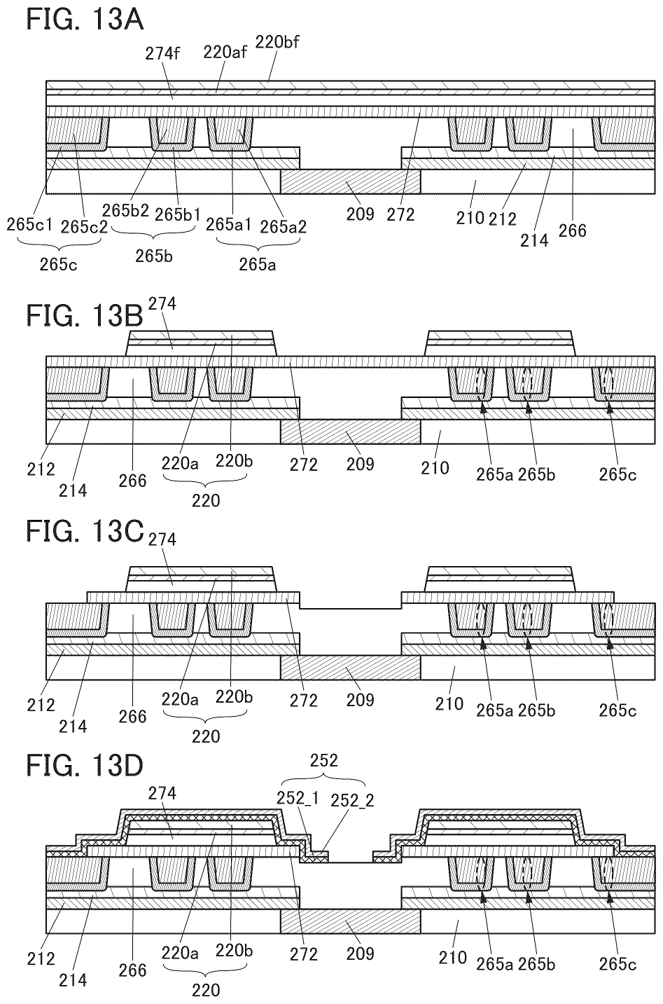

An example of a method for manufacturing a semiconductor device of one embodiment of the present invention will be described with reference to FIG. 13 to FIG. 18. Here, the case of manufacturing the semiconductor device illustrated in FIG. 1 is described as an example.

Hereinafter, an insulating material for forming an insulator, a conductive material for forming a conductor, or a semiconductor material for forming a semiconductor can be deposited by a sputtering method, a chemical vapor deposition (CVD) method, an molecular beam epitaxy (MBE) method, a pulsed laser deposition (PLD) method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is deposited, and a DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving charge from plasma. In that case, accumulated charge may break the wiring, the electrode, the element, or the like included in the semiconductor device. In contrast, such plasma damage is not caused in the case of a thermal CVD method not using plasma, and thus the yield of the semiconductor device can be increased. In addition, a thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, and the like can be used.

A CVD method and an ALD method are different from a sputtering method in which particles ejected from a target or the like are deposited. Thus, a CVD method and an ALD method are deposition methods that enable favorable step coverage almost regardless of the shape of an object to be processed. In particular, an ALD method has excellent step coverage and excellent thickness uniformity and thus is suitable for covering a surface of an opening portion with a high aspect ratio, for example. On the other hand, an ALD method has a relatively low deposition rate, and thus is preferably used in combination with another deposition method with a high deposition rate, such as a CVD method, in some cases.

By a CVD method, a film with a certain composition can be deposited depending on the flow rate ratio of the source gases. For example, by a CVD method, by changing the flow rate ratio of the source gases during the deposition, a film in which the composition is continuously changed can be deposited. In the case where the film is deposited while the flow rate ratio of the source gases is changed, as compared to the case where the film is deposited using a plurality of deposition chambers, the time taken for the deposition can be shortened because the time taken for transfer or pressure adjustment is omitted. Thus, the productivity of the semiconductor device can be increased in some cases.

In an ALD method, a film with a certain composition can be deposited by concurrently introducing different kinds of precursors. In the case where different kinds of precursors are introduced, a film with a certain composition can be deposited by controlling the cycle number of each of the precursors.

First, a substrate (not illustrated) is prepared and the insulator 210 and the conductor 209 are formed over the substrate. Next, the insulator 212 is formed over the insulator 210 and the conductor 209, the insulator 214 is formed over the insulator 212, and the insulator 266 is formed over the insulator 214 (FIG. 13A).

The insulator 212, the insulator 214, and the insulator 266 are each preferably deposited by a sputtering method. By using a sputtering method that does not need to use a molecule containing hydrogen as a deposition gas, the hydrogen concentration in the insulator 212, the insulator 214, and the insulator 266 can be reduced. Note that the deposition method for each of the insulator 212, the insulator 214, and the insulator 266 is not limited to a sputtering method, and a CVD method, an MBE method, a PLD method, or an ALD method may be used, for example.

In this embodiment, for the insulator 212, silicon nitride is deposited by a pulsed DC sputtering method using a silicon target in an atmosphere containing a nitrogen gas. The use of the pulsed DC sputtering method can inhibit generation of particles due to arcing on the target surface, enabling more uniform thickness. In addition, by using the pulsed voltage, rising and falling in discharge can be made steep as compared with the case where a high-frequency voltage is used. As a result, power can be supplied to an electrode more efficiently to improve the sputtering rate and film quality.

The use of an insulator through which impurities such as water and hydrogen are less likely to pass, such as silicon nitride, can inhibit diffusion of impurities such as water and hydrogen contained in a layer below the insulator 212. When an insulator through which copper is less likely to pass, such as silicon nitride, is used for the insulator 212, even in the case where a metal that is likely to diffuse, such as copper, is used for a conductor in a layer (not illustrated) below the insulator 212, upward diffusion of the metal through the insulator 212 can be inhibited.

In this embodiment, for the insulator 214, aluminum oxide is deposited by a pulsed DC sputtering method using an aluminum target in an atmosphere containing an oxygen gas. The use of the pulsed DC sputtering method can achieve more uniform thickness and improve the sputtering rate and film quality. Here, RF (Radio Frequency) power may be applied to the substrate. The amount of oxygen implanted to a layer below the insulator 214 can be controlled depending on the amount of the RF power applied to the substrate. The RF power is higher than or equal to 0) W/cm² and lower than or equal to 1.86 W/cm², for example. In other words, the amount of oxygen to be implanted can be changed to be appropriate for the characteristics of the transistor, with the RF power used at the time of forming the insulator 214. Accordingly, an appropriate amount of oxygen for improving the reliability of the transistor can be implanted. The RF frequency is preferably greater than or equal to 10 MHZ. The typical frequency is 13.56 MHz. The higher the RF frequency is, the less damage the substrate gets.

A metal oxide having an amorphous structure and an excellent function of capturing or fixing hydrogen, such as aluminum oxide, is preferably used for the insulator 214. In this case, the insulator 214 captures or fixes hydrogen contained in the insulator 266 and the like and prevents the hydrogen from diffusing into the oxide 220. In particular, it is preferable to use aluminum oxide having an amorphous structure or amorphous aluminum oxide for the insulator 214 because hydrogen can be captured or fixed more effectively in some cases. Accordingly, the transistor and a semiconductor device which have favorable characteristics and high reliability can be manufactured.

Note that this embodiment shows an example in which a portion of the insulator 212 and the insulator 214 that overlaps with a portion where the conductor 240 is provided is opened in advance is illustrated. The width of the opening is not particularly limited, and an end portion of the insulator 212 and an end portion of the insulator 214 may each be aligned with one or both of the end portion of the insulator 272 and an end portion of the conductor 252, for example.

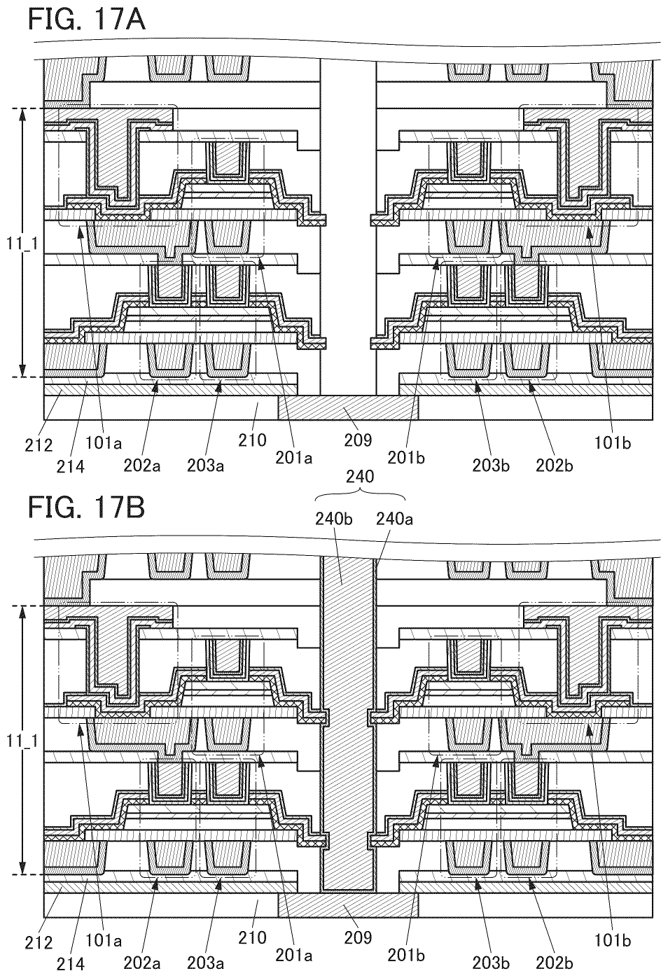

Note that the insulator 212 may be opened in the processing step described with reference to FIG. 17A. When the insulator 212 is opened in advance, impurities such as water and hydrogen are likely to diffuse into the transistor from the substrate side during the manufacturing process in some cases. The insulator 212 is preferably opened later so that the function of the insulator 212 as a barrier insulator is further increased. Similarly, the insulator 214 may be opened in the processing step described with reference to FIG. 17A. In the processing step described with reference to FIG. 17A, in the case where the insulator 212 and the insulator 214 are opened, the insulator 212 and the insulator 214 can each have a shape illustrated in FIG. 3, for example.

Note that the insulator 212 and the insulator 214 may be opened in the processing step described with reference to FIG. 17A. When the insulator 212 and the insulator 214 are opened in advance, impurities such as water and hydrogen are likely to diffuse into the transistor from the substrate side during the manufacturing process in some cases. When the insulator 212 and the insulator 214 are preferably opened later so that the function of the insulator 212 and the insulator 214 as barrier insulators are further increased. In the processing step illustrated in FIG. 17A, in the case where the insulator 212 and the insulator 214 are opened, the insulator 212 and the insulator 214 can each have a shape illustrated in FIG. 3, for example.

For the formation of an opening, a dry etching method or a wet etching method can be employed. A dry etching method is preferably used because processing by a dry etching method is suitable for microfabrication. An etching gas containing halogen can be used as an etching gas; specifically, an etching gas containing one or more of fluorine, chlorine, and bromine can be used. As the etching gas, for example, a C₄F₆ gas, a C₅F₆ gas, a C₄F₈ gas, a CF₄ gas, a SF₆ gas, a CHF₃ gas, a Cl₂ gas, a BCl₃ gas, a SiCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the etching gas as appropriate. For example, in the case where aluminum oxide is used for the insulator 214, a mixed gas of CHF₃ and Ar can be used as an etching gas. The etching conditions can be set as appropriate depending on an object to be etched.

As a dry etching apparatus, a capacitively coupled plasma (CCP) etching apparatus having parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus having a high-density plasma source can be used. As the dry etching apparatus including a high-density plasma source, an inductively coupled plasma (ICP) etching apparatus can be used, for example.

In this embodiment, for the insulator 266, silicon oxide is deposited by a pulsed DC sputtering method using a silicon target in an atmosphere containing an oxygen gas. The use of the pulsed DC sputtering method can achieve more uniform thickness and improve the sputtering rate and film quality.

Then, an opening reaching the insulator 214 is formed in the insulator 266. As the insulator 214, it is preferable to select an insulator that functions as an etching stopper film used in forming a groove by etching the insulator 266. For example, in the case where silicon oxide or silicon oxynitride is used for the insulator 266 in which the groove is to be formed, silicon nitride, aluminum oxide, or hafnium oxide is preferably used for the insulator 214.

After the opening is formed, a conductive film to be the conductors 265a1, 265b1, and 265c1 is deposited (FIG. 13A). The conductive film to be the conductors 265a1, 265b1, and 265c1 desirably includes a conductor having a function of inhibiting passage of oxygen. The conductive film preferably contains one or more of tantalum nitride, tungsten nitride, and titanium nitride, for example. Alternatively, the conductive film can be a stacked-layer film of the conductor having a function of inhibiting passage of oxygen and tantalum, tungsten, titanium, molybdenum, aluminum, copper, or a molybdenum-tungsten alloy. The conductive film to be the conductors 265a1, 265b1, and 265c1 can be deposited by, for example, a sputtering method, a CVD method, an MBE method, a PLD method, or an ALD method.

In this embodiment, titanium nitride is deposited for the conductive film to be the conductors 265a1, 265b1, and 265c1. When such a metal nitride is used for lower layers of the conductors 265a, 265b, and 265c, oxidation of the conductors 265a2, 265b2, and 265c2 due to the insulator 266 or the like can be inhibited. Furthermore, even when a metal that is likely to diffuse, such as copper, is used for the conductors 265a2, 265b2, and 265c2, the metal can be prevented from diffusing from the conductors 265a1, 265b1, and 265c1 to the outside.

Next, a conductive film to be the conductors 265a2, 265b2, and 265c2 is formed. The conductive film to be the conductors 265a2, 265b2, and 265c2 preferably contains one or more of tantalum, tungsten, titanium, molybdenum, aluminum, copper, and a molybdenum-tungsten alloy, for example. The conductive film can be deposited by a plating method, a sputtering method, a CVD method, an MBE method, a PLD method, or an ALD method, for example. In this embodiment, tungsten is deposited for the conductive film to be the conductors 265a2, 265b2, and 265c2.

Next, CMP treatment is performed to remove part of the conductive film to be the conductors 265a1, 265b1, and 265c1 and part of the conductive film to be the conductors 265a2, 265b2, and 265c2, so that the insulator 266 is exposed. As a result, the conductors 265a1, 265b1, and 265c1 and the conductors 265a2, 265b2, and 265c2 remain only in the opening portions of the insulator 266 (FIG. 13A). Note that part of the insulator 266 is removed by the CMP treatment in some cases.

Next, the insulator 272 is deposited over the insulator 266 and the conductors 265a, 265b, and 265c (FIG. 13A).

An insulator containing an oxide of one or both of aluminum and hafnium is preferably deposited as the insulator 272. Note that as the insulator containing an oxide of one or both of aluminum and hafnium, aluminum oxide, hafnium oxide, or an oxide containing aluminum and hafnium (hafnium aluminate) is preferably used, for example. Alternatively, hafnium-zirconium oxide is preferably used. The insulator containing an oxide of one or both of aluminum and hafnium has a barrier property against oxygen, hydrogen, and water. When the insulator 272 has a barrier property against hydrogen and water, hydrogen and water contained in components provided around the transistor are inhibited from diffusing into the transistor through the insulator 272, and generation of oxygen vacancies in the oxide 220 can be inhibited.

Alternatively, the insulator 272 can be a stacked-layer film of an insulator containing an oxide of one or both of aluminum and hafnium and silicon oxide, silicon oxynitride, silicon nitride, or silicon nitride oxide.

The insulator 272 can be deposited by, for example, a sputtering method, a CVD method, an MBE method, a PLD method, or an ALD method. In this embodiment, for the insulator 272, hafnium oxide is deposited by an ALD method. Alternatively, for the insulator 272, a stack of silicon nitride deposited by a PEALD method and hafnium oxide deposited by an ALD method may be used.

Subsequently, heat treatment is preferably performed. The temperature of the heat treatment is preferably higher than or equal to 250° C. and lower than or equal to 650° C., further preferably higher than or equal to 300° C. and lower than or equal to 500° C., still further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably set to approximately 20%. The heat treatment may be performed under reduced pressure. Alternatively, the heat treatment may be performed in an atmosphere containing an oxidizing gas at 10 ppm or more, 1% or more, or 10% or more in order to compensate for released oxygen, after heat treatment is performed in a nitrogen gas or inert gas atmosphere.

The gas used in the above heat treatment is preferably highly purified. For example, the amount of moisture contained in the gas used in the above heat treatment is preferably 1 ppb or less, further preferably 0.1 ppb or less, and still further preferably 0.05 ppb or less. The heat treatment using a highly purified gas can prevent entry of moisture or the like into the insulator 272 and the like as much as possible.

In this embodiment, as the heat treatment, treatment is performed with a flow rate ratio of a nitrogen gas and an oxygen gas of 4:1 at 400° C. for one hour after the deposition of the insulator 272. By the heat treatment, impurities such as water and hydrogen contained in the insulator 272 can be removed, for example. In the case where an oxide containing hafnium is used for the insulator 272, the insulator 272 is partly crystallized by the heat treatment in some cases. The heat treatment can also be performed after the deposition of the insulator 274, for example.

Then, an insulating film 274f is deposited over the insulator 272 (FIG. 13A).

The insulating film 274f can be deposited by a sputtering method, a CVD method, an MBE method, a PLD method, or an ALD method, for example. In this embodiment, for the insulating film 274f, silicon oxide is deposited by a sputtering method. By using a sputtering method that does not need to use a molecule containing hydrogen as a deposition gas, the hydrogen concentration in the insulating film 274f can be reduced. The hydrogen concentration in the insulating film 274f is preferably reduced because the insulating film 274f is in contact with the oxide 220a in a later step.

Next, an oxide film 220af is deposited over the insulating film 274f and an oxide film 220bf is deposited over the oxide film 220af (FIG. 13A). Note that the oxide film 220af and the oxide film 220bf are preferably deposited successively without being exposed to an atmospheric environment. By the deposition without exposure to the air, impurities or moisture from the atmospheric environment can be prevented from being attached onto the oxide film 220af and the oxide film 220bf, so that the vicinity of the interface between the oxide film 220af and the oxide film 220bf can be kept clean.

Each of the oxide film 220af and the oxide film 220bf can be deposited by, for example, a sputtering method, a CVD method, an MBE method, a PLD method, or an ALD method. In this embodiment, the oxide film 220af and the oxide film 220bf are deposited by a sputtering method.

For example, in the case where the oxide film 220af and the oxide film 220bf are deposited by a sputtering method, oxygen or a mixed gas of oxygen and a noble gas is used as a sputtering gas. Increasing the proportion of oxygen contained in the sputtering gas can increase the amount of excess oxygen in the deposited oxide films. In the case where the oxide films are deposited by a sputtering method, In-M-Zn oxide target or the like can be used.

In particular, when the oxide film 220af is deposited, part of oxygen contained in the sputtering gas is supplied to the insulating film 274f in some cases. Thus, the proportion of oxygen contained in the sputtering gas is preferably higher than or equal to 70%, further preferably higher than or equal to 80%, still further preferably 100%.

In the case where the oxide film 220bf is deposited by a sputtering method and the proportion of oxygen contained in the sputtering gas for deposition is higher than 30% and lower than or equal to 100%, preferably higher than or equal to 70% and lower than or equal to 100%, an oxygen-excess oxide semiconductor is formed. In a transistor including an oxygen-excess oxide semiconductor for its channel formation region, relatively high reliability can be obtained. Note that one embodiment of the present invention is not limited thereto. In the case where the oxide film 220bf is deposited by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. In a transistor including an oxygen-deficient oxide semiconductor for its channel formation region, relatively high field-effect mobility can be obtained. Furthermore, when the deposition is performed while the substrate is being heated, the crystallinity of the oxide film can be improved.

In this embodiment, the oxide film 220af is deposited by a sputtering method using an oxide target with In:Ga:Zn=1:3:4 [atomic ratio]. In addition, the oxide film 220bf is deposited by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 220a and the oxide 220b by selecting the deposition conditions and the atomic ratios as appropriate.

Note that the insulating film 274f, the oxide film 220af, and the oxide film 220bf are preferably deposited by a sputtering method without exposure to the air. For example, a multi-chamber deposition apparatus is preferably used. As a result, entry of hydrogen into the insulating film 274f, the oxide film 220af, and the oxide film 220bf in intervals between deposition steps can be inhibited.

Note that an ALD method may be employed for the deposition of the oxide film 220af and the oxide film 220bf. When the oxide film 220af and the oxide film 220bf are deposited by an ALD method, the films with uniform thicknesses can be formed even in a groove or an opening portion having a high aspect ratio. When a PEALD method is used, the oxide film 220af and the oxide film 220bf can be formed at a lower temperature than that in the case of employing a thermal ALD method.

Next, heat treatment is preferably performed. The heat treatment may be performed within a temperature range where the oxide film 220af and the oxide film 220bf do not become polycrystal. It is preferable that the temperature of the heat treatment be higher than or equal to 100° C., higher than or equal to 250° C., or higher than or equal to 350° C., and lower than or equal to 650° C., lower than or equal to 600° C., or lower than or equal to 550° C.

Examples of the atmosphere of the heat treatment include an atmosphere similar to the atmosphere that can be used for the heat treatment performed after the deposition of the insulator 272.

The gas used in the heat treatment is preferably highly purified as that in the heat treatment performed after deposition of the insulator 272. The heat treatment using a highly purified gas can prevent entry of moisture or the like into the oxide film 220af, the oxide film 220bf, and the like as much as possible.

In this embodiment, the heat treatment is performed at 400° C. for one hour with the flow rate ratio of nitrogen gas to oxygen gas being 4:1. By the heat treatment using the oxygen gas, impurities such as carbon, water, and hydrogen in the oxide film 220af and the oxide film 220bf can be reduced. The reduction of impurities in the films in this manner improves the crystallinity of the oxide film 220bf, thereby offering a dense structure with a higher density. Thus, crystalline regions in the oxide film 220af and the oxide film 220bf are expanded, so that in-plane variations of the crystalline regions in the oxide film 220af and the oxide film 220bf can be reduced. Accordingly, an in-plane variation of electrical characteristics of the transistor can be reduced.

By performing the heat treatment, hydrogen in the insulator 266, the insulating film 274f, the oxide film 220af, and the oxide film 220bf moves into the insulator 272 and is absorbed by the insulator 272. In other words, hydrogen in the insulator 266, the insulating film 274f, the oxide film 220af, and the oxide film 220bf diffuses into the insulator 272. Accordingly, the hydrogen concentration in the insulator 272 increases, while the hydrogen concentrations in the insulator 266, the insulating film 274f, the oxide film 220af, and the oxide film 220bf decrease.

Specifically, the insulating film 274f (to be the insulator 274 later) functions as the gate insulator of the transistors 202a and 203a, and the oxide film 220af and the oxide film 220bf (to be the oxide 220a and the oxide 220b later) function as the channel formation region of the transistors 202a and 203a. Thus, the transistors 202a and 203a formed using the insulating film 274f, the oxide film 220af, and the oxide film 220bf with reduced hydrogen concentrations are preferable because of their favorable reliability.

Next, the insulating film 274f, the oxide film 220af, and the oxide film 220bf are processed into island shapes by a lithography method to form the insulator 274, the oxide 220a, and the oxide 220b (FIG. 13B).

Here, the insulator 274, the oxide 220a, and the oxide 220b are formed to at least partly overlap with the conductors 265a and 265b. The insulator 274, the oxide 220a, and the oxide 220b are formed not to overlap with the conductor 265c.

As illustrated in FIG. 13B, the side surfaces of the insulator 274, the oxide 220a, and the oxide 220b may each have a tapered shape. The taper angles of the side surfaces of the insulator 274, the oxide 220a, and the oxide 220b may be greater than or equal to 60° and less than 90°, for example. With such tapered shapes of the side surfaces, the coverage with the insulator 276 and the like can be improved in a later step, so that defects such as a void can be reduced.

Not being limited to the above, the insulator 274, the oxide 220a, and the oxide 220b may have side surfaces that are substantially perpendicular to the top surface of the insulator 272. With such a structure, a plurality of the transistors can be provided with high density in a small area.

A dry etching method or a wet etching method can be employed for the processing. Processing by a dry etching method is suitable for microfabrication. The insulating film 274f, the oxide film 220af, and the oxide film 220bf may be processed under different conditions.

Note that in the lithography method, first, a resist is exposed to light through a mask. Next, a region exposed to light is removed or left using a developing solution, so that a resist mask is formed. Then, etching treatment is performed with the resist mask, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. Alternatively, a liquid immersion technique may be employed in which a gap between a substrate and a projection lens is filled with liquid (e.g., water) in light exposure. Alternatively, an electron beam or an ion beam may be used instead of the light. Note that a mask is unnecessary in the case of using an electron beam or an ion beam. Note that the resist mask can be removed by a dry etching process such as ashing, a wet etching process, a wet etching process after a dry etching process, or a dry etching process after a wet etching process.

In addition, a hard mask formed of an insulator or a conductor may be used under the resist mask. In the case of using a hard mask, a hard mask with a desired shape can be formed in the following manner: an insulating film or a conductive film that is the hard mask material is formed over the oxide film 220bf, a resist mask is formed thereover, and then the hard mask material is etched. The etching of the oxide film 220bf and the like may be performed after removing the resist mask or with the resist mask remaining. In the latter case, the resist mask sometimes disappears during the etching. The hard mask may be removed by etching after the etching of the oxide film 220bf and the like. Meanwhile, the hard mask is not necessarily removed when the hard mask material does not affect later steps or can be utilized in later steps.

Next, by a lithography method, the insulator 272 is processed, the top surface of the conductor 265c is exposed, and the top surface of a portion of the insulator 266 which overlaps with the conductor 209 is exposed (FIG. 13C). Here, the insulator 272 is preferably processed to expose at least the top surface of the conductor 265c, and the number of films processed in the processing step in FIG. 17A can be reduced by removing a portion of the insulator 272 which overlaps with the conductor 209. Furthermore, as described above, examples of a material that is preferably used for the insulator 272 also include a hard-to-etch material; thus, the insulator 272 is preferably opened in advance so that the range of choices of the processing conditions in FIG. 17A can be widened.

A dry etching method or a wet etching method can be employed for the processing. A dry etching method is preferably used because it is suitable for microfabrication. An etching gas containing halogen can be used as an etching gas; specifically, an etching gas containing one or more of fluorine, chlorine, and bromine can be used. As the etching gas, for example, a C₄F₆ gas, a C₅F₆ gas, a C₄F₈ gas, a CF₄ gas, a SF₆ gas, a CHF₃ gas, a Cl₂ gas, a BCl₃ gas, a SiCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the etching gas as appropriate. For example, in the case where hafnium oxide is used for the insulator 272, a mixed gas of C₄F₈, H₂, and Ar can be used as an etching gas. The etching conditions can be set as appropriate depending on an object to be etched.

When the insulator 272 is processed, a depressed portion is sometimes formed in a region of the top surface of the insulator 266 which overlaps with the conductor 209, as illustrated in FIG. 13C.

Next, a conductive film to be a conductor 252_1 is deposited over the insulator 272, the conductor 265c, and the oxide 220b, and a conductive film to be a conductor 252_2 is deposited over the conductive film (FIG. 13D).

The conductive film to be the conductor 252_1 and the conductive film to be the conductor 252_2 can be deposited by a sputtering method, a CVD method, an MBE method, a PLD method, or an ALD method, for example.

In this embodiment, tantalum nitride is deposited by a sputtering method for the conductive film to be the conductor 252_1, and tungsten is deposited for the conductive film to be the conductor 252_2. Note that heat treatment may be performed before the deposition of the conductive film to be the conductor 252_1. This heat treatment may be performed under reduced pressure, and the conductive film to be the conductor 252_1 may be successively deposited without exposure to the air. Such treatment can remove moisture and hydrogen adsorbed on the surface of the oxide 220b and can reduce the moisture concentration and the hydrogen concentration in the oxide 220a and the oxide 220b. The heat treatment is preferably performed at a temperature higher than or equal to 100° C. and lower than or equal to 400° C. In this embodiment, the heat treatment is performed at 200° C.

Next, the conductive film to be the conductor 252_1 and the conductive film to be the conductor 252_2 are processed by a lithography method to form the conductor 252_1 and the conductor 252_2 each of which has an island shape (FIG. 13D). Note that two conductors 252_1 illustrated in FIG. 13D may each be provided in an island shape or may be one island-shaped film having an opening in a position overlapping with the conductor 209. Similarly, two conductors 252_2 illustrated in FIG. 13D may each be provided in an island shape or may be one island-shaped film having an opening in a position overlapping with the conductor 209.

Here, the conductor 252_1 and the conductor 252_2 are formed to at least partly overlap with the conductors 265a, 265b, and 265c. The conductor 252_1 and the conductor 252_2 are provided in part of the opening provided in the insulator 272 and part of the depressed portion of the insulator 266. By forming the conductor 252_1 and the conductor 252_2, part of a region of the insulator 272 overlapping with the conductor 209 is exposed.

A dry etching method or a wet etching method can be employed for the processing. The conductive film to be the conductor 252_1 and the conductive film to be the conductor 252_2 may be processed under different conditions.

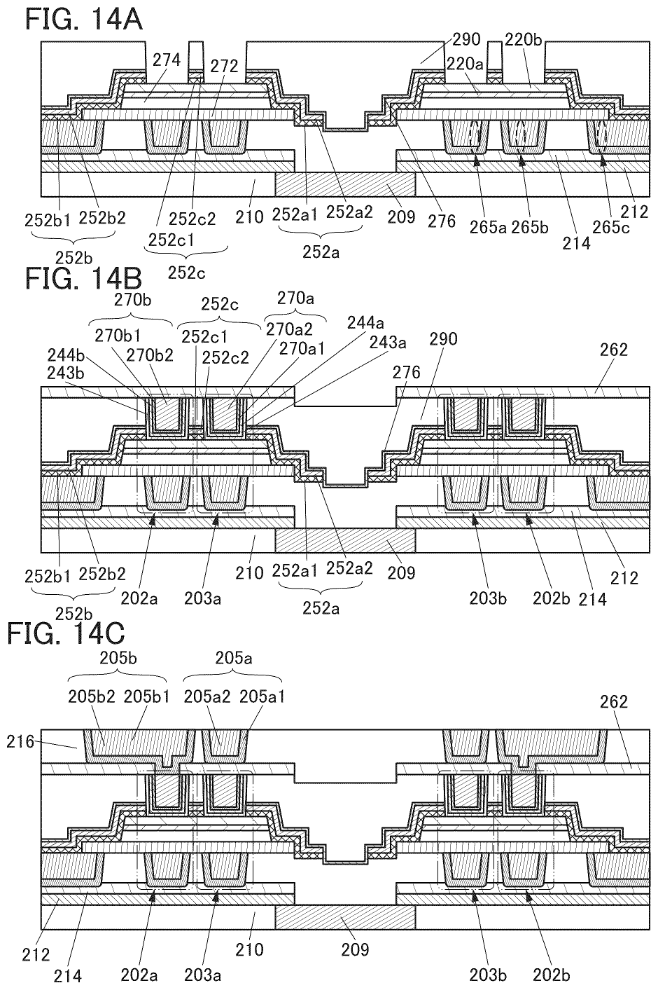

Next, the insulator 276 is deposited to cover the insulator 274, the oxide 220a, the oxide 220b, the conductor 252_1, and the conductor 252_2, and the insulator 290 is deposited over the insulator 276. After that, the conductor 252_1, the conductor 252_2, the insulator 276, and the insulator 290 are processed by a lithography method to form an opening reaching the oxide 220b (FIG. 14A).

Here, it is preferable that the insulator 276 be in contact with the top surface of the insulator 272 and the side surface of the insulator 274.

As the insulator 290, an insulator having a flat top surface is preferably formed in the following manner: an insulating film to be the insulator 290 is formed and then the insulating film is subjected to CMP treatment. Note that, for example, silicon nitride may be deposited over the insulator 290 by a sputtering method and CMP treatment may be performed on the silicon nitride until the insulator 290 is reached.

The opening reaching the oxide 220b is provided in two portions: a region where the oxide 220b and the conductor 265a overlap with each other and a region where the oxide 220b and the conductor 265b overlap with each other.

The insulator 276 and the insulator 290 can each be deposited by a sputtering method, a CVD method, an MBE method, a PLD method, or an ALD method, for example.

As the insulator 276, an insulator having a function of inhibiting passage of oxygen is preferably used. For example, silicon nitride is preferably deposited by an ALD method for the insulator 276. Alternatively, for the insulator 276, it is preferable that aluminum oxide be deposited by a sputtering method, and silicon nitride be deposited thereover by a PEALD method. When the insulator 276 has such a stacked-layer structure, the function of inhibiting diffusion of oxygen and impurities such as water and hydrogen can be improved.

In this manner, the oxide 220a, the oxide 220b, the conductor 252_1, and the conductor 252_2 can be covered with the insulator 276 having a function of inhibiting diffusion of oxygen. Thus, direct diffusion of oxygen from the insulator 290 or the like into the insulator 274, the oxide 220a, the oxide 220b, the conductor 252_1, and the conductor 252_2 in a later step can be suppressed.

For example, silicon oxide is preferably deposited by a sputtering method for the insulator 290. When the insulating film to be the insulator 290 is deposited by a sputtering method in an oxygen-containing atmosphere, the insulator 290 containing excess oxygen can be formed. By using a sputtering method that does not need to use a molecule containing hydrogen as a deposition gas, the hydrogen concentration in the insulator 290 can be reduced. Note that heat treatment may be performed before the deposition of the insulating film. The heat treatment may be performed under reduced pressure, and the insulating film may be successively deposited without exposure to the air. The treatment can remove moisture and hydrogen adsorbed onto the surface of the insulator 276 and the like, and further can reduce the moisture concentration and the hydrogen concentration in the oxide 220a, the oxide 220b, and the insulator 274. For the heat treatment, the above heat treatment conditions can be used.

A dry etching method or a wet etching method can be employed for the processing. The conductor 252_1, the conductor 252_2, the insulator 276, and the insulator 290 may be processed under different conditions.

By the processing, the conductor 252_1 is divided into the conductors 252a1, 252b1, and 252c1 each of which has an island shape. Similarly, the conductor 252_2 is divided into the conductors 252a2, 252b2, and 252c2 each of which has an island shape. Note that two conductors 252a1 illustrated in FIG. 14A may each be provided in an island shape or may be one island-shaped film having an opening in a position overlapping with the conductor 209. Similarly, two conductors 252a2 illustrated in FIG. 14A may each be provided in an island shape or may be one island-shaped film having an opening in a position overlapping with the conductor 209.

By the above etching treatment, impurities are attached to or diffused into the side surface of the oxide 220a, the top surface and the side surface of the oxide 220b, the side surfaces of the conductors 252a, 252b, and 252c, the side surface of the insulator 276, the side surface of the insulator 290, and the like in some cases. A step of removing such impurities may be performed. In addition, a damaged region is formed on the surface of the oxide 220b by the above dry etching in some cases. Such a damaged region may be removed. The impurities result from components contained in the insulator 290, the insulator 276, and the conductors 252a, 252b, and 252c; components contained in a member of an apparatus used to form the opening; and components contained in a gas or a liquid used for etching, for example. Examples of the impurities include hafnium, aluminum, silicon, tantalum, fluorine, and chlorine.

In particular, impurities such as aluminum and silicon reduce the crystallinity of the oxide 220b in some cases. Thus, it is preferable that impurities such as aluminum and silicon be removed from the surface of the oxide 220b and the vicinity thereof. The concentration of the impurities is preferably reduced. For example, the concentration of aluminum atoms of the surface of the oxide 220b and the vicinity thereof is preferably lower than or equal to 5.0 atomic %, further preferably lower than or equal to 2.0 atomic %, still further preferably lower than or equal to 1.5 atomic %, yet still further preferably lower than or equal to 1.0 atomic %, yet further preferably lower than 0.3 atomic %.

Note that since the density of a crystal structure is reduced in a low-crystallinity region of the oxide 220b due to impurities such as aluminum and silicon, a large amount of V_{O}H is formed; thus, the transistor is likely to be normally on. Hence, the low-crystallinity region of the oxide 220b is preferably reduced or removed.

In contrast, the oxide 220b preferably has a layered CAAC structure. In particular, the CAAC structure preferably reaches a lower edge portion of a drain in the oxide 220b. Here, in the transistor, the conductor 252a, the conductor 252b, or the conductor 252c and its vicinity function as a drain. In other words, the oxide 220b in the vicinity of the lower edge portion of the conductor 252a, the conductor 252b, or the conductor 252c preferably has a CAAC structure. In this manner, the low-crystallinity region of the oxide 220b is removed and the CAAC structure is formed also in the edge portion of the drain, which significantly affects the drain breakdown voltage, so that a variation in electrical characteristics of the transistor can be further suppressed. In addition, the reliability of the transistor can be improved.

In order to remove impurities and the like attached to the surface of the oxide 220b in the above etching step, cleaning treatment is performed. Examples of the cleaning method include wet cleaning using a cleaning solution (also can be referred to as wet etching process), plasma treatment using plasma, and cleaning by heat treatment, and any of these cleanings may be performed in combination as appropriate. Note that the cleaning treatment sometimes makes the groove portion deeper.

The wet cleaning may be performed using an aqueous solution in which one or more of ammonia water, oxalic acid, phosphoric acid, and hydrofluoric acid are diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency greater than or equal to 200 kHz is preferable, and a frequency greater than or equal to 900 KHz is further preferable. Damage to the oxide 220b and the like can be reduced with this frequency.

The cleaning treatment may be performed a plurality of times, and the cleaning solution may be changed in every cleaning treatment. For example, the first cleaning treatment may use diluted hydrofluoric acid or diluted ammonia water, and the second cleaning treatment may use pure water or carbonated water.

As the cleaning treatment in this embodiment, wet cleaning using diluted ammonia water is performed. The cleaning treatment can remove impurities that are attached onto or diffused into the surfaces of the oxide 220a, the oxide 220b, and the like. Furthermore, the crystallinity of the oxide 220b can be increased.

After the etching or the cleaning, heat treatment may be performed. It is preferable that the temperature of the heat treatment be higher than or equal to 100° C., higher than or equal to 250° C., or higher than or equal to 350° C. and lower than or equal to 650° C., lower than or equal to 600° C., lower than or equal to 550° C., or lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 220a and the oxide 220b to reduce oxygen vacancies. In addition, the crystallinity of the oxide 220b can be improved by such heat treatment. Furthermore, hydrogen remaining in the oxide 220a and the oxide 220b reacts with supplied oxygen, so that the hydrogen can be removed as H₂O (dehydration can be caused). This can inhibit recombination of hydrogen remaining in the oxide 220a and the oxide 220b with oxygen vacancies and formation of V_{O}H. The heat treatment may be performed under reduced pressure. Alternatively, heat treatment may be performed in an oxygen atmosphere, and then heat treatment may be successively performed in a nitrogen atmosphere without exposure to the air.

In the case where heat treatment is performed in a state where the oxide 220b is in contact with the conductor 252a and the conductor 242b, the sheet resistance is sometimes reduced in each of a region of the oxide 220b which overlaps with the conductor 242a and a region of the oxide 220b which overlaps with the conductor 242b. Furthermore, the carrier concentration is sometimes increased. Thus, the resistance of each of the region of the oxide 220b which overlaps with the conductor 242a and the region of the oxide 220b which overlaps with the conductor 242b can be lowered in a self-aligned manner.

Next, insulating films and conductive films are deposited and processed to fill the opening, whereby the insulator 243a, the insulator 244a, the conductor 270a1, and the conductor 270a2 are provided in a position overlapping with the conductor 265a, and the insulator 243b, the insulator 244b, the conductor 270b1, and the conductor 270b2 are provided in a position overlapping with the conductor 265b (FIG. 14B).

First, an insulating film to be the insulator 243a and the insulator 243b is deposited. The insulating film can be deposited by a sputtering method, a CVD method, an MBE method, a PLD method, or an ALD method, for example. The insulating film is preferably deposited by an ALD method. Like the above-described insulator 253, each of the insulator 243a and the insulator 243b is preferably formed to have a small thickness, and an unevenness of the thickness needs to be reduced. Since an ALD method is a deposition method in which a precursor and a reactant (e.g., oxidizer) are alternately introduced and the thickness can be adjusted with the number of repetition times of the cycle, accurate control of the thickness is possible. Furthermore, as illustrated in FIG. 14B, each of the insulator 243a and the insulator 243b needs to be deposited on the bottom surface and the side surface of the opening with good coverage. With the use of an ALD method, an atomic layer can be deposited one by one on the bottom surface and the side surface of the opening, whereby the insulators 243a and 243b can be formed in the opening with good coverage.

In the case where the insulating film to be the insulators 243a and 243b is deposited by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the oxide 220b can be reduced.

In this embodiment, hafnium oxide is deposited for the insulating film to be the insulators 243a and 243b by a thermal ALD method.

Next, it is preferable to perform microwave treatment in an atmosphere containing oxygen. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHZ.

For the microwave treatment, a microwave treatment apparatus including a power source for generating high-density plasma using a microwave is preferably used, for example. Here, the frequency of the microwave treatment apparatus is preferably set to greater than or equal to 300 MHz and less than or equal to 300 GHz, further preferably greater than or equal to 2.4 GHZ and less than or equal to 2.5 GHZ, for example, can be 2.45 GHZ. Oxygen radicals at a high density can be generated with high-density plasma. The power of the power source that applies microwaves of the microwave treatment apparatus is preferably set to higher than or equal to 1000 W and lower than or equal to 10000 W, preferably higher than or equal to 2000 W and lower than or equal to 5000 W. A power source may be provided to the microwave treatment apparatus to apply RF to the substrate side. Furthermore, application of RF to the substrate side allows oxygen ions generated by the high-density plasma to be introduced into the oxide 220b efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably lower than or equal to 750° C., further preferably lower than or equal to 500° C., and can be approximately 250° C., for example. The oxygen plasma treatment can be followed successively by heat treatment without exposure to air. The temperature of the heat treatment is preferably higher than or equal to 100° C. and lower than or equal to 750° C., further preferably higher than or equal to 300° C. and lower than or equal to 500° C., for example.

Furthermore, the microwave treatment can be performed using an oxygen gas and an argon gas, for example. Here, the oxygen flow rate ratio (O₂/(O₂+Ar)) is higher than 0) % and lower than or equal to 100%. The oxygen flow rate ratio (O₂/(O₂+Ar)) is preferably higher than 0) % and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The carrier concentration in the oxide 220b can be reduced by performing the microwave treatment in an atmosphere containing oxygen. In addition, the carrier concentration in the oxide 220b can be prevented from being excessively reduced by preventing an excess amount of oxygen from being introduced into the chamber in the microwave treatment.

The microwave treatment in an oxygen-containing atmosphere can convert an oxygen gas into plasma using a high-frequency wave such as a microwave or RF, and apply the oxygen plasma to a region of the oxide 220b which is between the conductor 252a and the conductor 252c and a region of the oxide 220b which is between the conductor 252b and the conductor 252c. By the effect of plasma, microwave, or the like, V_{O}H in the region can be divided into oxygen vacancies and hydrogen, and hydrogen can be removed from the region. That is, V_{O}H contained in the channel formation region can be reduced. As a result, oxygen vacancies and V_{O}H in the channel formation region can be reduced to lower the carrier concentration. In addition, oxygen radicals generated by the oxygen plasma can be supplied to oxygen vacancies formed in the channel formation region, thereby further reducing oxygen vacancies and lowering the carrier concentration in the channel formation region.

The oxygen implanted into the channel formation region has any of a variety of forms such as an oxygen atom, an oxygen molecule, an oxygen ion, and an oxygen radical (an O radical, an atom or a molecule having an unpaired electron, or an ion). Note that the oxygen implanted into the channel formation region has any one or more of the above forms, particularly preferably an oxygen radical. Furthermore, the film quality of the insulator 243 can be improved, leading to higher reliability of the transistor.

In contrast, the oxide 220b includes a region overlapping with the conductor 252a, 252b or 252c. The region can function as a source region or a drain region. Here, the conductors 252a, 252b, and 252c preferably function as blocking films preventing the effect caused by the high-frequency wave such as a microwave or RF, the oxygen plasma, or the like in the microwave treatment in an atmosphere containing oxygen. Therefore, the conductors 252a, 252b, and 252c preferably have a function of blocking an electromagnetic wave of greater than or equal to 300 MHz and less than or equal to 300 GHZ, for example, greater than or equal to 2.4 GHZ and less than or equal to 2.5 GHZ.

Since the conductors 252a, 252b, and 252c prevent the effect of the high-frequency wave such as a microwave or RF, the oxygen plasma, or the like, the effect does not reach a region of the oxide 220b which overlaps with the conductors 252a, 252b, or 252c. Hence, a reduction in V_{O}H and supply of an excess amount of oxygen due to the microwave treatment do not occur in the source region and the drain region, preventing a decrease in carrier concentration.

Furthermore, the insulator 243 having a barrier property against oxygen is provided in contact with the side surfaces of the conductors 252a, 252b, and 252c. Thus, formation of an oxide film on the side surfaces of the conductors 252a, 252b, and 252c by the microwave treatment can be inhibited.

Furthermore, the film quality of the insulator 243 can be improved, leading to higher reliability of the transistor.

In the above manner, oxygen vacancies and V_{O}H can be selectively removed from the channel formation region in the oxide semiconductor, whereby the channel formation region can be an i-type or substantially i-type region. Furthermore, supply of an excess amount of oxygen to the region functioning as the source region or the drain region can be inhibited and the conductivity before the microwave treatment is performed (a state of being a low-resistance region) can be maintained. As a result, a change in the electrical characteristics of the transistor can be inhibited, and thus a variation in the electrical characteristics of the transistors in the substrate plane can be inhibited.

In the microwave treatment, thermal energy is directly transmitted to the oxide 220b in some cases owing to an electromagnetic interaction between the microwave and a molecule in the oxide 220b. The oxide 220b may be heated by this thermal energy. Such heat treatment is sometimes referred to as microwave annealing. When microwave treatment is performed in an atmosphere containing oxygen, an effect equivalent to that of oxygen annealing is sometimes obtained. In the case where hydrogen is contained in the oxide 220b, it is probable that the thermal energy is transmitted to the hydrogen in the oxide 220b and the hydrogen activated by the energy is released from the oxide 220b.

Note that microwave treatment may be performed before the deposition of the insulating film to be the insulators 243a and 243b, without the microwave treatment performed after the deposition of the insulating film.

After microwave treatment after the deposition of the insulating film to be the insulators 243a and 243b, heat treatment may be performed with the reduced pressure being maintained. Such treatment enables hydrogen in the insulating film, the oxide 220b, and the oxide 220a to be removed efficiently. Part of hydrogen is sometimes gettered by the conductor 252 (the conductors 252a, 252b, and 252c). Alternatively, the step of performing microwave treatment and then performing heat treatment with the reduced pressure being maintained may be repeated a plurality of cycles. The repetition of the heat treatment enables hydrogen in the insulating film, the oxide 220b, and the oxide 220a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 220b and the like are adequately heated by the microwave annealing.

Furthermore, the microwave treatment improves the film quality of the insulating film to be the insulators 243a and 243b, thereby inhibiting diffusion of hydrogen, water, impurities, and the like. Accordingly, hydrogen, water, impurities, and the like can be inhibited from diffusing into the oxide 220b, the oxide 220a, and the like through the insulator 243 in a later step such as deposition of a conductive film to be the conductor 270 or later treatment such as heat treatment.

Next, an insulating film to be the insulators 244a and 244b is formed. The insulating film can be deposited by a sputtering method, a CVD method, an MBE method, a PLD method, or an ALD method, for example. Like the insulating film to be the insulators 243a and 243b, the insulating film is preferably deposited by an ALD method. By an ALD method, the insulating film to be the insulators 244a and 244b can be deposited to have a small thickness and good coverage. In this embodiment, for the insulating film, silicon nitride is deposited by a PEALD method.

Next, a conductive film to be the conductors 270a1 and 270b1 and a conductive film to be the conductors 270a2 and 270b2 are deposited in this order. The conductive film to be the conductors 270a1 and 270b1 and the conductive film to be the conductors 270a2 and 270b2 can be deposited by a sputtering method, a CVD method, an MBE method, a PLD method, or an ALD method, for example. In this embodiment, titanium nitride is deposited for the conductive film to be the conductors 270a1 and 270b1 by an ALD method, and tungsten is deposited for the conductive film to be the conductors 270a2 and 270b2 by a CVD method.

Next, by CMP treatment, the insulating film to be the insulators 243a and 243b, the insulating film to be the insulators 244a and 244b, the conductive film to be the conductors 270a1 and 270b1, and the conductive film to be the conductors 270a2 and 270b2 are polished until the insulator 290 is exposed. That is, portions of the insulating film to be the insulators 243a and 243b, the insulating film to be the insulators 244a and 244b, the conductive film to be the conductors 270a1 and 270b1, and the conductive film to be the conductors 270a2 and 270b2 that are exposed from the openings are removed. Thus, the insulator 243a, the insulator 244a, and the conductor 270a (the conductor 270a1 and the conductor 270a2) are formed in the opening overlapping with the conductor 265a, and the insulator 243b, the insulator 244b, and the conductor 270b (the conductor 270b1 and the conductor 270b2) are formed in the opening overlapping with the conductor 265b (FIG. 14B).

Accordingly, the insulators 243a and 243b are provided in contact with an inner wall and the side surface of the opening overlapping with the oxide 220b. The insulators 244a and 244b are provided along the inner wall and the side surface of the opening overlapping with the oxide 220b. The conductor 270a is provided to fill the opening with the insulator 243a and the insulator 244a therebetween, and the conductor 270b is provided to fill the opening with the insulator 243b and the insulator 244b therebetween. In this manner, the transistors 202a, 202b, 203a, and 203b are formed. As described above, the transistors 202a, 202b, 203a, and 203b can be manufactured in parallel in the same step.

Then, heat treatment may be performed under conditions similar to those for the above heat treatment. In this embodiment, treatment is performed at 400° C. in a nitrogen atmosphere for one hour. The heat treatment can reduce the moisture concentration and the hydrogen concentration in the insulator 290. After the heat treatment, the insulator 262 may be deposited successively without exposure to the air.

Next, the insulator 262 is formed over the insulators 243a, 243b, 244a, and 244b, the conductors 270a and 270b, and the insulator 290 (FIG. 14B). The insulator 262 can be deposited by a sputtering method, a CVD method, an MBE method, a PLD method, or an ALD method, for example. The insulator 262 is preferably deposited by a sputtering method. By using a sputtering method that does not need to use a molecule containing hydrogen as a deposition gas, the hydrogen concentration in the insulator 262 can be reduced.

In this embodiment, for the insulator 262, aluminum oxide is deposited by a pulsed DC sputtering method using an aluminum target in an atmosphere containing an oxygen gas. The use of the pulsed DC sputtering method can achieve more uniform thickness and improve the sputtering rate and film quality. The RF power applied to the substrate is lower than or equal to 1.86 W/cm². The RF power is preferably higher than or equal to 0 W/cm² and lower than or equal to 0.62 W/cm². Note that an RF power of 0 W/cm² is the same as that RF power is not applied to the substrate. The amount of oxygen implanted to a layer below the insulator 282 can be controlled depending on the amount of the RF power applied to the substrate. For example, the amount of oxygen implanted into the layer below the insulator 262 decreases as the RF power decreases, and the amount of oxygen is easily saturated even when the insulator 262 has a small thickness. Moreover, the amount of oxygen implanted into the layer below the insulator 262 increases as the RF power increases. With low RF power, the amount of oxygen implanted into the insulator 290 can be reduced. Alternatively, the insulator 262 may have a stacked-layer structure of two layers. In that case, the lower layer of the insulator 262 is deposited with an RF power of 0 W/cm² applied to the substrate, and the upper layer of the insulator 262 is deposited with an RF power of 0.62 W/cm² applied to the substrate, for example.

The RF frequency is preferably greater than or equal to 10 MHZ. The typical frequency is 13.56 MHZ. The higher the RF frequency is, the less damage the substrate gets.

The insulator 262 is deposited by a sputtering method in an oxygen-containing atmosphere, whereby oxygen can be added to the insulator 290 during the deposition. Thus, excess oxygen can be contained in the insulator 290. At this time, the insulator 262 is preferably deposited while the substrate is being heated.

Next, the insulator 262 is processed by a lithography method to expose the top surface of the insulator 290 of a portion which overlaps with the conductor 209 (FIG. 14B). When the portion of the insulator 262 which overlaps with the conductor 209 is removed, the number of films processed in the processing step in FIG. 17A can be reduced. Furthermore, as described above, examples of a material that is preferably used for the insulator 262 also include a hard-to-etch material; thus, the insulator 262 is preferably opened in advance so that the range of choices of the processing conditions in FIG. 17A can be widened.

For the formation of the opening, a dry etching method or a wet etching method can be employed. A dry etching method is preferably used because it is suitable for microfabrication. An etching gas containing halogen can be used as an etching gas; specifically, an etching gas containing one or more of fluorine, chlorine, and bromine can be used. As the etching gas, for example, a C₄F₆ gas, a C₅F₆ gas, a C₄F₈ gas, a CF₄ gas, a SF₆ gas, a CHF₃ gas, a Cl₂ gas, a BCl₃ gas, a SiCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the etching gas as appropriate. For example, in the case where aluminum oxide is used for the insulator 262, a mixed gas of CHF₃ and Ar can be used as an etching gas. The etching conditions can be set as appropriate depending on an object to be etched.

When the insulator 262 is processed, a depressed portion is sometimes formed in a region of the top surface of the insulator 290 which overlaps with the conductor 209, as illustrated in FIG. 14B.

Next, the insulator 216 is formed over the insulator 262, and an opening reaching the insulator 262 and an opening reaching the conductor 270b are formed in the insulator 216. Then, the conductors 205a and 205b are formed to fill the openings (FIG. 14C). The conductor 205b is physically and electrically connected to the conductor 270b through the opening provided in the insulator 262.

The timing of forming the opening reaching the conductor 270b in the insulator 262 may be before the formation of the insulator 216 or after the formation of the insulator 216.

The insulator 216 is provided to fill the opening provided in the insulator 262 and the depressed portion of the insulator 290.

For the material and the manufacturing method of the insulator 216, the material and the manufacturing method that can be used for the insulator 266 can be referred to.

For the material and the manufacturing method of the conductors 205a1 and 205b1, the material and the manufacturing method that can be used for the conductors 265a1 and 265b1 can be referred to.

For the material and the manufacturing method of the conductors 205a2 and 205b2, the material and the manufacturing method that can be used for the conductors 265a2 and 265b2 can be referred to.

As a method for forming the conductors 205a and 205b, a dual damascene method is preferably used.

Note that as illustrated in FIG. 5 and the like, the conductor 205b and the conductor 270b may be electrically connected to each other using the conductor 263.

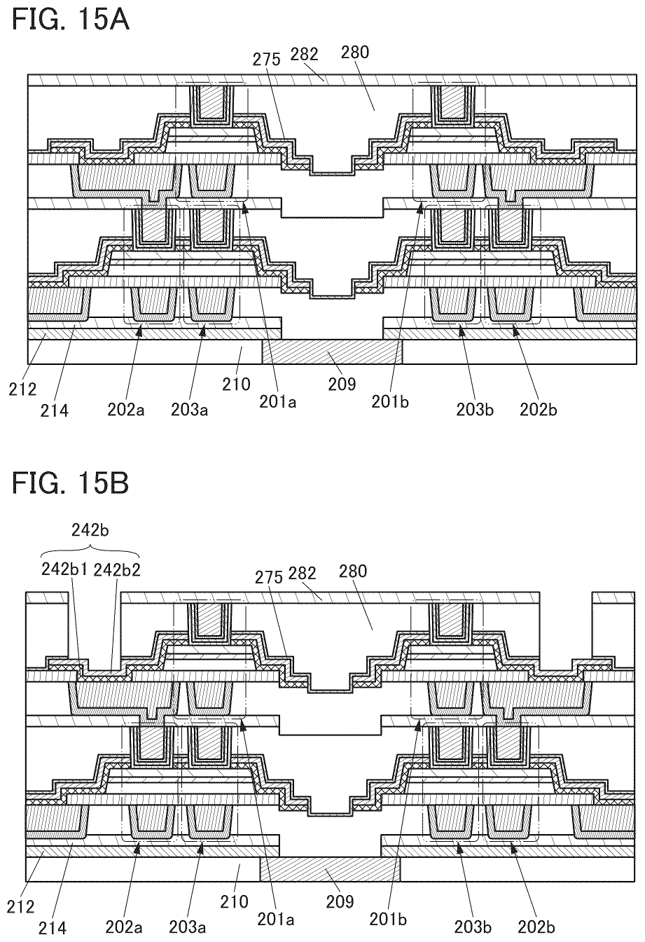

Next, as illustrated in FIG. 15A, the transistors 201a and 201b are formed. As the material and the manufacturing method of each of the layers from the insulator 222 to the insulator 282, the material and the manufacturing method of each of the layers from the insulator 272 to the insulator 262 can be referred to.

Next, as illustrated in FIG. 15B, the insulator 275, the insulator 280, and the insulator 282 are processed to form an opening reaching the conductor 242b.

The width of the opening provided in this step is preferably minute. For example, the width of the opening is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm. In order to form such a minute opening, a lithography method using an electron beam or short-wavelength light such as EUV light is preferably used.

Since the opening provided in this step has a high aspect ratio, part of the insulator 282, part of the insulator 280, and part of the insulator 275 are preferably processed using anisotropic etching. Processing by a dry etching method is particularly preferable because it is suitable for microfabrication. The processing may be performed under different conditions.

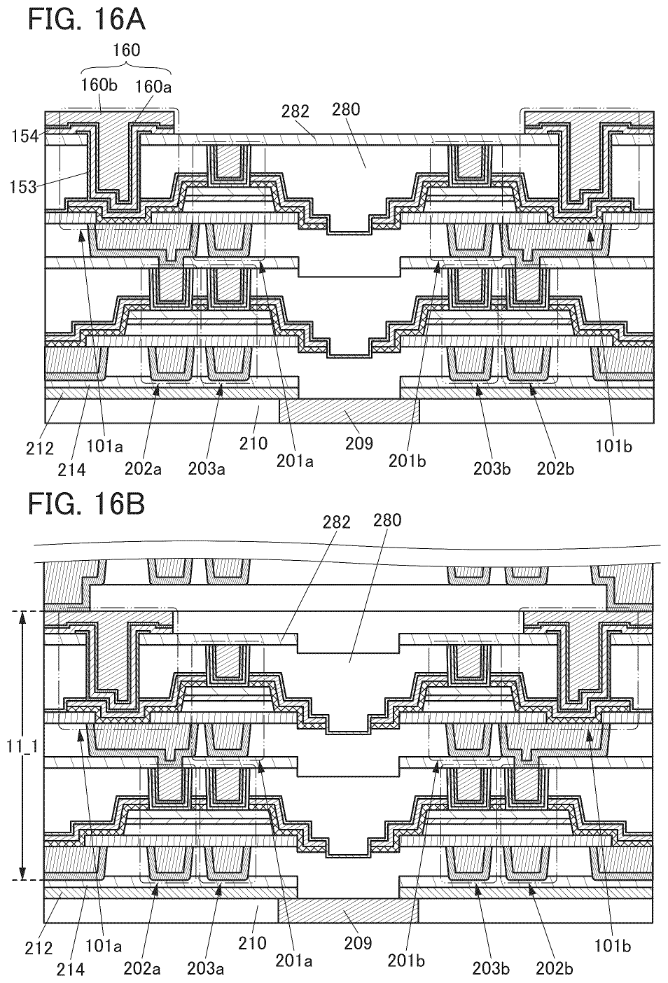

Next, as illustrated in FIG. 16A, the capacitors 101a and 101b are formed to fill the openings. Specifically, the conductor 153, the insulator 154, the conductor 160a, and the conductor 160b are formed.

First, a conductive film to be the conductor 153 is deposited to cover the openings and the insulator 282. The conductive film to be the conductor 153 is preferably formed in contact with the side surface and the bottom surface of each of the openings. For this reason, the conductive film to be the conductor 153 is preferably deposited by a deposition method that provides favorable coverage, such as an ALD method or a CVD method. For example, titanium nitride or tantalum nitride is preferably deposited by an ALD method.

Next, the conductive film to be the conductor 153 is processed by a lithography method to form the conductor 153. Accordingly, part of the conductor 153 is formed inside the opening and is in contact with part of the top surface of the insulator 282.

Alternatively, the conductive film to be the conductor 153 may be processed by a CMP method. In that case, the uppermost portion of the conductor 153 can have a shape substantially aligned with that of the top surface of the insulator 282.

Next, over the conductor 153, an insulating film to be the insulator 154 is deposited. The insulating film to be the insulator 154 is preferably formed in contact with the conductor 153 that is provided inside the opening. Thus, the insulating film to be the insulator 154 is preferably deposited by a deposition method that provides favorable coverage, such as an ALD method or a CVD method. The insulating film to be the insulator 154 is preferably formed using the above-described High-k material.

Next, a conductive film to be the conductor 160a and a conductive film to be the conductor 160b are deposited in this order. The conductive film to be the conductor 160a is preferably formed in contact with the insulating film to be the insulator 154 provided inside the opening, and the conductive film to be the conductor 160b is preferably formed to fill the opening. For this reason, the conductive film to be the conductor 160a and the conductive film to be the conductor 160b are each preferably deposited by a deposition method that provides favorable coverage, such as an ALD method or a CVD method. For example, it is preferable that titanium nitride be deposited for the conductive film to be the conductor 160a by an ALD method, and tungsten be deposited for the conductive film to be the conductor 160b by a CVD method.

In the case where the conductive film to be the conductor 160b is deposited by a CVD method, the average surface roughness of the top surface of the conductive film is sometimes increased. In this case, the conductive film is preferably planarized by a CMP method.

Next, the insulating film to be the insulator 154, the conductive film to be the conductor 160a, and the conductive film to be the conductor 160b are processed by a lithography method to form the insulator 154, the conductor 160a, and the conductor 160b (FIG. 16A). At this time, the insulator 154, the conductor 160a, and the conductor 160b are preferably formed to cover a side end portion of the conductor 153. With such a structure, the conductor 160 and the conductor 153 can be separated by the insulator 154, so that a short circuit between the conductor 160 and the conductor 153 can be inhibited.

Although an example in which the insulating film to be the insulator 154 is processed is described above, the present invention is not limited thereto. A structure may be employed in which only the conductor is processed and the insulating film is left without processing. Thus, the processing step of the insulator 154 can be eliminated and the productivity can be improved.

Through the above steps, a plurality of transistors 201, 202, and 203 and a plurality of capacitors 101 that constitute one memory layer can be formed.

Next, the insulator 282 is processed by a lithography method to expose the top surface of the insulator 280 of a portion overlapping with the conductor 209 (FIG. 16B). When the portion of the insulator 282 overlapping with the conductor 209 is removed, the number of films processed in the processing step in FIG. 17A can be reduced. Furthermore, as described above, examples of a material that is preferably used for the insulator 282 also include a hard-to-etch material; thus, the insulator 282 is preferably opened in advance so that the range of choices of the processing conditions in FIG. 17A can be widened.

For the formation of the opening, a dry etching method or a wet etching method can be employed. A dry etching method is preferably used because it is suitable for microfabrication. An etching gas containing halogen can be used as an etching gas; specifically, an etching gas containing one or more of fluorine, chlorine, and bromine can be used. As the etching gas, for example, a C₄F₆ gas, a C₅F₆ gas, a C₄F₈ gas, a CF₄ gas, a SF₆ gas, a CHF₃ gas, a Cl₂ gas, a BCl₃ gas, a SiCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the etching gas as appropriate. Furthermore, an oxygen gas, a carbonic acid gas, a nitrogen gas, a helium gas, an argon gas, a hydrogen gas, a hydrocarbon gas, or the like can be added to the etching gas as appropriate. For example, in the case where aluminum oxide is used for the insulator 282, a mixed gas of CHF₃ and Ar can be used as an etching gas. The etching conditions can be set as appropriate depending on an object to be etched.

When the insulator 282 is processed, a depressed portion is sometimes formed in a region of the top surface of the insulator 280 which overlaps with the conductor 209, as illustrated in FIG. 16B.

After that, by repeating the above-described manufacture of the transistors 201, 202, and 203 and the capacitor 101, a multilayer memory layer can be formed (FIG. 16B). For example, in the case where a memory device including the N memory layers (Nis an integer greater than or equal to 1) is manufactured, the above-described manufacturing process (from the deposition of the insulator 266 to the formation of the capacitor 101) is repeated N times.

As described above, after the formation of the plurality of transistors 201, 202, and 203 and the plurality of capacitors 101 that constitute the N memory layers, the process proceeds to a step of providing the conductor 240.

Next, an opening reaching the conductor 209 is formed in the insulator 212, the insulator 214, the insulator 266, the insulator 272, the insulator 276, the insulator 290, the insulator 262, the insulator 216, the insulator 222, the insulator 275, the insulator 280, the insulator 282, and the insulator 284 (FIG. 17A). The opening is preferably formed by a lithography method. Here, each of part of the conductors 242a, 242b, 252a, and 252b protrudes in the opening. Thus, in the opening, the side surfaces of the conductors 242a, 242b, 252a, and 252b are formed to protrude more than at least one of the side surfaces of the insulators in which the opening is formed in this step.

When an insulator formed using a hard-to-etch material, such as the insulators 282, 272, and 262 are opened in advance, the processing step in FIG. 17A can be performed with high yield and the productivity of the semiconductor device can be improved.

First, by anisotropic etching, the opening is preferably formed in the insulator 212, the insulator 214, the insulator 266, the insulator 272, the insulator 276, the insulator 290, the insulator 262, the insulator 216, the insulator 222, the insulator 275, the insulator 280, the insulator 282, and the insulator 284, for example. At this time, the width of the opening can be substantially equal to one or both of the width between two conductors 252a and the width between two conductors 242a. A dry etching method is preferably employed for the anisotropic etching.

Next, the width of the opening is preferably widened by isotropic etching. At this time, by using a condition where the conductor 252a and the conductor 242a are not etched or less likely to be etched, the width of the opening in the insulator 212, the insulator 214, the insulator 266, the insulator 272, the insulator 276, the insulator 290, the insulator 262, the insulator 216, the insulator 222, the insulator 275, the insulator 280, the insulator 282, and the insulator 284 can be widened while the width between the two conductors 252a and the width between the two conductors 242a are maintained. A dry etching method or a wet etching method can be used for the isotropic etching.

The anisotropic etching and the isotropic etching are preferably performed successively without exposure to the air in the same etching apparatus with different conditions. For example, in the case where a dry etching method is used for both anisotropic etching and isotropic etching, changing one or more of the conditions such as power supply, bias power, the flow rate of the etching gas, kinds of the etching gas, and the pressure enables switching from the anisotropic etching to the isotropic etching.

Alternatively, different etching methods may be used for the anisotropic etching and the isotropic etching. For example, a dry etching method can be used for the anisotropic etching, and a wet etching method can be used for the isotropic etching.

Next, a conductive film to be the conductor 240a and a conductive film to be the conductor 240b are deposited in this order. The conductive film to be the conductor 240a preferably has a function of inhibiting passage of impurities such as water and hydrogen. As the conductive film to be the conductor 240a, tantalum nitride or titanium nitride can be used, for example. As the conductive film to be the conductor 240b, tungsten, molybdenum, or copper can be used, for example. The conductive films can be deposited by a sputtering method, a CVD method, an MBE method, a PLD method, or an ALD method, for example.

Next, CMP treatment is performed, thereby removing part of the conductive film to be the conductor 240a and part of the conductive film to be the conductor 240b to expose the top surface of the insulator in the uppermost layer. As a result, the conductive films remain only in the openings, so that the conductor 240 (the conductor 240a and the conductor 240b) having flat top surfaces can be formed (FIG. 17B). For example, in FIG. 1, CMP treatment is performed until the insulator 281 is exposed. Note that the top surface of the insulator 281 is partly removed by the CMP treatment in some cases. The conductor 240 is electrically connected to the conductors 209, 242a, 242b, 252a, and 252b.

Through the above steps, the semiconductor device illustrated in FIG. 1 can be manufactured.

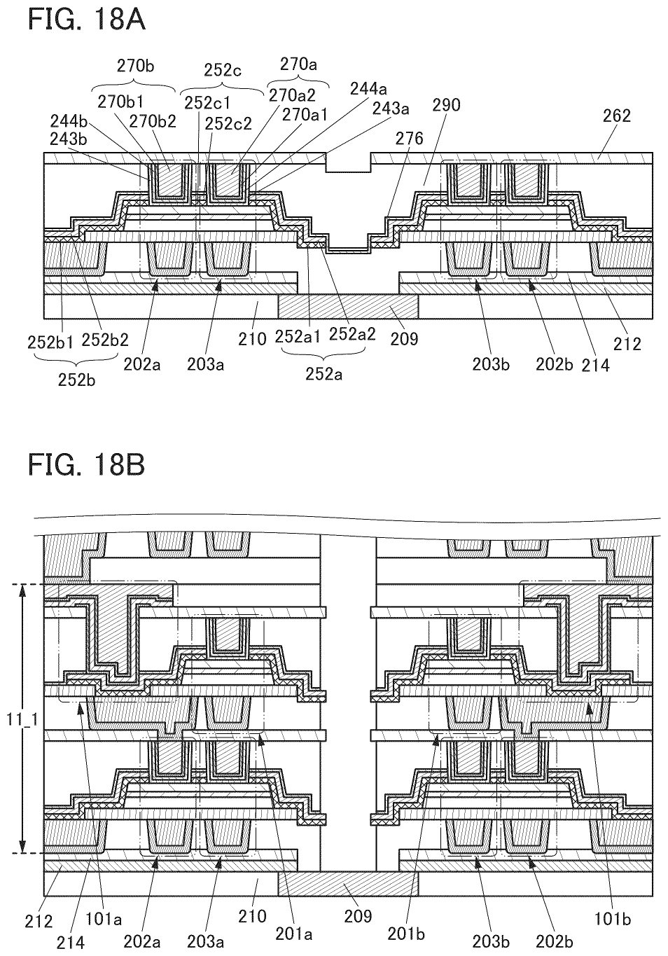

In the case where the semiconductor device having the structure illustrated in FIG. 7 is manufactured, the insulator 262 is processed such that the width of the opening provided in the insulator 262 in FIG. 14B is smaller than the width of the conductor 240 (see FIG. 18A, for example). Similarly, the insulator 282 is processed such that the width of the opening provided in the insulator 282 in FIG. 16B is smaller than the width of the conductor 240. Thus, as illustrated in FIG. 18B, after the opening reaching the conductor 209 is formed, the end portion of the insulator 262 and the end portion of the insulator 282 can protrude from the opening.

In the semiconductor device of this embodiment, when two transistors share a metal oxide and a conductor over the metal oxide, two transistors can be formed in an area smaller than that for two transistors. Thus, miniaturization or high integration of the semiconductor device can be achieved. With the use of the semiconductor device of this embodiment, a memory device with high storage capacity can be obtained. In addition, a memory device occupying a small area can be provided.

The semiconductor device of this embodiment includes an OS transistor. Since the off-state current of an OS transistor is low, a semiconductor device or a memory device with low power consumption can be achieved. Since an OS transistor has high frequency characteristics, a semiconductor device or a memory device that can operate at high speed can be achieved. With the use of an OS transistor, a semiconductor device having favorable electrical characteristics, a semiconductor device in which a variation in electrical characteristics of transistors is small, a semiconductor device with a high on-state current, or a semiconductor device or a memory device with high reliability can be achieved.

This embodiment can be combined with the other embodiments as appropriate. In this specification, in the case where a plurality of structure examples are described in one embodiment, the structure examples can be combined as appropriate.

### Embodiment 2

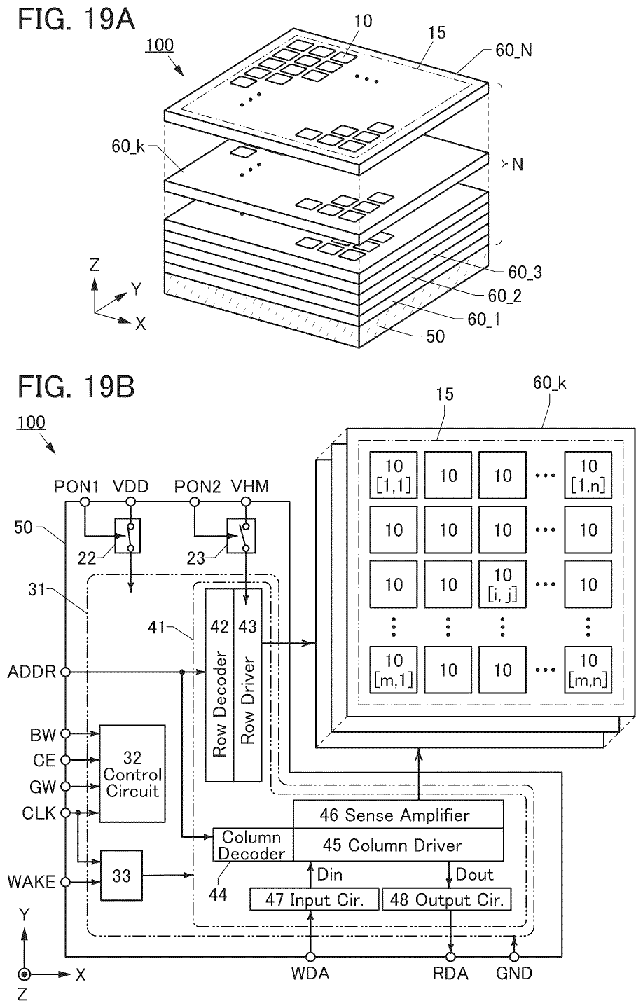

In this embodiment, a memory device of one embodiment of the present invention will be described with reference to FIG. 19 to FIG. 24.

FIG. 19A illustrates a schematic perspective view of a memory device of one embodiment of the present invention. FIG. 19B is a block diagram of the memory device of one embodiment of the present invention.

A memory device 100 illustrated in FIG. 19A and FIG. 19B includes the driver circuit layer 50 and N memory layers 60 (N is an integer greater than or equal to 1). The memory layers 60 each include a memory cell array 15. The memory cell array 15 includes a plurality of memory cells 10 (also referred to as memory elements).

The N memory layers 60 are provided over the driver circuit layer 50. Provision of the N memory layers 60 over the driver circuit layer 50 can reduce the area occupied by the memory device 100. Furthermore, the storage capacity per unit area can also be increased.

In this embodiment and the like, the first memory layer 60 is denoted by a memory layer 60_1, the second memory layer 60 is denoted by a memory layer 60_2, and the third memory layer 60 is denoted by a memory layer 60_3. Furthermore, the k-th memory layer 60 (k is an integer greater than or equal to 1 and less than or equal to N) is denoted by a memory layer 60_k, and the N-th memory layer 60 is denoted by a memory layer 60_N. Note that in this embodiment and the like, the “memory layer 60” is merely stated in some cases when describing a matter related to all the N memory layers 60 or showing a matter common to the N memory layers 60.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs a logical operation on the signal CE, the signal GW, and the signal BW to determine an operation mode (e.g., a writing operation or a reading operation) of the memory device 100. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47 (Input Cir.), an output circuit 48 (Output Cir.), and a sense amplifier circuit 46 (Sense Amplifier).

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring WWL (write word line) or a wiring SL (read word line) specified by the row decoder 42. The column driver 45 has a function of writing data to the memory cells 10, a function of reading data from the memory cells 10, a function of retaining the read data, and the like. The column driver 45 has a function of selecting a wiring BL (write and read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 100, a high power supply voltage is VDD and a low power supply voltage is GND (a ground potential). In addition, VHM is a high power supply voltage used to set a word line at a high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 19B but can be more than one. In this case, a power switch is provided for each power domain.

### <Structure Example of Memory Layer 60>

A structure example of the N memory layers 60 is described. Each of the N memory layers 60 includes the memory cell array 15. The memory cell array 15 includes the plurality of memory cells 10. FIG. 19A and FIG. 19B illustrate an example in which the memory cell array 15 includes the plurality of memory cells 10 arranged in a matrix of m rows and n columns (each of m and n is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”

In FIG. 19B, the memory cell 10 in the first row and the first column is referred to as a memory cell 10[1,1], and the memory cell 10 in the m-th row and the n-th column is referred to as a memory cell 10[m,n]. The memory cell 10 in the i-th row and the j-th column (i is an integer greater than or equal to 1 and less than or equal to m, and j is an integer greater than or equal to 1 and less than or equal to n) is referred to as a memory cell 10[i,j].

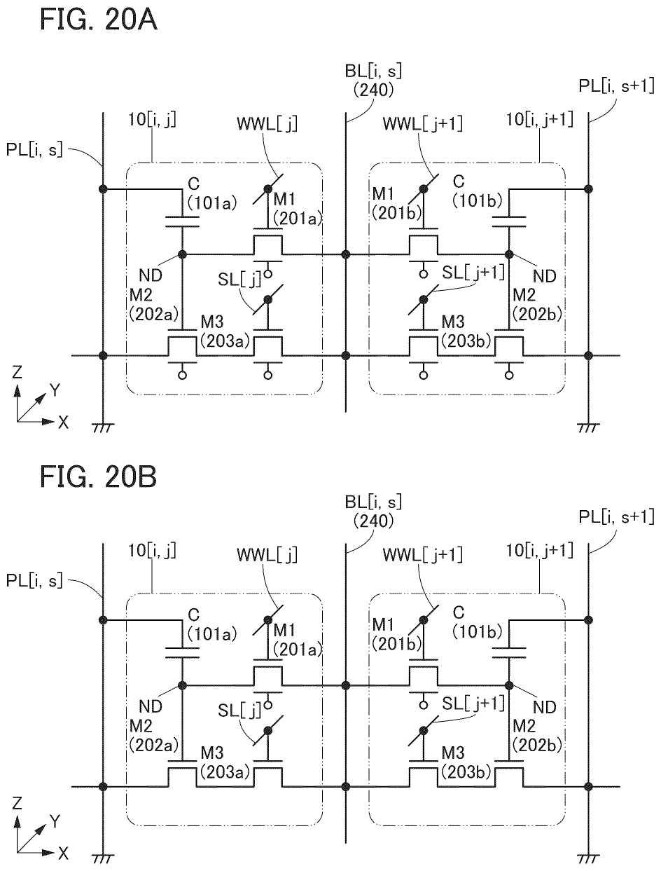

FIG. 20A and FIG. 20B illustrate circuit structure examples of the memory cell. Embodiment 1 can be referred to for a cross-sectional structure example of the memory cell 10 corresponding to the circuit structure.

As described in Embodiment 1, in the semiconductor device of one embodiment of the present invention, the wiring BL[i,s] (s is an integer greater than or equal to 1 and less than or equal to n/2 when n is an even number, and n is an integer greater than or equal to 1 and less than or equal to (n+1)/2 when n is an odd number) (the conductor 240) is directly in contact with both of at least one of the top surface, the side surface, and the bottom surface of the conductor 242a including a region that functions as one of a source electrode and a drain electrode of a transistor M1 (the transistor 201a) and at least one of the top surface, the side surface, and the bottom surface of the conductor 252a including a region that functions as one of a source electrode and a drain electrode of a transistor M3 (the transistor 203a). Thus, a separate electrode for connection does not need to be provided, so that the area occupied by the memory array 15 can be reduced. In addition, the integration degree of the memory cells 10 can be increased and the storage capacity of the memory device 100 can be increased.

The memory cell 10 includes the transistor M1, a transistor M2, the transistor M3, and a capacitor C. A memory cell including three transistors and one capacitor is also referred to as a 3Tr1C memory cell. Thus, the memory cell 10 shown in this embodiment is a 3Tr1C memory cell.

The memory cell 10 can be referred to as a NOSRAM (registered trademark, Nonvolatile Oxide Semiconductor Random Access Memory).

The transistor M1 corresponds to the transistor 201a or the transistor 201b described in Embodiment 1. The transistor M2 corresponds to the transistor 202a or the transistor 202b described in Embodiment 1. The transistor M3 corresponds to the transistor 203a or the transistor 203b described in Embodiment 1. The capacitor C corresponds to the capacitor 101a or the capacitor 101b described in Embodiment 1. The wiring BL corresponds to the conductor 240 described in Embodiment 1.

In the memory cell 10[i,j], a gate of the transistor M1 is electrically connected to the wiring WWL[j], and one of a source and a drain of the transistor M1 is electrically connected to the wiring BL[i,s]. Note that FIG. 20A illustrates a structure example in which part of the wiring WWL[j] functions as the gate of the transistor M1. One electrode of the capacitor C is electrically connected to a wiring PL[i,s], and the other electrode thereof is electrically connected to the other of the source and the drain of the transistor M1. FIG. 20A and the like illustrate a structure example in which part of the wiring PL[i,s] functions as the one electrode of the capacitor C. A gate of the transistor M2 is electrically connected to the other electrode of the capacitor C, one of a source and a drain of the transistor M2 is electrically connected to one of a source and a drain of the transistor M3, and the other of the source and the drain of the transistor M2 is electrically connected to the wiring PL[i,s]. A gate of the transistor M3 is electrically connected to the wiring SL[j] and the other of the source and the drain of the transistor M3 is electrically connected to the wiring BL[i,s].

In the memory cell 10[i,j], a region where the other electrode of the capacitor C, the other of the source and the drain of the transistor M1, and the gate of the transistor M2 are electrically connected to one another and always have the same potential is referred to as a “node ND”.

In the memory cell 10[i,j+1], the gate of the transistor M1 is electrically connected to the wiring WWL[j+1], and one of the source and the drain of the transistor M1 is electrically connected to the wiring BL[i,s]. Note that FIG. 20A illustrates a structure example in which part of the wiring WWL[j+1] functions as the gate of the transistor M1. One electrode of the capacitor C is electrically connected to the wiring PL[i,s+1] and the other electrode thereof is electrically connected to the other of the source and the drain of the transistor M1. Note that FIG. 20A and the like illustrate a structure example in which part of the wiring PL[i,s+1] functions as the one electrode of the capacitor C. The gate of the transistor M2 is electrically connected to the other electrode of the capacitor C, one of the source and the drain of the transistor M2 is electrically connected to the one of the source and the drain of the transistor M3, and the other of the source and the drain of the transistor M2 is electrically connected to the wiring PL[i,s+1]. The gate of the transistor M3 is electrically connected to the wiring SL[j+1], and the other of the source and the drain thereof is electrically connected to the wiring BL[i,s].

In the memory cell 10[i,j+1], a region where the other electrode of the capacitor C, the other of the source and the drain of the transistor M1, and the gate of the transistor M2 are electrically connected to one another and always have the same potential is referred to as the node ND.

As illustrated in FIG. 20A, a transistor with a back gate may be used as each of the transistor M1, the transistor M2, and the transistor M3. The gate and the back gate are provided so that a channel formation region of a semiconductor is sandwiched between the gate and the back gate. The gate and the back gate are formed using a conductor. The back gate can function in a manner similar to that of the gate. The threshold voltage of the transistor can be changed by changing the potential of the back gate. The potential of the back gate may be the same as that of the gate or may be a ground potential or a given potential.

Each of the transistor M1, the transistor M2, and the transistor M3 does not necessarily include a back gate. For example, as illustrated in FIG. 20B, a transistor with a back gate may be used as the transistor M1 and a transistor without a back gate may be used as each of the transistor M2 and the transistor M3.

The gate and the back gate are formed using conductors and thus each have a function of preventing an electric field generated outside the transistor from affecting the semiconductor in which a channel is formed (in particular, a function of blocking static electricity). That is, the variation in the electrical characteristics of the transistor due to the influence of external electric field such as static electricity can be prevented. Providing the back gate enables a reduction in the amount of change in the threshold voltage of the transistor before and after a BT test can be reduced.

For example, the use of a transistor with a back gate as the transistor M1 can reduce the influence of an external electric field, allowing the transistor M1 to be maintained in a stable off state. Thus, data written to the node ND can be retained stably. Providing the back gate can stabilize the operation of the memory cells 10 and can improve the reliability of the memory device including the memory cells 10.

Likewise, the use of a transistor with a back gate as the transistor M3 can reduce the influence of an external electric field, allowing the transistor M3 to be maintained in a stable off state. Thus, leakage current between the wiring BL and the wiring PL can be reduced, resulting in a reduction in the power consumption of the memory device including the memory cells 10.

For a semiconductor layer in which the channel of each of the transistor M1, the transistor M2, and the transistor M3 is formed, one or a combination of a single crystal semiconductor, a polycrystalline semiconductor, a microcrystalline semiconductor, an amorphous semiconductor, and the like can be used. Examples of the semiconductor material include silicon and germanium. Alternatively, a compound semiconductor such as silicon germanium, silicon carbide, gallium arsenide, an oxide semiconductor, or a nitride semiconductor can be used.

Each of the transistor M1, the transistor M2, and the transistor M3 is preferably a transistor using an oxide semiconductor, which is one type of metal oxide, in a semiconductor layer where a channel is formed (also referred to as an “OS transistor”). An oxide semiconductor has a band gap of 2 eV or more, achieving an extremely low off-state current. Accordingly, the power consumption of the memory cell 10 can be reduced. Accordingly, the power consumption of the memory device 100 including the memory cells 10 can be reduced.

A memory cell including an OS transistor can be referred to as an “OS memory”. The memory device 100 including the memory cells can also be referred to as an “OS memory”.

The OS transistor operates stably even in a high-temperature environment and has a small variation in characteristics. For example, the off-state current hardly increases even in a high-temperature environment. Specifically, the off-state current hardly increases even at an environment temperature higher than or equal to room temperature and lower than or equal to 200° C. In addition, the on-state current of the OS transistor is less likely to decrease even in a high-temperature environment. Thus, the OS memory achieves a stable operation and high reliability even in a high-temperature environment.

### <Operation Example of Memory Cell 10>

Examples of a data writing operation and a data reading operation on the memory cell 10 will be described. Note that each of the transistor M1, the transistor M2, and the transistor M3 is preferably a normally-off transistor. Described below is the case where a normally-off n-channel transistor is used as each of the transistor M1, the transistor M2, and the transistor M3.

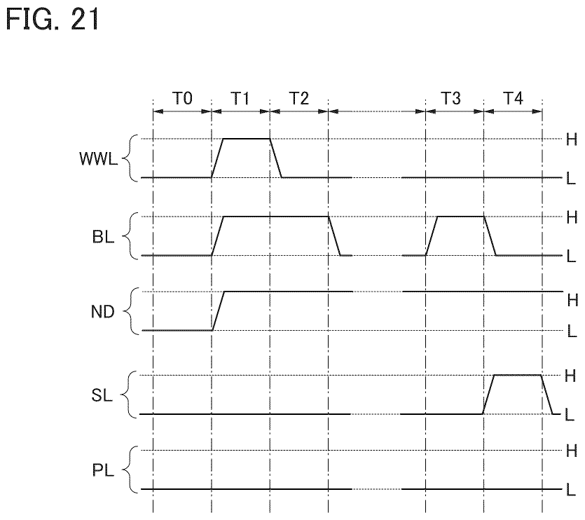

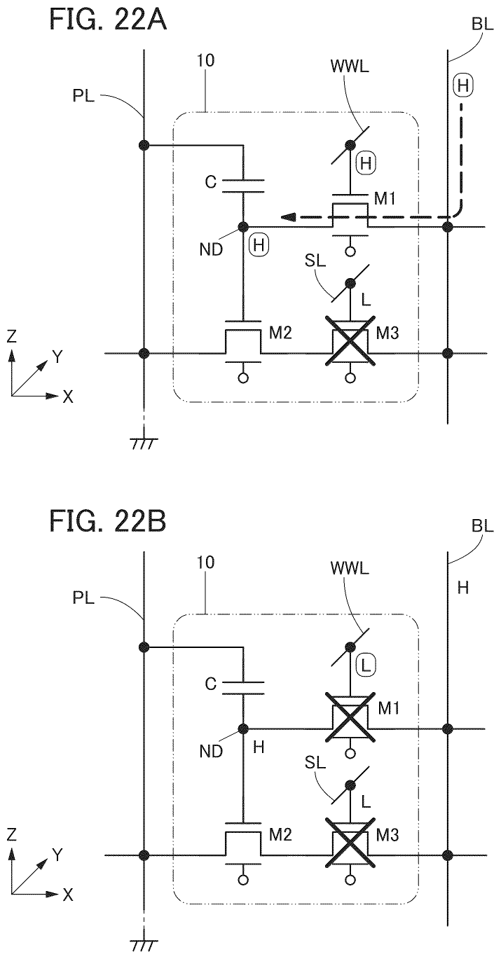

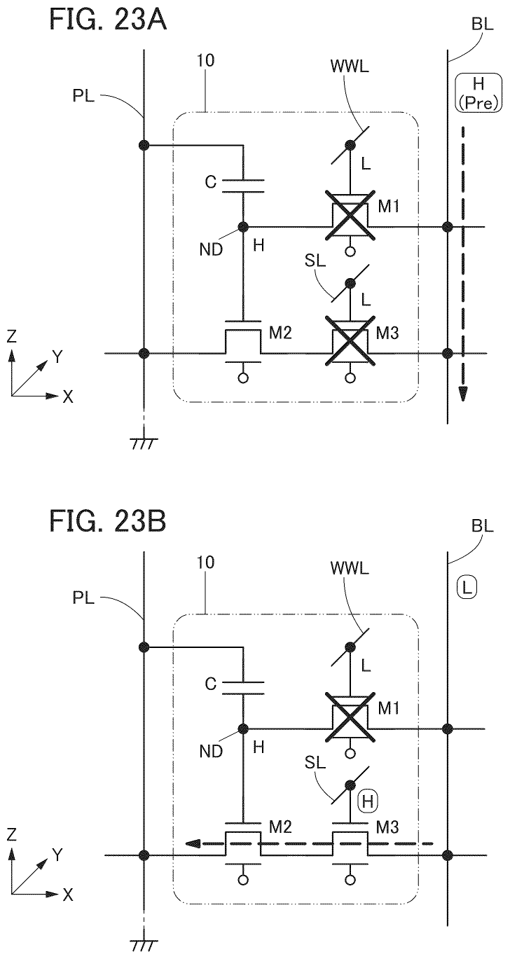

FIG. 21 is a timing chart showing an operation example of the memory cell 10. FIG. 22A, FIG. 22B, FIG. 23A, and FIG. 23B are circuit diagrams showing operation examples of the memory cell 10.

In the drawings and the like, for showing the potentials of a wiring and an electrode, “H” representing a potential H or “L” representing a potential L is sometimes written near the wiring and the electrode. In addition, enclosed “H” or “L” is sometimes written near a wiring and an electrode whose potentials are changed. Moreover, in the case where a transistor is in an off state, a symbol “x” is sometimes written on the transistor.

When the potential H is supplied to a gate of an n-channel transistor, the transistor is turned on. When the potential L is supplied to the gate of the n-channel transistor, the transistor is turned off. Thus, the potential H is a potential higher than the potential L. The potential H may be a potential equal to the high power supply potential VDD. The potential L is a potential lower than the potential H. The potential L may be a potential equal to a ground potential GND. In this embodiment, the potential L is set to a potential equal to the ground potential GND.

First, in Period TO, the wiring WWL, the wiring BL, the wiring SL, the wiring PL, and the node ND are set to the potential L (FIG. 21). In addition, the ground potential GND is supplied to the back gates of the transistor M1, the transistor M2, and the transistor M3.

### [Data Writing Operation]

In Period T1, the potential H is supplied to the wiring WWL and the wiring BL (FIG. 21 and FIG. 22A). Accordingly, the transistor M1 is turned on, and the potential H is written to the node ND as data indicating “1”.

When the potential of the node ND becomes the potential H, the transistor M2 is turned on. Since the potential of the wiring SL is the potential L, the transistor M3 is in the off state. The transistor M3 in the off state can prevent a short circuit between the wiring BL and the wiring PL.

### [Retaining Operation]

In Period T2, the potential L is supplied to the wiring WWL. Then, the transistor M1 is turned off and the node ND is brought into a floating state. Thus, data (potential H) written to the node ND is retained (FIG. 21 and FIG. 22B).

As described above, the OS transistor is a transistor having an extremely low off-state current. When the OS transistor is used as the transistor M1, the data written to the node ND can be retained for a long period. Therefore, the necessity of refreshing the node ND is eliminated or the frequency of the refresh operation of the node ND can be extremely reduced, so that the power consumption of the memory cell 10 can be reduced. Thus, the power consumption of the memory device 100 can be reduced.

When the OS transistor is used as one or both of the transistor M2 and the transistor M3, the amount of leakage current flowing between the wiring BL and the wiring PL in the writing operation and retaining operation can be significantly reduced.

In addition, the OS transistor has a higher withstand voltage between its source and drain than a Si transistor. When the OS transistor is used as the transistor M1, a higher potential can be supplied to the node ND. This increases the range of a potential retained at the node ND. An increase in the range of the potential retained at the node ND makes it easy to retain multilevel data or to retain analog data.

### [Reading Operation]

In Period T3, the wiring BL is precharged to the potential H. That is, the potential of the wiring BL is set to the potential H, and then the wiring BL is brought into a floating state (FIG. 21 and FIG. 23A).

Next, the potential H is supplied to the wiring SL in Period T4, so that the transistor M3 is turned on (FIG. 21 and FIG. 23B). In the case where the potential of the node ND is the potential H at this time, electrical continuity is established between the wiring BL and the wiring PL through the transistor M2 and the transistor M3 because the transistor M2 is in the on state. When electrical continuity is established between the wiring BL and the wiring PL, the potential of the wiring BL, which is in a floating state, changes from the potential H to the potential L.

Note that the transistor M2 is in the off state in the case where the potential L is written to the node ND as data indicating “0”. Thus, electrical continuity is not established between the wiring BL and the wiring PL even when the transistor M3 is turned on, and the potential of the wiring BL remains at the potential H.

By thus detecting a change in the potential of the wiring BL when the potential H is supplied to the wiring SL, data written to the memory cell 10 can be read.

In the memory cell 10 including the OS transistor, charge is written to the node ND through the OS transistor; hence, high voltage, which a conventional flash memory requires, is unnecessary and high-speed write operation is possible. Unlike in a flash memory, charge injection and extraction into/from a floating gate or a charge trap layer are not performed in the memory cell 10 including the OS transistor, allowing a substantially unlimited number of data writing and reading operations. Furthermore, unlike in a flash memory, instability due to an increase of electron trap centers is not observed in the memory cell 10 including the OS transistor even when rewrite operation is repeated. The memory cell 10 including the OS transistor is less likely to degrade than a conventional flash memory and can have high reliability.

Unlike a magnetic memory, a resistive random access memory, or the like, the memory cell 10 including the OS transistor has no change in the structure at the atomic level. Thus, the memory cell 10 including the OS transistor has higher write endurance than the magnetic memory and the resistive random access memory.

### <Structure Example of Sense Amplifier Circuit 46>

Next, a structure example of the sense amplifier circuit 46 is described. Specifically, a structure example of a write read circuit, which includes the sense amplifier circuit 46 and performs writing or reading of a data signal, is described.

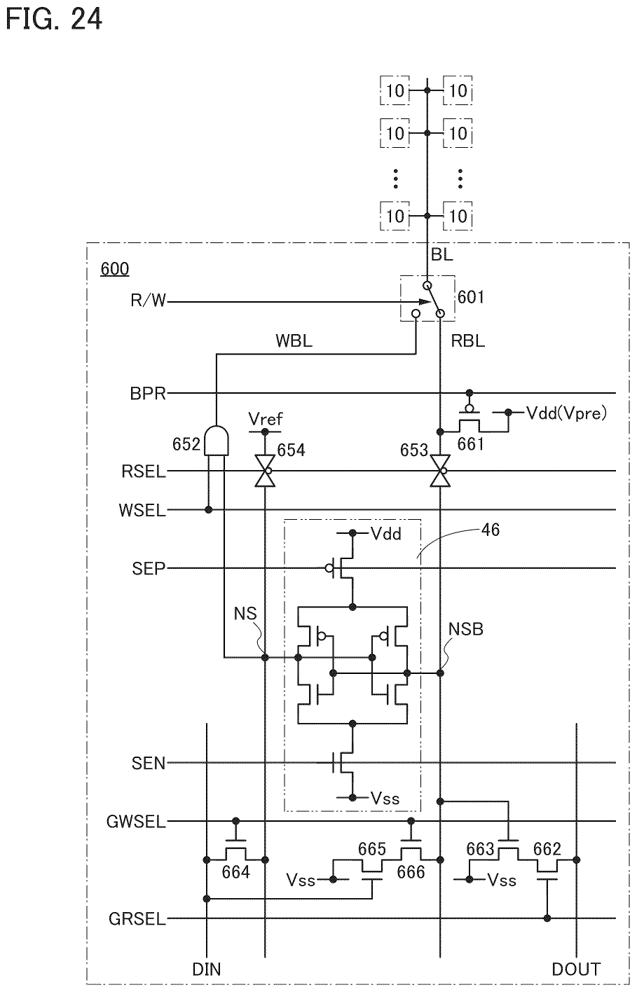

FIG. 24 is a circuit diagram showing a structure example of a circuit 600, which includes the sense amplifier circuit 46 and performs writing or reading of a data signal. The wiring BL connected to the memory cell 10 is provided with the circuit 600 illustrated in FIG. 24 for each column.

The circuit 600 includes a switching circuit 601, a transistor 661 to a transistor 666, the sense amplifier circuit 46, an AND circuit 652, an analog switch 653, and an analog switch 654.

The circuit 600 operates in accordance with a signal R/W, a signal SEN, a signal SEP, a signal BPR, a signal RSEL, a signal WSEL, a signal GRSEL, and a signal GWSEL.

Data DIN input to the circuit 600 is transmitted to the wiring BL through the wiring WBL electrically connected to a node NS and is written to the memory cell 10. The data DOUT written to the memory cell 10 is transmitted to a wiring RBL electrically connected to a node NSB through the wiring BL and output from the circuit 600 as data DOUT.

Note that the data DIN and the data DOUT are internal signals and correspond to the signal WDA and the signal RDA, respectively.

The transistor 661 constitutes a precharge circuit. The wiring BL and the wiring RBL are precharged to a precharge potential Vpre by the transistor 661. Note that in this embodiment, the case where a potential Vdd (high level) (denoted by Vdd (Vpre) in FIG. 24) is used as the precharge potential Vpre is described. The signal BPR is a precharge signal and controls the conduction state of the transistor 661.

In the reading operation, the sense amplifier circuit 46 determines whether data input to the wiring RBL is at a high level or a low level through the wiring BL. In the writing operation, the sense amplifier circuit 46 functions as a latch circuit that temporarily retains the data DIN input to the circuit 600.

The sense amplifier circuit 46 illustrated in FIG. 24 is a latch sense amplifier. The sense amplifier circuit 46 includes two inverter circuits, and an input node of one of the inverter circuits is connected to an output node of the other of the inverter circuits. When the input node and the output node of the one of the inverter circuits are the node NS and the node NSB, respectively, complementary data is retained at the node NS and the node NSB.

The signal R/W is a signal for switching the conduction state between the wiring BL and the wiring WBL or the conduction state between the wiring BL and the wiring RBL. When an analog switch is controlled by the signal R/W, the switching circuit 601 can switch the conduction state between the wiring BL and the wiring WBL or the conduction state between the wiring BL and the wiring RBL. Note that the signal R/W can be a signal that can be switched at the same timing as the signal WSEL that is a write selection signal and the signal RSEL that is a read selection signal.

The switching circuit 601 can establish electrical continuity between the wiring BL and the wiring WBL at the time of data writing and electrical continuity between the wiring BL and the wiring RBL at the time of data reading. The wiring BL can function as both a wiring for writing data to the memory cell 10 and a wiring for reading data from the memory cell 10. Thus, the number of wirings between the memory cell 10 and the circuit 600 including the sense amplifier circuit 46 can be reduced.

The signal SEN and the signal SEP are each a sense amplifier enable signal for activating the sense amplifier circuit 46, and a reference potential Vref is a read judge potential. The sense amplifier circuit 46 determines whether the potential of the node NSB at the time of the activation is at a high level or a low level on the basis of the reference potential Vref.

The AND circuit 652 controls the conduction state between the node NS and the wiring WBL. The analog switch 653 controls the conduction state between the node NSB and the wiring RBL, and the analog switch 654 controls the conduction state between the node NS and a wiring for supplying the reference potential Vref.

In data reading, the wiring BL and the wiring RBL are brought into the conducting state and the potential of the wiring RBL that is the same potential as the potential of the wiring BL is transmitted to the node NSB by the analog switch 653. When the potential of the wiring RBL is lower than the reference potential Vref, the sense amplifier circuit 46 determines that the wiring RBL is at a low level. When the potential of the wiring RBL that is the same potential as the potential of the wiring BL is not lower than the reference potential Vref, the sense amplifier circuit 46 determines that the wiring RBL is at a high level.

The signal WSEL is a write selection signal, which controls the AND circuit 652. The signal RSEL is a read selection signal, which controls the analog switch 653 and the analog switch 654.

The transistor 662 and the transistor 663 constitute an output MUX (multiplexer) circuit. The signal GRSEL is a global read selection signal and controls the output MUX circuit. The output MUX circuit has a function of selecting the wiring RBL for data reading.

The output MUX circuit has a function of outputting the data DOUT read from the sense amplifier circuit 46.

The transistor 664, the transistor 665, and the transistor 666 constitute a write driver circuit. The signal GWSEL is a global write selection signal and controls the write driver circuit. The write driver circuit has a function of writing the data DIN to the sense amplifier circuit 46.

The write driver circuit has a function of selecting a column to which the data DIN is to be written. The write driver circuit writes data in byte units, half-word units, or word units in response to the signal GWSEL.

In a gain-cell memory cell, at least two transistors are required for one memory cell, which makes it difficult to increase the number of memory cells that can be arranged per unit area. However, when an OS transistor is used as a transistor included in the memory cell 10, a plurality of memory cell arrays 15 can be provided to be stacked. That is, the amount of data that can be stored per unit area can be increased. The gain-cell memory cell can operate as a memory by amplifying accumulated charge by the closest transistor even when charge is accumulated in small capacitance. Furthermore, the capacitance of a capacitor can be reduced by using an OS transistor with an extremely low off-state current as a transistor included in the memory cell 10. Alternatively, one or both of the gate capacitance of the transistor and the parasitic capacitance of the wiring can be utilized as a capacitor, in which case the capacitor can be omitted. That is, the area of the memory cell 10 can be made small.

This embodiment can be combined with the other embodiments as appropriate.

### Embodiment 3

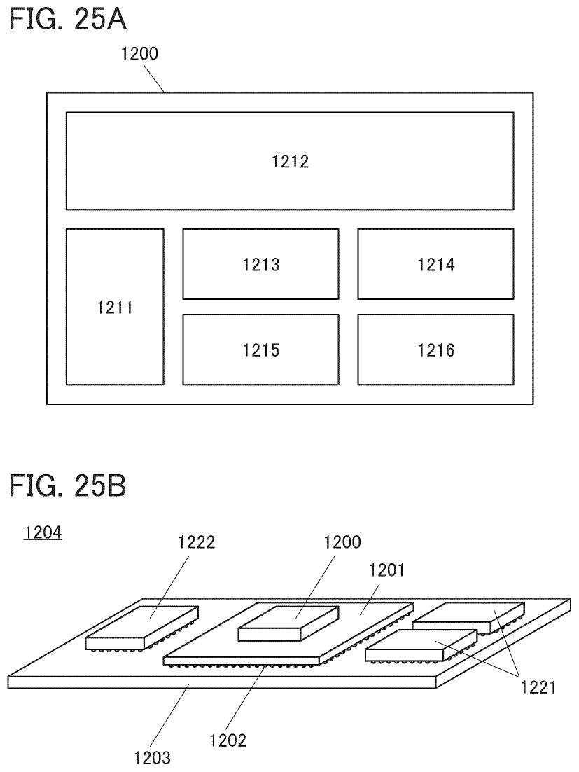

In this embodiment, an example of a chip on which the memory device of one embodiment of the present invention is mounted will be described with reference to FIG. 25.

A plurality of circuits (systems) are mounted on a chip 1200 illustrated in FIG. 25A and FIG. 25B. The technique for integrating a plurality of circuits (systems) on one chip is referred to as system on chip (SoC) in some cases.

As illustrated in FIG. 25A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 25B, the chip 1200 is connected to a first surface of a package substrate 1201. A plurality of bumps 1202 are provided on the rear side of the first surface of the package substrate 1201, and the package substrate 1201 is connected to a motherboard 1203.

A memory device such as a DRAM 1221 or a flash memory 1222 may be provided over the motherboard 1203. For example, the NOSRAM described in the above embodiment can be used as the DRAM 1221. This can make the DRAM 1221 have low power consumption, operate at high speed, and have a large capacity.

The CPU 1211 preferably includes a plurality of CPU cores. The GPU 1212 preferably includes a plurality of GPU cores. The CPU 1211 and the GPU 1212 may each include a memory for storing data temporarily. Alternatively, a common memory for the CPU 1211 and the GPU 1212 may be provided in the chip 1200. The NOSRAM described above can be used as the memory. The GPU 1212 is suitable for parallel computation of a large number of data and thus can be used for image processing or product-sum operation. When an image processing circuit or a product-sum operation circuit including an OS transistor is provided in the GPU 1212, image processing or product-sum operation can be performed with low power consumption.

In addition, since the CPU 1211 and the GPU 1212 are provided in the same chip, a wiring between the CPU 1211 and the GPU 1212 can be shortened; accordingly, the data transfer from the CPU 1211 to the GPU 1212, the data transfer between the memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the analog arithmetic unit 1213 may include the above-described product-sum operation circuit.

The memory controller 1214 includes a circuit functioning as a controller of the DRAM 1221 and a circuit functioning as the interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit of a LAN (Local Area Network) or the like. Furthermore, the network circuit 1216 may include a circuit for network security.

The circuits (systems) described above can be formed in the chip 1200 in the same manufacturing process. Therefore, even when the number of circuits needed for the chip 1200 is increased, there is no need to increase the number of steps in the manufacturing process; thus, the chip 1200 can be manufactured at a low cost.

The motherboard 1203 provided with the package substrate 1201 on which the chip 1200 including the GPU 1212 is mounted, the DRAM 1221, and the flash memory 1222 can be referred to as a GPU module 1204.

The GPU module 1204 includes the chip 1200 formed using the SoC technology, and thus can have a small size. Furthermore, the GPU module 1204 is excellent in image processing, and thus is suitably used in a portable electronic device such as a smartphone, a tablet terminal, a laptop PC, or a portable (mobile) game console. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 4

Described in this embodiment are examples of an electronic component including the memory device of one embodiment of the present invention.

### [Electronic Component]

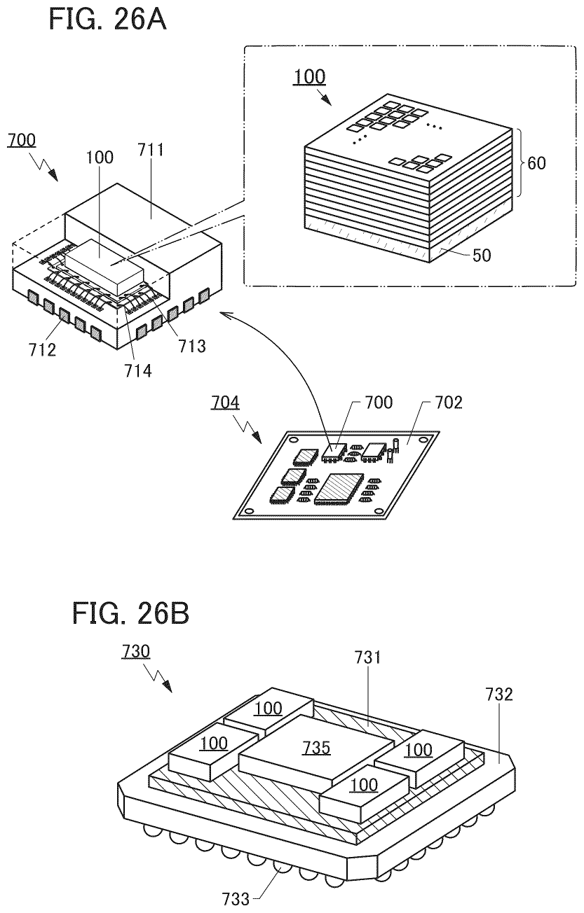

FIG. 26A is a perspective view of an electronic component 700 and a substrate (circuit board 704) on which the electronic component 700 is mounted. The electronic component 700 illustrated in FIG. 26A includes the memory device 100, which is the memory device of one embodiment of the present invention in a mold 711. FIG. 26A omits illustrations of some components to show the inside of the electronic component 700. The electronic component 700 includes a land 712 outside the mold 711. The land 712 is electrically connected to an electrode pad 713, and the electrode pad 713 is electrically connected to the memory device 100 via a wire 714. The electronic component 700 is mounted on a printed circuit board 702, for example. A plurality of such electronic components are combined and electrically connected to each other on the printed circuit board 702, which forms the circuit board 704.

As described in the above embodiments, the memory device 100 includes the driver circuit layer 50 and the memory layer 60 (including the memory cell array 15).

FIG. 26B illustrates a perspective view of an electronic component 730. The electronic component 730 is an example of a SiP (System in package) or an MCM (Multi Chip Module). In the electronic component 730, an interposer 731 is provided over a package substrate 732 (printed circuit board) and a semiconductor device 735 and a plurality of memory devices 100 are provided over the interposer 731.

The electronic component 730 using the memory device 100 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at a lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In an SiP, an MCM, or the like using a silicon interposer, a decrease in reliability due to a difference in expansion coefficient between an integrated circuit and the interposer is unlikely to occur. Furthermore, a surface of a silicon interposer has high planarity; thus, a poor connection between the silicon interposer and an integrated circuit provided on the silicon interposer is unlikely to occur. It is particularly preferable to use a silicon interposer for a 2.5D package (2.5D mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably equal to each other. In the electronic component 730 described in this embodiment, the heights of the memory device 100 and the semiconductor device 735 are preferably equal to each other, for example.

An electrode 733 may be provided on the bottom portion of the package substrate 732 to mount the electronic component 730 on another substrate. FIG. 26B illustrates an example in which the electrode 733 is formed of a solder ball. Solder balls are provided in a matrix on the bottom portion of the package substrate 732, whereby a BGA (Ball Grid Array) mounting can be achieved. Alternatively, the electrode 733 may be formed of a conductive pin. When conductive pins are provided in a matrix on the bottom portion of the package substrate 732, a PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat non-leaded package).

This embodiment can be combined with the other embodiments as appropriate.

### Embodiment 5

In this embodiment, application examples of the memory device of one embodiment of the present invention will be described.

The memory device of one embodiment of the present invention can be used as memory devices of a variety of electronic devices (e.g., information terminals, computers, smartphones, e-book readers, digital still cameras, video cameras, video recording/reproducing devices, navigation systems, and game machines). The memory device of one embodiment of the present invention can also be used for image sensors, IoT (Internet of Things), healthcare devices, and the like. This enables electronic devices to achieve low power consumption. Here, the computers refer not only to tablet computers, notebook computers, and desktop computers, but also to large computers such as server systems.

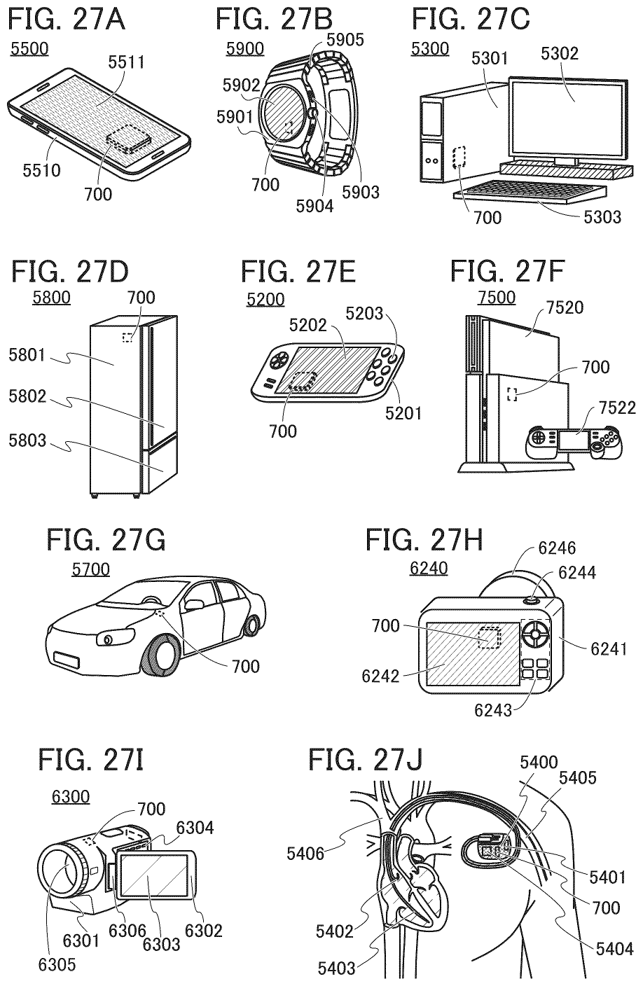

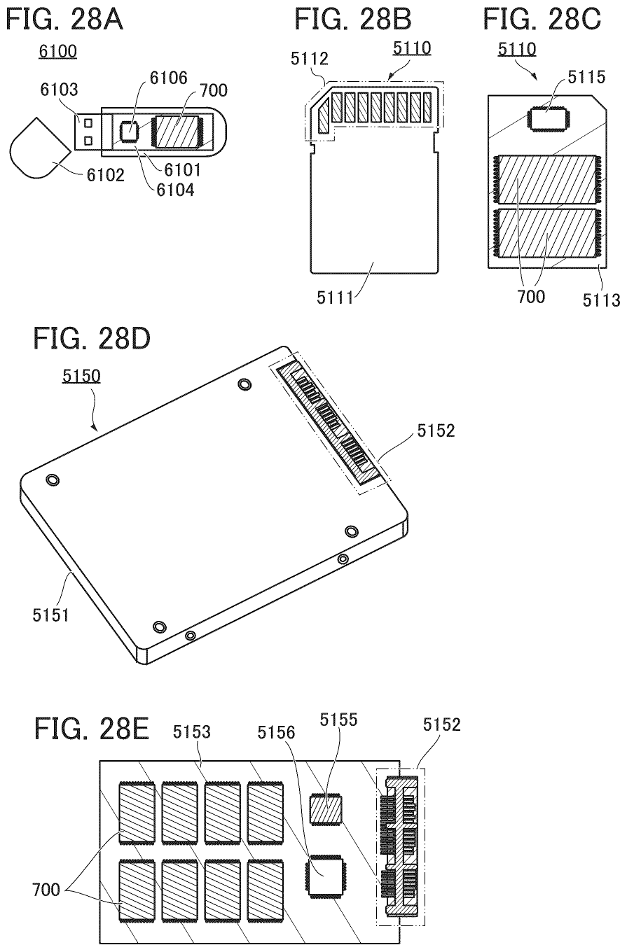

Examples of an electronic device including the memory device of one embodiment of the present invention will be described. FIG. 27A to FIG. 27J and FIG. 28A to FIG. 28E each illustrate that the electronic component 700 or the electronic component 730, each of which includes the memory device described in the above embodiments, is included in an electronic device.

### [Mobile Phone]

An information terminal 5500 illustrated in FIG. 27A is a mobile phone (a smartphone), which is a type of information terminal. The information terminal 5500 includes a housing 5510 and a display portion 5511, and as input interfaces, a touch panel is provided in the display portion 5511 and a button is provided in the housing 5510.

By using the memory device of one embodiment of the present invention, the information terminal 5500 can retain a temporary file generated at the time of executing an application (e.g., a web browser's cache).

### [Wearable Terminal]

FIG. 27B illustrates an information terminal 5900 as an example of a wearable terminal. The information terminal 5900 includes a housing 5901, a display portion 5902, an operation switch 5903, an operation switch 5904, a band 5905, and the like.

Like the aforementioned information terminal 5500, the wearable terminal can retain a temporary file generated at the time of executing an application, by using the memory device of one embodiment of the present invention.

### [Information Terminal]

FIG. 27C illustrates a desktop information terminal 5300. The desktop information terminal 5300 includes a main body 5301 of the information terminal, a display portion 5302, and a key board 5303.

Like the information terminal 5500, the desktop information terminal 5300 can retain a temporary file generated at the time of executing an application, by using the memory device of one embodiment of the present invention.

FIG. 27A to FIG. 27C illustrate the smartphone, the wearable terminal, and the desktop information terminal as electronic devices; other examples of information terminals include a PDA (Personal Digital Assistant), a laptop information terminal, and a workstation.

### [Household Appliance]

FIG. 27D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The memory device of one embodiment of the present invention can be used in the electric refrigerator-freezer 5800. The electric refrigerator-freezer 5800 can transmit and receive data on food stored in the electric refrigerator-freezer 5800, food expiration dates, and the like to/from an information terminal or the like via the Internet, for example. In the electric refrigerator-freezer 5800, the memory device of one embodiment of the present invention can retain a temporary file generated at the time of transmitting the data.

An electric refrigerator-freezer is described as an example of a household appliance in FIG. 27D; other examples of household appliances include a vacuum, a microwave oven, an electric oven, a rice cooker, a water heater, an IH cooker, a water server, a heating-cooling combination appliance such as an air conditioner, a washing machine, a drying machine, and an audio visual appliance.

### [Game Machine]

FIG. 27E illustrates a portable game machine 5200 as an example of a game machine. The portable game machine 5200 includes a housing 5201, a display portion 5202, a button 5203, and the like.

FIG. 27F illustrates a stationary game machine 7500 as another example of a game machine. The stationary game machine 7500 can be especially referred to as a home-use stationary game machine. The stationary game machine 7500 includes a main body 7520 and a controller 7522. The controller 7522 can be connected to the main body 7520 with or without a wire. Although not illustrated in FIG. 27F, the controller 7522 can include a display portion that displays a game image, and an input interface besides a button, such as a touch panel, a stick, a rotating knob, and a sliding knob, for example. The shape of the controller 7522 is not limited to that in FIG. 27F and may be changed variously in accordance with the genres of games. For example, in a shooting game such as an FPS (first person shooter) game, a gun-shaped controller having a trigger button can be used. As another example, in a music game or the like, a controller having a shape of a music instrument, audio equipment, or the like can be used. Furthermore, the stationary game machine may include one or more of a camera, a depth sensor, and a microphone, so that the game player can play a game using a gesture or a voice instead of a controller.

Videos displayed on the game machine can be output with a display device such as a television device, a personal computer display, a game display, or a head-mounted display.

By using the memory device of one embodiment of the present invention in the portable game machine 5200 or the stationary game machine 7500, low power consumption can be achieved. The low power consumption reduces heat generation from a circuit; thus, the influence of heat generation on the circuit itself, the peripheral circuit, and the module can be reduced.

Moreover, with the use of the memory device of one embodiment of the present invention, the portable game machine 5200 or the stationary game machine 7500 can retain a temporary file or the like necessary for arithmetic operation that occurs during game play.

As examples of game machines, FIG. 27E and FIG. 27F illustrate a portable game machine and a home-use stationary game machine; other examples of the game machines include an arcade game machine installed in an entertainment facility (e.g., a game center and an amusement park) and a throwing machine for batting practice, installed in sports facilities.

### [Moving Vehicle]

The memory device of one embodiment of the present invention can be used in an automobile, which is a moving vehicle, and around the driver's seat in an automobile.

FIG. 27G illustrates an automobile 5700 as an example of a moving vehicle.

An instrument panel that provides various kinds of information by displaying a speedometer, a tachometer, a mileage, a fuel meter, a gearshift indicator, air-conditioning settings, and the like is provided around the driver's seat in the automobile 5700. In addition, a memory device showing the above information may be provided around the driver's seat.

In particular, the display device can compensate for the view obstructed by the pillar or the like, the blind areas for the driver's seat, and the like by displaying a video taken by an imaging device (not illustrated) provided for the automobile 5700, thereby providing a high level of safety. That is, display of an image from an imaging device provided on the outside of the automobile 5700 can fill in blind areas and increase safety.

The memory device of one embodiment of the present invention can temporarily retain information; thus, the memory device can be used to retain temporary information necessary in an automatic driving system for the automobile 5700 and a system or the like for navigation and risk prediction, for example. The display device may be configured to display temporary information regarding navigation, risk prediction, or the like. Moreover, the memory device may be configured to retain a video of a driving recorder provided in the automobile 5700.

Although an automobile is described above as an example of a moving vehicle, moving vehicles are not limited to an automobile. Other examples of moving vehicles include a train, a monorail train, a ship, and a flying object (a helicopter, an unmanned aircraft (a drone), an airplane, and a rocket).

### [Camera]

The memory device of one embodiment of the present invention can be used in a camera.

FIG. 27H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that, here, although the digital camera 6240 is configured such that the lens 6246 is detachable from the housing 6241 for replacement, the lens 6246 may be integrated with the housing 6241. Moreover, the digital camera 6240 may be configured to be additionally equipped with a stroboscope, a viewfinder, or the like.

By using the memory device of one embodiment of the present invention in the digital camera 6240, the power consumption can be reduced. Moreover, heat generation from a circuit can be reduced owing to the low power consumption; thus, the influence of heat generation on the circuit itself, a peripheral circuit, and a module can be reduced.

### [Video Camera]

The memory device of one embodiment of the present invention can be used in a video camera.

FIG. 27I illustrates a video camera 6300 as an example of an imaging device. The video camera 6300 includes a first housing 6301, a second housing 6302, a display portion 6303, an operation switch 6304, a lens 6305, a joint 6306, and the like. The operation switch 6304 and the lens 6305 are provided for the first housing 6301, and the display portion 6303 is provided for the second housing 6302. The first housing 6301 and the second housing 6302 are connected to each other with the joint 6306, and the angle between the first housing 6301 and the second housing 6302 can be changed with the joint 6306. Videos displayed on the display portion 6303 may be switched in accordance with the angle at the joint 6306 between the first housing 6301 and the second housing 6302.

When a video taken by the video camera 6300 is recorded, the video needs to be encoded based on a data recording format. With the use of the memory device of one embodiment of the present invention, the video camera 6300 can retain a temporary file generated in encoding.

### [ICD]

The memory device of one embodiment of the present invention can be used in an implantable cardioverter-defibrillator (ICD).

FIG. 27J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with the end of one of them placed in the right ventricle and the end of the other placed in the right atrium.

The ICD main unit 5400 functions as a pacemaker and paces the heart when the heart rate is not within a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor, the number of times the treatment with pacing is performed, and the time taken for the treatment, for example, can be stored in the electronic component 700.

The antenna 5404 can receive power, and the power is charged into the battery 5401. When the ICD main unit 5400 includes a plurality of batteries, the safety can be improved. Specifically, even if some of the batteries in the ICD main unit 5400 are dead, the other batteries can work properly; hence, the batteries also function as an auxiliary power source.

In addition to the antenna 5404 that can receive power, an antenna that can transmit a physiological signal may be provided. For example, a system that monitors the cardiac activity and is capable of monitoring physiological signals such as pulses, respiratory rate, heart rate, and body temperature with an external monitoring device may be constructed.

### [Expansion Device for PC]

The memory device of one embodiment of the present invention can be used in a computer such as a PC (Personal Computer) and an expansion device for an information terminal.

FIG. 28A illustrates, as an example of the expansion device, a portable expansion device 6100 that is externally attached to a PC and includes a chip capable of storing data. When the expansion device 6100 is connected to a PC with a USB (Universal Serial Bus), for example, data can be stored in the chip. FIG. 28A illustrates the portable expansion device 6100; however, the expansion device of one embodiment of the present invention is not limited to this and may be a relatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the memory device of one embodiment of the present invention, for example. For example, the substrate 6104 is provided with the electronic component 700 and a controller chip 6106. The USB connector 6103 functions as an interface for connection to an external device.

### [Sd Card]

The memory device of one embodiment of the present invention can be used in an SD card that can be attached to electronic devices such as an information terminal and a digital camera.

FIG. 28B is a schematic external view of an SD card, and FIG. 28C is a schematic view illustrating the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the substrate 5113 is provided with the electronic component 700 and a controller chip 5115. Note that the circuit structures of the electronic component 700 and the controller chip 5115 are not limited to those described above and can be changed as appropriate depending on circumstances. For example, a write circuit, a row driver, a read circuit, and the like that are provided in an electronic component may be incorporated into the controller chip 5115 instead of the electronic component 700.

When the electronic component 700 is also provided on the back side of the substrate 5113, the capacity of the SD card 5110 can be increased. In addition, a wireless chip with a wireless communication function may be provided on the substrate 5113. This enables wireless communication between an external device and the SD card 5110, making it possible to write and read data to and from the electronic component 700.

### [SSD]

The memory device of one embodiment of the present invention can be used in an SSD (Solid State Drive) that can be attached to electronic devices such as information terminals.

FIG. 28D is a schematic external view of an SSD, and FIG. 28E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the substrate 5153 is provided with the electronic component 700, a memory chip 5155, and a controller chip 5156. When the electronic component 700 is also provided on the back side of the substrate 5153, the capacity of the SSD 5150 can be increased. A work memory is incorporated into the memory chip 5155. For example, a DRAM chip can be used as the memory chip 5155. A processor, an ECC (Error Check and Correct) circuit, and the like are incorporated into the controller chip 5156. Note that the circuit structures of the electronic component 700, the memory chip 5155, and the controller chip 5115 are not limited to those described above and can be changed as appropriate depending on circumstances. For example, a memory functioning as a work memory may also be provided in the controller chip 5156.

### [Computer]

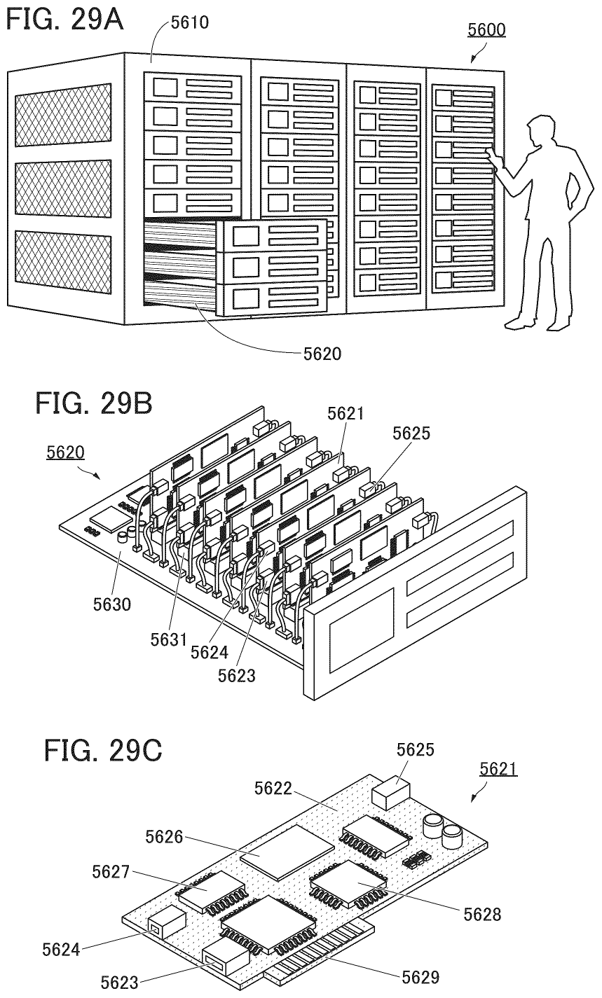

A computer 5600 illustrated in FIG. 29A is an example of a large computer. In the computer 5600, a plurality of rack mount computers 5620 are stored in a rack 5610.

The computer 5620 can have a structure in a perspective view illustrated in FIG. 29B, for example. In FIG. 29B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 29C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 29C illustrates semiconductor devices other than the semiconductor device 5626, the semiconductor device 5627, and the semiconductor device 5628, the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, and the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include a FPGA (Field Programmable Gate Array), a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention is used in a variety of electronic devices or the like described above, so that a reduction in size and a reduction in power consumption of the electronic device can be achieved. The memory device of one embodiment of the present invention has low power consumption, and thus can reduce heat generation from a circuit. Accordingly, the adverse effects of heat generation on the circuit itself, the peripheral circuit, and the module can be reduced. Furthermore, the use of the memory device of one embodiment of the present invention can achieve an electronic device that operates stably even in a high temperature environment. Thus, the reliability of the electronic device can be improved.

This embodiment can be combined with the other embodiments as appropriate.

### Embodiment 6

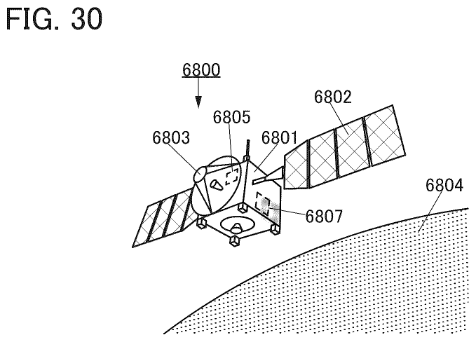

In this embodiment, specific examples of using the semiconductor device of one embodiment of the present invention in a device for space will be described with reference to FIG. 30.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space. Specifically, the OS transistor can be used as the transistor included in the semiconductor device provided in a space shuttle, an artificial satellite, or a space probe. Examples of radiation include X-rays and a neutron beam. Note that outer space refers to, for example, space at an altitude greater than or equal to 100 km, and outer space in this specification may include one or more of thermosphere, mesosphere, and stratosphere.

FIG. 30 illustrates an artificial satellite 6800 as an example of a device for space. The artificial satellite 6800 includes a body 6801, a solar panel 6802, an antenna 6803, a secondary battery 6805, and a control device 6807. FIG. 30 illustrates a planet 6804 in outer space, for example.

The amount of radiation in outer space is 100 or more times that on the ground. Examples of radiation include electromagnetic waves (electromagnetic radiation) typified by X-ray's and gamma rays and particle radiation typified by alpha rays, beta rays, neutron beam, proton beam, heavy-ion beams, and meson beams.

When the solar panel 6802 is irradiated with sunlight, power required for operation of the artificial satellite 6800 is generated. However, for example, in the situation where the solar panel is not irradiated with sunlight or the situation where the amount of sunlight with which the solar panel is irradiated is small, the amount of generated power is small. Accordingly, a sufficient amount of power required for operation of the artificial satellite 6800 might not be generated. In order to operate the artificial satellite 6800 even with a small amount of generated power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics of the OS transistor due to radiation irradiation is smaller than a change in electrical characteristics of a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

Alternatively, for example, the OS transistor can be used as a transistor included in a semiconductor device provided in a working robot in a nuclear power plant and a treatment plant or a disposal plant for radioactive wastes. In particular, the OS transistor can be suitably used as a transistor included in a semiconductor device provided in a remote control robot that is controlled remotely in demolishment of a reactor facility, taking out of a nuclear fuel or a fuel debris, a field investigation on a space with a large amount of radioactive substance, or the like.

This embodiment can be combined with the other embodiments as appropriate.

### REFERENCE NUMERALS

ADDR: signal, BL[i,s]: wiring, BL: wiring, BPR: signal, BW: signal, CE: signal, CLK: signal, DIN: data, DOUT: data, GND: ground potential, GRSEL: signal, GW: signal, GWSEL: signal, ND: node, NS: node, NSB: node, PL[i,s+1]: wiring, PL[i,s]: wiring, PL: wiring, RBL: wiring, RDA: signal, RSEL: signal, SEN: signal, SEP: signal, SL[j+1]: wiring, SL[j]: wiring, SL: wiring, Vdd: potential, VDD: power supply potential, Vref: reference potential, WAKE: signal, WBL: wiring, WDA: signal, WSEL: signal, WWL[j+1]: wiring, WWL[j]: wiring, WWL: wiring, 10[1,1]: memory cell, 10[i,j+1]: memory cell, 10[i,j]: memory cell, 10[m,n]: memory cell, 10: memory cell, 11_1: first layer, 11_2: second layer, 11_n: n-th layer, 15: memory cell array, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier circuit, 47: input circuit, 48: output circuit, 50: driver circuit layer, 60_1: memory layer, 60_2: memory layer, 60_3: memory layer, 60_k: memory layer, 60_N: memory layer, 60: memory layer, 100: memory device, 101a: capacitor, 101b: capacitor, 153: conductor, 154: insulator, 160a: conductor, 160b: conductor, 160: conductor, 201a: transistor, 201b: transistor, 202a: transistor, 202b: transistor, 203a: transistor, 203b: transistor, 205a: conductor, 205b: conductor, 209: conductor, 210a: insulator, 210b: insulator, 210: insulator, 212: insulator, 214: insulator, 216: insulator, 220a: oxide, 220af: oxide film, 220b: oxide, 220bf: oxide film, 220: oxide, 222: insulator, 224: insulator, 230a: oxide, 230b: oxide, 230: oxide, 231a: conductor, 231b: conductor, 231: conductor, 232: insulator, 240) a: conductor, 240b: conductor, 240): conductor, 242a: conductor, 242b: conductor, 243a: insulator, 243b: insulator, 244a: insulator, 244b: insulator, 250): region, 252_1: conductor, 252_2: conductor, 252a: conductor, 252b: conductor, 252c: conductor, 252: conductor, 253: insulator, 254: insulator, 260a: conductor, 260b: conductor, 260: conductor, 262: insulator, 263a: conductor, 263b: conductor, 263: conductor, 264: insulator, 265a: conductor, 265b: conductor, 265c: conductor, 266: insulator, 270a: conductor, 270b: conductor, 272: insulator, 274f: insulating film, 274: insulator, 275: insulator, 276: insulator, 280): insulator, 281: insulator, 282: insulator, 283: insulator, 284: insulator, 285: insulator, 290): insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350): insulator, 357: insulator, 600: circuit, 601: switching circuit, 652: AND circuit, 653: analog switch, 654: analog switch, 661: transistor, 662: transistor, 663: transistor, 664: transistor, 665: transistor, 666: transistor, 700: electronic component, 702: printed circuit board, 704: circuit board, 711: mold, 712: land, 713: electrode pad, 714: wire, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 30) 6244: shutter button, 6246: lens, 6300: video camera, 6301: first housing, 6302: second housing, 6303: display portion, 6304: operation switch, 6305: lens, 6306: joint, 6800: artificial satellite, 6801: body, 6802: solar panel, 6803: antenna, 6804: planet, 6805: secondary battery, 6807: control device, 7500: stationary game machine, 7520: main body, 7522: controller

1. A semiconductor device comprising:
a first transistor, a second transistor, and a first insulator over an insulating surface,
wherein the first transistor and the second transistor share a first metal oxide over the first insulator and a first conductor over the first metal oxide,
wherein the first transistor comprises a second conductor and a second insulator, the second conductor and the second insulator being over the first metal oxide, and a third conductor over the second insulator,
wherein the second transistor comprises a fourth conductor and a third insulator, the fourth conductor and the third insulator being over the first metal oxide, and a fifth conductor over the third insulator,
wherein a side surface of the first insulator comprises a portion in contact with the fourth conductor,
wherein an end portion of the fourth conductor comprises a portion positioned outward from an end portion of the first insulator,
wherein the second insulator is positioned between the first conductor and the second conductor,
wherein the metal oxide and the third conductor overlap with each other with the second insulator therebetween,
wherein the third insulator is positioned between the first conductor and the fourth conductor, and
wherein the metal oxide and the fifth conductor overlap with each other with the third insulator therebetween.

2. A semiconductor device comprising:
a first transistor, a second transistor, a third transistor, a first insulator, a second insulator, a third insulator, and a capacitor,
wherein the first transistor and the second transistor share a first metal oxide over the first insulator and a first conductor over the first metal oxide,
wherein the first transistor comprises a second conductor and a fourth insulator, the second conductor and the fourth insulator being over the first metal oxide, and a third conductor over the fourth insulator,
wherein the second transistor comprises a fourth conductor and a fifth insulator, the fourth conductor and the fifth insulator being over the first metal oxide, and a fifth conductor over the fifth insulator,
wherein the third transistor comprises a second metal oxide, a sixth conductor, a seventh conductor, and a sixth insulator, the sixth conductor, the seventh conductor, and the sixth insulator being over the second metal oxide, and an eighth conductor over the sixth insulator,
wherein the capacitor comprises a ninth conductor, a seventh insulator over the ninth conductor, and a tenth conductor over the seventh insulator,
wherein a side surface of the first insulator comprises a portion in contact with the fourth conductor,
wherein an end portion of the fourth conductor comprises a portion positioned outward from an end portion of the first insulator,
wherein the second insulator is positioned over the first transistor and over the second transistor,
wherein the second conductor and the sixth conductor are electrically connected to each other through an opening provided in the second insulator,
wherein the third insulator is positioned over the third transistor,
wherein a portion where the ninth conductor, the seventh insulator, and the tenth conductor overlap with one another is positioned over the third insulator, and
wherein the sixth conductor and the ninth conductor are electrically connected to each other through an opening provided in the third insulator.

3. The semiconductor device according to claim 2,
wherein the end portion of the fourth conductor comprises a portion positioned outward from an end portion of the second insulator.

4. The semiconductor device according to claim 2,
wherein the end portion of the second insulator comprises a portion positioned outward from the end portion of the first insulator.

5. The semiconductor device according to claim 2,
wherein an end portion of the seventh conductor comprises a portion positioned outward from the end portion of the second insulator.

6. The semiconductor device according to claim 2,
wherein an end portion of the third insulator comprises a portion positioned outward from the end portion of the first insulator.

7. The semiconductor device according to claim 2, further comprising an eleventh conductor,
wherein the eleventh conductor comprises a portion in contact with part of a top surface of the fourth conductor, a portion in contact with part of a side surface of the fourth conductor, a portion in contact with part of a top surface of the seventh conductor, and a portion in contact with part of a side surface of the seventh conductor.

8. The semiconductor device according to claim 7,
wherein the eleventh conductor comprises a portion in contact with part of a bottom surface of the fourth conductor and a portion in contact with part of a bottom surface of the seventh conductor.

9. The semiconductor device according to claim 2,
wherein the seventh insulator comprises one or both of zirconium oxide and aluminum oxide.
